(19) United States
(12) Patent Application Publication
(10) Pub. No.: US 2025/0110402 A1
(43) Pub. Date: Apr. 3, 2025

(54) SILICON-CONTAINING RESIST UNDERLAYER FILM-FORMING COMPOSITION HAVING UNSATURATED BOND AND CYCLIC STRUCTURE

(71) Applicant: NISSAN CHEMICAL CORPORATION, Tokyo (JP)

(72) Inventors: Kodai KATO, Toyama (JP); Satoshi TAKEDA, Toyama (JP); Shuhei SHIGAKI, Toyama (JP); Wataru SHIBAYAMA, Toyama (JP)

(73) Assignee: NISSAN CHEMICAL CORPORATION, Tokyo (JP)

(21) Appl. No.: 18/729,727

(22) PCT Filed: Feb. 17, 2023
(86) PCT No.: PCT/JP2023/005661

§ 371 Date: Jul. 17, 2024

(30) Foreign Application Priority Data
Feb. 18, 2022 (JP) 2022-024068

(51) Int. Cl. G03F 7/038; C09D 183/06; G03F 7/00; G03F 7/40; G03F 7/42; H01L 21/027

(52) U.S. Cl. CPC G03F 7/0388; C09D 183/06; G03F 7/40; G03F 7/422; G03F 7/70033; H01L 21/0274

(57) ABSTRACT

A silicon-containing resist underlayer film-forming composition for forming a silicon-containing resist underlayer film between a metal-containing resist film and a substrate, the silicon-containing resist underlayer film-forming composition including: a component [A]: a polysiloxane; and a component [C]: a solvent, in which the polysiloxane contains a structural unit derived from a hydrolyzable silane (A) represented by the following Formula (A-1):

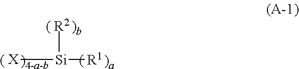

where in Formula (A-1), a represents an integer of 1 to 3, b represents an integer of 0 to 2, a+b represents an integer of 1 to 3, and R¹ represents an organic group having an unsaturated bond and a ring structure.

### TECHNICAL FIELD

The present invention relates to a silicon-containing resist underlayer film-forming composition and a silicon-containing resist underlayer film.

### BACKGROUND ART

In the related art, fine processing by lithography using photoresists has been performed in the production of semiconductor devices. The fine processing is a processing method including: forming a photoresist thin film on a semiconductor substrate such as a silicon wafer; irradiating the thin film with active rays such as ultraviolet rays through a mask pattern having a semiconductor device pattern drawn thereon; developing the irradiated thin film; and etching the substrate with the resultant photoresist pattern serving as a protective film to form, on the surface of the substrate, fine irregularities corresponding to the pattern.

Active rays having a shorter wavelength have tended to be used (i.e. shifting from KrF excimer laser (248 nm) to ArF excimer laser (193 nm)) in association with an increase in the degree of integration of semiconductor devices. Furthermore, an exposure technique using an extreme ultraviolet (EUV) or an electron beam has been studied. The use of such active rays having a shorter wavelength causes a serious problem in terms of reflection of active rays from a semiconductor substrate. In order to avoid such a problem, there has been widely used a method of providing a resist underlayer film called anti-reflective coating (Bottom Anti-Reflective Coating, BARC) between a photoresist and a to-be-processed substrate. As such a resist underlayer film, for example, an underlayer film containing silicon or the like has been proposed (Patent Literature 1 and the like).

With the miniaturization of the resist pattern in the most advanced semiconductor devices in recent years, the demand for thinning the resist has become more remarkable. In particular, in a three-layer process including a resist film, a silicon-containing resist underlayer film, and an organic underlayer film, good lithography characteristics of the resist on the silicon-containing resist underlayer film are desired.

### CITATION LIST

### Patent Literature

Patent Literature 1: JP 2007-163846 A

### SUMMARY OF INVENTION

### Technical Problem

Aiming at finer patterning of the resist as described above, a lithography technique using a metal oxide resist (MOR) having excellent etching resistance as compared with a known chemically amplified resist has been actively developed in recent years. For finer patterning in the future, it is essential to reduce the thickness of the resist film. However, the metal oxide resist (MOR) (hereinafter, also referred to as “metal-containing resist”) has sufficient etching resistance to perform fine patterning even on a thin film. Thus, the metal oxide resist is recently expected as a material to be used for next generation EUV lithography technique. Under such a background, the performance of imparting good lithography characteristics to the metal oxide resist underlayer film, which is different from the known chemically amplified resist lower layer film, may be an important object.

The present invention has been made in view of the above circumstances, and it is an object of the present invention to provide a silicon-containing resist underlayer film-forming composition for forming a resist underlayer film in which the roughness of a pattern width in fine patterning with a metal-containing resist can be improved.

### Solution to Problem

As a result of intensive studies to solve the above problem, the present inventors have found that the above problem can be solved, thereby completing the present invention having the following gist.

That is, the present invention includes the followings.
[1]A silicon-containing resist underlayer film-forming composition for forming a silicon-containing resist underlayer film between a metal-containing resist film and a substrate, the silicon-containing resist underlayer film-forming composition including:
a component [A]: a polysiloxane; and
a component [C]: a solvent,
wherein the polysiloxane contains a structural unit derived from a hydrolyzable silane (A) represented by the following Formula (A-1):

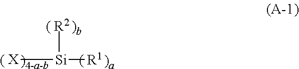

where in Formula (A-1), a represents an integer of 1 to 3,
b represents an integer of 0 to 2,
a+b represents an integer of 1 to 3,
R¹ represents an organic group having an unsaturated bond and a ring structure,
R² represents an optionally substituted alkyl group, an optionally substituted alkyl halide group, an optionally substituted alkoxyalkyl group, or an optionally substituted alkenyl group, or represents an organic group having an epoxy group, an organic group having an acryloyl group, an organic group having a methacryloyl group, an organic group having a mercapto group, an organic group having an amino group, an organic group having an alkoxy group, an organic group having a sulfonyl group or an organic group having a cyano group, or a combination of two or more of the groups,
X represents an alkoxy group, an aralkyloxy group, an acyloxy group, or a halogen atom, and
when a plurality of R¹s, R²s, or Xs is present, the plurality of R¹s, R²s, or Xs may be identical to or different from each other or one another.
[2]A silicon-containing resist underlayer film-forming composition for forming a silicon-containing resist underlayer film between a metal-containing resist film and a substrate, the silicon-containing resist underlayer film-forming composition including:
a component [A′]: a polysiloxane;
a component [B]: a hydrolyzable silane (A) represented by the following Formula (A-1); and
a component [C]: a solvent,

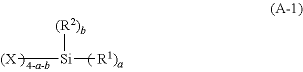

where in Formula (A-1), a represents an integer of 1 to 3,
b represents an integer of 0 to 2,
a+b represents an integer of 1 to 3,
R¹ represents an organic group having an unsaturated bond and a ring structure,
R² represents an optionally substituted alkyl group, an optionally substituted alkyl halide group, an optionally substituted alkoxyalkyl group, or an optionally substituted alkenyl group, or represents an organic group having an epoxy group, an organic group having an acryloyl group, an organic group having a methacryloyl group, an organic group having a mercapto group, an organic group having an amino group, an organic group having an alkoxy group, an organic group having a sulfonyl group or an organic group having a cyano group, or a combination of two or more of the groups,
X represents an alkoxy group, an aralkyloxy group, an acyloxy group, or a halogen atom, and
when a plurality of R¹s, R²s, or Xs is present, the plurality of R¹s, R²s, or Xs may be identical to or different from each other or one another.
[3] The silicon-containing resist underlayer film-forming composition according to [1] or [2], wherein R¹ in Formula (A-1) is represented by the following Formula (A-2 a):

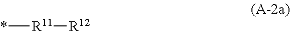

where in Formula (A-2a), R¹¹ represents a single bond or a divalent organic group which may have an ionic bond,
R¹² represents a group having an unsaturated bond and a ring structure, and
an asterisk * represents a bonding hand.
[4] The silicon-containing resist underlayer film-forming composition according to [3], wherein R¹² in Formula (A-2a) is represented by the following Formula (A-2b):

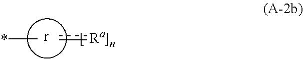

where in Formula (A-2b), r represents a ring structure, [symbol]
represents a single bond or a double bond, provided that, when [symbol]
represents a single bond, R^{a} represents a halogen atom or a monovalent group, and when [symbol]
represents a double bond, R^{a} represents an oxygen atom,
n is 0 or more and represents a value less than or equal to a number n of substituents that the ring structure r may have,
when n is 2 or more, [symbol]
and R^{a} may be identical or different,
when the ring structure r has a double bond in a bond forming the ring, n may be 0,
when the ring structure r has only a single bond as the bond forming the ring, n is 1 or more, and at least one of [symbol]
is a double bond or at least one R^{a} has an unsaturated bond, and
an asterisk * represents a bonding hand.
[5] The silicon-containing resist underlayer film-forming composition according to [4], wherein the ring structure r is a monocyclic 5-membered ring structure, a monocyclic 6-membered ring structure, a bicyclic structure, or a tricyclic structure.
[6] The silicon-containing resist underlayer film-forming composition according to [4] or [5], wherein Formula (A-2b) is any one of the following Formulae (A-2c-1) to (A-2c-6):

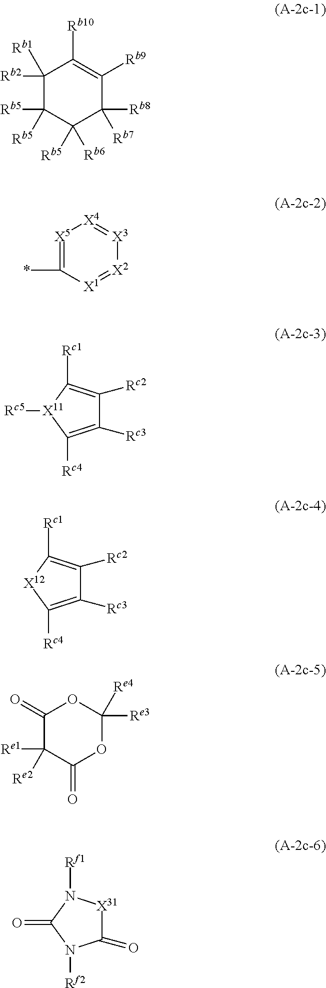

where in Formula (A-2c-1), R^{1b} to R^{b10} each independently represent a hydrogen atom, a halogen atom, or a monovalent group, R^{b1} and R^{b8} may be combined to form a methylene group or a 1,2-ethylene group, provided that one of R^{1b} to R^{b10} represents a bonding hand bonded to R¹¹ in Formula (A-2a),
in Formula (A-2c-2), X¹ to X⁵ each represent N or CR (provided that Rs each independently represent a hydrogen atom, a halogen atom, or a monovalent group), an asterisk * represents a bonding hand,
in Formula (A-2c-3), X¹¹ represents N or CR (provided that R represents a hydrogen atom, a halogen atom, or a monovalent group), R^{c1} to R^{c5} each independently represent a hydrogen atom, a halogen atom, or a monovalent group, provided that one of R^{c1} to R^{c5} represents a bonding hand bonded to R¹¹ in Formula (A-2a),
in Formula (A-2c-4), X²¹ represents O or S, R^{d1} to R^{d4} each independently represent a hydrogen atom, a halogen atom, or a monovalent group, provided that one of R^{d1} to R^{d4} represents a bonding hand bonded to R¹¹ in Formula (A-2a),
in Formula (A-2c-5), R^{e1} to R^{e4} each independently represent a hydrogen atom, a halogen atom, or a monovalent group, provided that one of R^{e1} to R^{e4} represents a bonding hand bonded to R¹¹ in Formula (A-2a),
in Formula (A-2c-6), X³¹ represents —C(═O)—N(R^{f3})—, —C(═O)—C(R^{f4})(R^{f5})—, or —C(R^{f6})(R^{f7})—, R^{f1} to R^{f7} each independently represent a hydrogen atom, a halogen atom, or a monovalent group, provided that one of R^{f1} and R^{f2} represents a bonding hand bonded to R¹¹ in Formula (A-2a)
[7] The silicon-containing resist underlayer film-forming composition according to [1], wherein the polysiloxane as the component [A] is a modified polysiloxane in which some of silanol groups are alcohol-modified or acetal-protected.
[8] The silicon-containing resist underlayer film-forming composition according to [2], wherein the polysiloxane as the component [A′] is a modified polysiloxane in which some of silanol groups are alcohol-modified or acetal-protected.
[9] The silicon-containing resist underlayer film-forming composition according to any one of [1] to [8], wherein the component [C] contains an alcohol-based solvent.
[10] The silicon-containing resist underlayer film-forming composition according to [9], wherein the component [C] contains propylene glycol monoalkyl ether.
[11] The silicon-containing resist underlayer film-forming composition according to any one of [1] to [10], further including a component [D]: a curing catalyst.
[12] The silicon-containing resist underlayer film-forming composition according to any one of [1] to [11], further including a component [E]: nitric acid.
[13] The silicon-containing resist underlayer film-forming composition according to any one of [1] to [12], wherein the component [C] contains water.
[14] The silicon-containing resist underlayer film-forming composition according to any one of [1] to [13], which is for forming a resist underlayer film for EUV lithography.
[15]A silicon-containing resist underlayer film which is a cured product of the silicon-containing resist underlayer film-forming composition described in any one of [1] to [14].
[16]A semiconductor processing substrate including:
a semiconductor substrate; and
the silicon-containing resist underlayer film described in [15].
[17]A method for producing a semiconductor element, the method including the steps of:
forming an organic underlayer film on a substrate;
forming a resist underlayer film on the organic underlayer film using the silicon-containing resist underlayer film-forming composition described in any one of [1] to [14]; and
forming a metal-containing resist film on the resist underlayer film.
[18] The method for producing a semiconductor element according to [17],
wherein the metal-containing resist film is formed of a metal-containing resist for EUV lithography.
[19] The method for producing a semiconductor element according to [17] or [18],
wherein in the step of forming a resist underlayer film, the silicon-containing resist underlayer film-forming composition to be used is filtered through a nylon filter.
[20]A method for forming a pattern, the method including the steps of:
forming an organic underlayer film on a semiconductor substrate;
applying the silicon-containing resist underlayer film-forming composition described in any one of [1] to [14] on the organic underlayer film and baking to form a resist underlayer film;
forming a metal-containing resist film on the resist underlayer film;
exposing and developing the metal-containing resist film to form a resist pattern;
etching the resist underlayer film using the resist pattern as a mask; and
etching the organic underlayer film using the patterned resist underlayer film as a mask.
[21] The method for forming a pattern according to [20], further including
a step of removing the resist underlayer film by a wet method using a chemical liquid, after the step of etching the organic underlayer film.
[22] The method for forming a pattern according to [20] or [21],
wherein the metal-containing resist film is formed of a metal-containing resist for EUV lithography.

### Advantageous Effects of Invention

The present invention can provide a silicon-containing resist underlayer film-forming composition for forming a resist underlayer film in which the roughness of a pattern width can be improved in fine patterning with a metal-containing resist.

### DESCRIPTION OF EMBODIMENTS

### (Silicon-Containing Resist Underlayer Film-Forming Composition)

The silicon-containing resist underlayer film-forming composition of the present invention is a silicon-containing resist underlayer film-forming composition for forming a silicon-containing resist underlayer film between a metal-containing resist film and a substrate.

### First Embodiment

The silicon-containing resist underlayer film-forming composition of the present invention according to a first embodiment contains a polysiloxane as a component [A] and a solvent as a component [C], and further contains an additional component, if necessary.

The polysiloxane as the component [A] contains a structural unit derived from a hydrolyzable silane (A) represented by the following Formula (A-1). The polysiloxane as the component [A] is, for example, a hydrolysis condensate of the hydrolyzable silane containing the hydrolyzable silane (A) represented by the following Formula (A-1) or a modified product of the hydrolysis condensate.

### Second Embodiment

The silicon-containing resist underlayer film-forming composition of the present invention according to a second embodiment contains a polysiloxane (hereinafter, may be referred to as “polysiloxane [A′]”) as a component [A′], a hydrolyzable silane (A) represented by the following Formula (A-1) as a component [B], and a solvent as a component [C], and further contains additional component, if necessary.

The present inventors consider as follows.

When a silicon-containing resist underlayer film formed from the silicon-containing resist underlayer film-forming composition of the present invention has an organic group having an unsaturated bond and a ring structure as an organic group bonded to Si, the roughness of a pattern width can be improved in fine patterning with a metal-containing resist. Although electrons are considered to be involved in the curing of the metal-containing resist, it is deemed that the unsaturated bond and the ring structure in the silicon-containing resist underlayer film appropriately trap electrons, and thus the excess diffusion of electrons are suppressed and the roughness of the pattern width is improved.

For example, in extremely fine metal-containing resist patterning with a resolution (hp) of less than 25 nm or even 8 to 20 nm, the roughness of the pattern width is improved.

### <Hydrolyzable Silane (A)>

The hydrolyzable silane (A) is a compound represented by the following Formula (A-1).

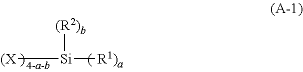

where in Formula (A-1), a represents an integer of 1 to 3,
b represents an integer of 0 to 2,
a+b represents an integer of 1 to 3,
R¹ represents an organic group having an unsaturated bond and a ring structure,
R² represents an optionally substituted alkyl group, an optionally substituted alkyl halide group, an optionally substituted alkoxyalkyl group, or an optionally substituted alkenyl group, or represents an organic group having an epoxy group, an organic group having an acryloyl group, an organic group having a methacryloyl group, an organic group having a mercapto group, an organic group having an amino group, an organic group having an alkoxy group, an organic group having a sulfonyl group or an organic group having a cyano group, or a combination of two or more of the groups,
X represents an alkoxy group, an aralkyloxy group, an acyloxy group, or a halogen atom, and
when a plurality of R¹s, R²s, or Xs is present, the plurality of R¹s, R²s, or Xs may be identical to or different from each other or one another.

Note that R² is not an organic group having an unsaturated bond and a ring structure.

In the present invention, examples of the halogen atom include a fluorine atom, a chlorine atom, a bromine atom, and an iodine atom.

### <<R¹ in Formula (A-1)>>

With regard to R¹, the unsaturated bond in the “organic group having an unsaturated bond and a ring structure” may be an unsaturated bond present in the ring structure. That is, even when in R¹, the ring structure has an unsaturated bond, and R¹ has no unsaturated bond other than the unsaturated bond, R¹ corresponds to the “organic group having an unsaturated bond and a ring structure”.

Examples of the unsaturated bond include a double bond and a triple bond.

Examples of the unsaturated bond include a carbon-carbon unsaturated bond (e.g. C═C), a carbon-oxygen unsaturated bond (e.g. C═O), and a carbon-nitrogen unsaturated bond (e.g. C═N).

R¹ may have one unsaturated bond or a plurality of unsaturated bonds. R¹ may have, for example, 1 to 8 unsaturated bonds, 1 to 6 unsaturated bonds, or 1 to 4 unsaturated bonds.

The ring structure may be a hydrocarbon ring or a hetero ring. Examples of atoms other than the carbon atom forming the hetero ring include an oxygen atom, a sulfur atom, and a nitrogen atom.

The ring structure may be an aromatic ring or a non-aromatic ring.

Examples of the ring structure include a 3-membered ring to a 10 membered ring. Specific examples thereof include a 3-membered ring, a 4-membered ring, a 5-membered ring, a 6-membered ring, a 7-membered ring, and an 8-membered ring.

The ring structure may be a monocyclic structure or a polycyclic structure. The polycyclic structure may be, for example, a bicyclic structure or a tricyclic structure.

In the polycyclic ring, the manner of bonding between the rings includes, for example, the following three bonding manners:
Sharing of one atom: e.g. spirocyclic compound;
Sharing of two atoms: when two rings share two atoms, such as decalin and naphthalene; and
Bridged structure: when two rings can be considered to share three or more atoms, such as norbornane.

In the case of the polycyclic ring, the number of atoms forming the ring is defined as the number of membered rings. For example, norbornane is a 7-membered ring.

R¹ may have one ring structure or a plurality of ring structures. R¹ may have, for example, one to three ring structures, or one to two ring structures.

R¹ does not have, for example, a Si—O group.

The carbon atom number of R¹ is not particularly limited, but the carbon atom number of R¹ is preferably 4 to 30, more preferably 4 to 20.

R¹ ordinarily has a hydrogen atom. R¹ may have an oxygen atom, a nitrogen atom, a sulfur atom, or a halogen atom, in addition to a carbon atom and a hydrogen atom.

R¹ may have or need not have an ionic bond. When R¹ has an ionic bond, R¹ may have an ionic bond in a row of atoms connecting an unsaturated bond or a ring structure and a silicon atom, or may have an ionic bond in a row of atoms branched from the row of atoms connecting an unsaturated bond or a ring structure and a silicon atom.

R¹ in Formula (A-1) is preferably represented by the following Formula (A-2a).

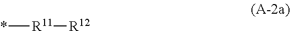

where in Formula (A-2a), R¹¹ represents a single bond or a divalent organic group which may have an ionic bond,
R¹² represents a group having an unsaturated bond and a ring structure, and
an asterisk * represents a bonding hand.

When R¹¹ is a divalent organic group which may have an ionic bond, the carbon atom number of R¹¹ is not particularly limited, but the carbon atom number of R¹¹ is preferably 1 to 25, more preferably 1 to 15.

<<R¹²R¹² in Formula (A-2a) is represented by, for example, the following Formula (A-2b):

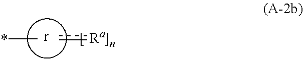

where in Formula (A-2b), r represents a ring structure,

[symbol]

represents a single bond or a double bond, provided that, when [symbol]
represents a single bond, R^{a} represents a halogen atom or a monovalent group, and when [symbol]
represents a double bond, R^{a} represents an oxygen atom,
n is 0 or more and represents a value less than or equal to a number n of substituents that the ring structure r may have,
when n is 2 or more, [symbol]
and R^{a} may be identical or different,
when the ring structure r has a double bond in a bond forming the ring, n may be 0,
when the ring structure r has only a single bond as the bond forming the ring, n is 1 or more, and at least one of [symbol]
is a double bond or at least one R^{a} has an unsaturated bond, and
an asterisk * represents a bonding hand.

The bond of the ring structure r is, for example, only a single bond.

The bond of the ring structure r is, for example, a single bond and a double bond.

The ring structure r is, for example, a monocyclic 5-membered ring structure, a monocyclic 6-membered ring structure, a bicyclic structure, or a tricyclic structure.

Examples of the monovalent group in R^{a} include a halogen atom and a monovalent organic group having 1 to 10 carbon atoms.

The monovalent group in R^{a} may have or need not have an unsaturated bond.

The monovalent group in R^{a} may have or need not have a ring structure.

n in Formula (A-2b) may be, for example, 0 to 8, 0 to 6, or 0 to 5.

For example, when Formula (A-2b) is represented by the following Formula, the ring structure r is a 6-membered ring including three carbon atoms and three nitrogen atoms, n is 5, two R^{a}s are methyl groups, and three R^{a}s are oxygen atoms bonded to the ring structure r by a carbon-oxygen double bond. The bond of the ring structure r is only a carbon-nitrogen single bond.

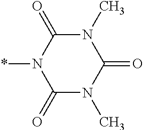 [SMILES: *n1c(=O)n(C)c(=O)n(C)c1=O]

From the viewpoint of suitably achieving the effects of the present invention, Formula (A-2b) is preferably any one of the following Formulae (A-2c-1) to (A-2c-6). In other words, R¹² in Formula (A-2a) is preferably any one of the following Formulae (A-2c-1) to (A-2c-6) from the viewpoint of suitably achieving the effects of the present invention.

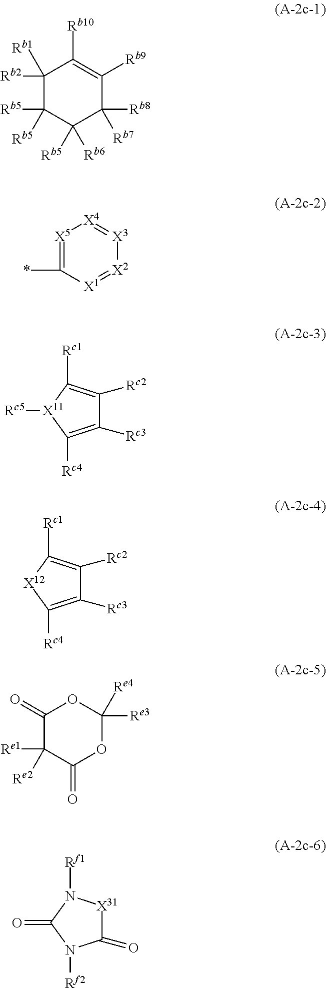

where in Formula (A-2c-1), R^{1b} to R^{b10} each independently represent a hydrogen atom, a halogen atom, or a monovalent group, R^{b1} and R^{b8} may be combined to form a methylene group or a 1,2-ethylene group, provided that one of R^{1b} to R^{b10} represents a bonding hand bonded to R¹¹ in Formula (A-2a),
in Formula (A-2c-2), X¹ to X⁵ each represent N or CR (provided that Rs each independently represent a hydrogen atom, a halogen atom, or a monovalent group), an asterisk * represents a bonding hand,
in Formula (A-2c-3), X¹¹ represents N or CR (provided that R represents a hydrogen atom, a halogen atom, or a monovalent group), R^{c1} to R^{c5} each independently represent a hydrogen atom, a halogen atom, or a monovalent group, provided that one of R^{c1} to R^{c5} represents a bonding hand bonded to R¹¹ in Formula (A-2a),
in Formula (A-2c-4), X²¹ represents O or S, R^{d1} to R^{d4} each independently represent a hydrogen atom, a halogen atom, or a monovalent group, provided that one of R^{d1} to R^{d4} represents a bonding hand bonded to R¹¹ in Formula (A-2a),
in Formula (A-2c-5), R^{e1} to R^{e4} each independently represent a hydrogen atom, a halogen atom, or a monovalent group, provided that one of R^{e1} to R^{e4} represents a bonding hand bonded to R¹¹ in Formula (A-2a),
in Formula (A-2c-6), X³¹ represents —C(═O)—N(R^{f3})—, —C(═O)—C(R^{f4})(R^{f5})—, or —C(R^{f6})(R^{f7})—, R^{f1} to R^{f7} each independently represent a hydrogen atom, a halogen atom, or a monovalent group, provided that one of R^{f1} and R^{f2} represents a bonding hand bonded to R¹¹ in Formula (A-2a).

Examples of the monovalent group in R^{1b} to R^{b10}, R^{c1} to R^{c5}, R^{d1} to R^{d4}, R^{e1} to R^{e4}, R^{f1} to R^{f7}, and R of CR include a monovalent organic group having 1 to 10 carbon atoms. Examples of the monovalent organic group having 1 to 10 carbon atoms include an alkyl group having 1 to 10 carbon atoms, an alkoxy group having 1 to 10 carbon atoms, and an alkenyl group having 2 to 10 carbon atoms.

Examples of the alkyl group having 1 to 10 carbon atoms include methyl group, ethyl group, n-propyl group, i-propyl group, cyclopropyl group, n-butyl group, i-butyl group, s-butyl group, t-butyl group, cyclobutyl group, 1-methyl-cyclopropyl group, 2-methyl-cyclopropyl group, n-pentyl group, 1-methyl-n-butyl group, 2-methyl-n-butyl group, 3-methyl-n-butyl group, 1,1-dimethyl-n-propyl group, 1,2-dimethyl-n-propyl group, 2,2-dimethyl-n-propyl group, 1-ethyl-n-propyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, n-hexyl group, 1-methyl-n-pentyl group, 2-methyl-n-pentyl group, 3-methyl-n-pentyl group, 4-methyl-n-pentyl group, 1,1-dimethyl-n-butyl group, 1,2-dimethyl-n-butyl group, 1,3-dimethyl-n-butyl group, 2,2-dimethyl-n-butyl group, 2,3-dimethyl-n-butyl group, 3,3-dimethyl-n-butyl group, 1-ethyl-n-butyl group, 2-ethyl-n-butyl group, 1,1,2-trimethyl-n-propyl group, 1,2,2-trimethyl-n-propyl group, 1-ethyl-1 methyl-n-propyl group, 1-ethyl-2-methyl-n-propyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, 2,4-dimethyl-cyclobutyl group, 3,3-dimethyl-cyclobutyl group, 1-n-propyl-cyclopropyl group, 2-n-propyl-cyclopropyl group, 1-i-propyl-cyclopropyl group, 2-i-propyl-cyclopropyl group, 1,2,2-trimethyl-cyclopropyl group, 1,2,3-trimethyl-cyclopropyl group, 2,2,3-trimethyl-cyclopropyl group, 1-ethyl-2 methyl-cyclopropyl group, 2-ethyl-1-methyl-cyclopropyl group, 2-ethyl-2-methyl-cyclopropyl group, 2-ethyl-3-methyl-cyclopropyl group, decyl group, undecyl group, dodecyl group, tridecyl group, tetradecyl group, pentadecyl group, hexadecyl group, heptadecyl group, octadecyl group, nonadecyl group, and isodecyl group.

Examples of the alkoxy group having 1 to 10 carbon atoms include methoxy group, ethoxy group, n-propoxy group, i-propoxy group, n-butoxy group, i-butoxy group, an s-butoxy group, t-butoxy group, n-pentyloxy group, 1-methyl-n-butoxy group, 2-methyl-n-butoxy group, 3-methyl-n-butoxy group, 1,1-dimethyl-n-propoxy group, 1,2-dimethyl-n-propoxy group, 2,2-dimethyl-n-propoxy group, 1-ethyl-n-propoxy group, n-hexyloxy group, 1-methyl-n-pentyloxy group, 2-methyl-n-pentyloxy group, 3-methyl-n-pentyloxy group, 4-methyl-n-pentyloxy group, 1,1-dimethyl-n-butoxy group, 1,2-dimethyl-n-butoxy group, 1,3-dimethyl-n-butoxy group, 2,2-dimethyl-n-butoxy group, 2,3-dimethyl-n-butoxy group, 3,3-dimethyl-n-butoxy group, 1-ethyl-n-butoxy group, 2-ethyl-n-butoxy group, 1,1,2-trimethyl-n-propoxy group, 1,2,2-trimethyl-n-propoxy group, 1-ethyl-1-methyl-n-propoxy group, 1-ethyl-2 methyl-n-propoxy group, cyclopentyloxy group, cyclohexyloxy group, norbornyloxy group, adamantyloxy group, adamantanemethyloxy group, adamantane ethyl oxy group, tetracyclodecanyloxy group, and tricyclodecanyloxy group.

Examples of the alkenyl group having 2 to 10 carbon atoms include ethenyl group, 1-propenyl group, 2-propenyl group, 1-methyl-1-ethenyl group, 1-butenyl group, 2-butenyl group, 3-butenyl group, 2-methyl-1-propenyl group, 2-methyl-2-propenyl group, 1-ethylethenyl group, 1-methyl-1-propenyl group, 1-methyl-2-propenyl group, 1-pentenyl group, 2-pentenyl group, 3-pentenyl group, 4-pentenyl group, 1-n-propylethenyl group, 1-methyl-1-butenyl group, 1-methyl-2-butenyl group, 1-methyl-3-butenyl group, 2-ethyl-2-propenyl group, 2-methyl-1-butenyl group, 2-methyl-2-butenyl group, 2-methyl-3-butenyl group, 3-methyl-1-butenyl group, 3-methyl-2-butenyl group, 3-methyl-3-butenyl group, 1,1-dimethyl-2-propenyl group, 1-i-propylethenyl group, 1,2-dimethyl-1-propenyl group, 1,2-dimethyl-2-propenyl group, 1-cyclopentenyl group, 2-cyclopentenyl group, 3-cyclopentenyl group, 1-hexenyl group, 2-hexenyl group, 3-hexenyl group, 4-hexenyl group, 5-hexenyl group, 1-methyl-1-pentenyl group, 1-methyl-2-pentenyl group, 1-methyl-3-pentenyl group, 1-methyl-4-pentenyl group, 1-n-butylethenyl group, 2-methyl-1-pentenyl group, 2-methyl-2-pentenyl group, 2-methyl-3 pentenyl group, 2-methyl-4-pentenyl group, 2-n-propyl-2-propenyl group, 3-methyl-1-pentenyl group, 3-methyl-2-pentenyl group, 3-methyl-3-pentenyl group, 3-methyl-4-pentenyl group, 3-ethyl-3-butenyl group, 4-methyl-1-pentenyl group, 4-methyl-2-pentenyl group, 4-methyl-3-pentenyl group, 4-methyl-4-pentenyl group, 1,1-dimethyl-2-butenyl group, 1,1-dimethyl-3-butenyl group, 1,2-dimethyl-1-butenyl group, 1,2-dimethyl-2-butenyl group, 1,2-dimethyl-3-butenyl group, 1-methyl-2-ethyl-2-propenyl group, 1-s-butylethenyl group, 1,3-dimethyl-1-butenyl group, 1,3-dimethyl-2-butenyl group, 1,3-dimethyl-3-butenyl group, 1-i-butylethenyl group, 2,2-dimethyl-3-butenyl group, 2,3-dimethyl-1-butenyl group, 2,3-dimethyl-2-butenyl group, 2,3-dimethyl-3-butenyl group, 2-i-propyl-2-propenyl group, 3,3-dimethyl-1-butenyl group, 1-ethyl-1-butenyl group, 1-ethyl-2-butenyl group, 1-ethyl-3-butenyl group, 1-n-propyl-1-propenyl group, 1-n-propyl-2-propenyl group, 2-ethyl-1-butenyl group, 2-ethyl-2-butenyl group, 2-ethyl-3-butenyl group, 1,1,2-trimethyl-2-propenyl group, 1-t-butylethenyl group, 1-methyl-1-ethyl-2-propenyl group, 1-ethyl-2-methyl-1-propenyl group, 1-ethyl-2-methyl-2-propenyl group, 1-i-propyl-1-propenyl group, 1-i-propyl-2-propenyl group, 1-methyl-2-cyclopentenyl group, 1-methyl-3-cyclopentenyl group, 2-methyl-1-cyclopentenyl group, 2-methyl-2-cyclopentenyl group, 2-methyl-3-cyclopentenyl group, 2-methyl-4-cyclopentenyl group, 2-methyl-5-cyclopentenyl group, 2-methylene-cyclopentyl group, 3-methyl-1-cyclopentenyl group, 3-methyl-2-cyclopentenyl group, 3-methyl-3-cyclopentenyl group, 3-methyl-4-cyclopentenyl group, 3-methyl-5-cyclopentenyl group, 3-methylene-cyclopentyl group, 1-cyclohexenyl group, 2-cyclohexenyl group, and 3-cyclohexenyl group.

In the present specification, “i” means “iso”, “s” means “sec”, and “t” means “tert”.

Examples of Formula (A-2c-2) include the following Formulae (A-2c-2-1) and (A-2c-2-2).

Examples of Formula (A-2c-6) include the following Formulae (A-2c-6-1) to (A-2c-6-3).

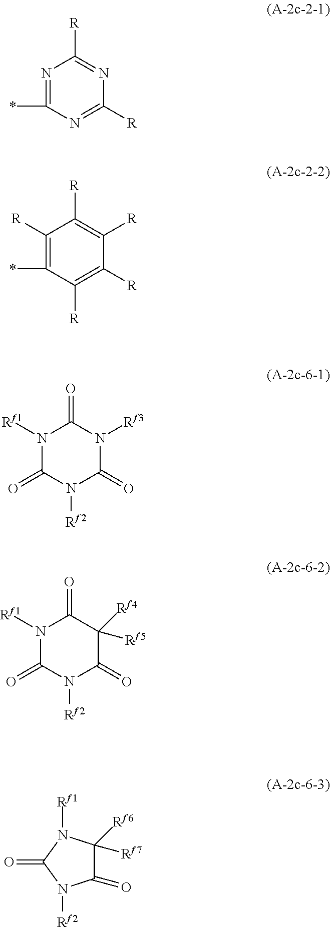

where in Formulae (A-2c-2-1) and (A-2c-2-2), Rs each independently represent a hydrogen atom, a halogen atom, or a monovalent group, each asterisk * represents a bonding hand,
in Formulae (A-2c-6-1) to (A-2c-6-3), R^{f1} to R^{f7} each independently represent a hydrogen atom, a halogen atom, or a monovalent group, provided that one of R^{f1} and R^{f2} represents a bonding hand bonded to R¹¹ in Formula (A-2a).

### <<<R¹¹>>>

R¹¹ is preferably either a single bond or a divalent organic group represented by the following Formulae (A-2-1) to (A-2-4).

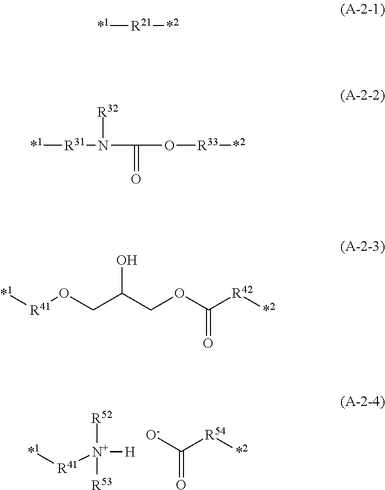

where in Formula (A-2-1), R²¹ represents an alkylene group having 1 to 6 carbon atoms,
in Formula (A-2-2), R³¹ represents an alkylene group having 1 to 6 carbon atoms, R³² represents a hydrogen atom or an alkyl group having 1 to 4 carbon atoms, and R³³ represents a single bond or an alkylene group having 1 to 6 carbon atoms,
in Formula (A-2-3), R⁴¹ represents an alkylene group having 1 to 6 carbon atoms, and R⁴² represents a single bond or an alkylene group having 1 to 6 carbon atoms,
in Formula (A-2-4), R⁵¹ represents an alkylene group having 1 to 6 carbon atoms, R⁵² and R⁵³ each independently represent a hydrogen atom or an alkyl group having 1 to 4 carbon atoms, and R⁵⁴ represents a single bond or an alkylene group having 1 to 6 carbon atoms,
in Formulae (A-2-1) to (A-2-4), a reference numeral with an asterisk “*1” represents a bonding hand bonded to Si, and a reference numeral with an asterisk “*2” represents a bonding hand bonded to R¹².

In the silicon-containing resist underlayer film-forming composition and the resist underlayer film, an amino group (—N(R³²)—) in Formula (A-2-2) may be cationized. For example, when nitric acid is added to the silicon-containing resist underlayer film-forming composition, the amino group (—N(R³²)—) in Formula (A-2-2) may be cationized to form a nitrate.

The alkylene group having 1 to 6 carbon atoms in R²¹, R³¹, R³³, R⁴¹, R⁴², and R⁵¹ may be linear or branched. Examples of the alkylene group having 1 to 6 carbon atoms include linear alkylene groups such as methylene group, ethylene group, trimethylene group, tetramethylene group, pentamethylene group, and hexamethylene group. Among these alkylene groups, a methylene group, an ethylene group, a trimethylene group, and a tetramethylene group are preferred.

The alkyl group having 1 to 4 carbon atoms in R³², R⁵², and R⁵³ may be linear or branched. Examples of the alkyl group having 1 to 4 carbon atoms include methyl group, ethyl group, n-propyl group, i-propyl group, n-butyl group, i-butyl group, s-butyl group, and t-butyl group.

As R³², R⁵², and R⁵³, a hydrogen atom, a methyl group, and an ethyl group are preferred.

### <<R² in Formula (A-1)>>

The alkyl group may be linear, branched, or cyclic, and the carbon atom numbers thereof is not particularly limited, but is preferably 40 or less, more preferably 30 or less, still more preferably 20 or less, and yet still more preferably 10 or less.

Specific examples of the linear or branched alkyl group as the alkyl group include methyl group, ethyl group, n-propyl group, i-propyl group, n-butyl group, i-butyl group, s-butyl group, t-butyl group, n-pentyl group, 1-methyl-n-butyl group, 2-methyl-n-butyl group, 3-methyl-n-butyl group, 1,1-dimethyl-n-propyl group, 1,2-dimethyl-n-propyl group, 2,2-dimethyl-n-propyl group, 1-ethyl-n-propyl group, n-hexyl group, 1-methyl-n-pentyl group, 2-methyl-n-pentyl group, 3-methyl-n-pentyl group, 4-methyl-n-pentyl group, 1,1-dimethyl-n-butyl group, 1,2-dimethyl-n-butyl group, 1,3-dimethyl-n-butyl group, 2,2-dimethyl-n-butyl group, 2,3-dimethyl-n-butyl group, 3,3-dimethyl-n-butyl group, 1-ethyl-n-butyl group, 2-ethyl-n-butyl group, 1,1,2-trimethyl-n-propyl group, 1,2,2-trimethyl-n-propyl group, 1-ethyl-1-methyl-n-propyl group, and 1-ethyl-2-methyl-n-propyl group.

Specific examples of the cyclic alkyl group include cycloalkyl groups, such as cyclopropyl group, cyclobutyl group, 1-methyl-cyclopropyl group, 2-methyl-cyclopropyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, cycloalkyl groups, such as 2,4-dimethyl-cyclobutyl group, 3,3-dimethyl-cyclobutyl group, 1-n-propyl-cyclopropyl group, 2-n-propyl-cyclopropyl group, 1-i-propyl-cyclopropyl group, 2-i-propyl-cyclopropyl group, 1,2,2-trimethyl-cyclopropyl group, 1,2,3-trimethyl-cyclopropyl group, 2,2,3-trimethyl-cyclopropyl group, 1-ethyl-2-methyl-cyclopropyl group, 2-ethyl-1-methyl-cyclopropyl group, 2-ethyl-2-methyl-cyclopropyl group, and 2-ethyl-3-methyl-cyclopropyl group; and crosslinked cyclic cycloalkyl groups, such as bicyclobutyl group, bicyclopentyl group, bicyclohexyl group, bicycloheptyl group, bicyclooctyl group, bicyclononyl group, and bicyclodecyl group.

The alkyl halide group is an alkyl group substituted with one or more halogen atoms, and specific examples of the alkyl group are the same as those described above.

Examples of the halogen atom include a fluorine atom, a chlorine atom, a bromine atom, and an iodine atom.

The carbon atom number of the alkyl halide group is not particularly limited, but is preferably 40 or less, more preferably 30 or less, still more preferably 20 or less, and yet still more preferably 10 or less.

Specific examples of the alkyl halide group include, but are not limited to, monofluoromethyl group, difluoromethyl group, trifluoromethyl group, bromodifluoromethyl group, 2-chloroethyl group, 2-bromoethyl group, 1,1-difluoroethyl group, 2,2,2-trifluoroethyl group, 1,1,2,2-tetrafluoroethyl group, 2-chloro-1,1,2-trifluoroethyl group, pentafluoroethyl group, 3-bromopropyl group, 2,2,3,3-tetrafluoropropyl group, 1,1,2,3,3,3-hexafluoropropyl group, 1,1,1,3,3,3-hexafluoropropane-2-yl group, 3-bromo-2-methylpropyl group, 4-bromobutyl group, and perfluoropentyl group.

The alkoxyalkyl group is an alkyl group substituted with one or more alkoxy groups, and specific examples of the alkyl group are the same as those described above.

The alkoxy group as the substituent is, for example, an alkoxy group having at least any one of linear, branched, and cyclic alkyl moieties having 1 to 20 carbon atoms.

Examples of the linear or branched alkoxy group include methoxy group, ethoxy group, n-propoxy group, i-propoxy group, n-butoxy group, i-butoxy group, s-butoxy group, t-butoxy group, n-pentyloxy group, 1-methyl-n-butoxy group, 2-methyl-n-butoxy group, 3-methyl-n-butoxy group, 1,1-dimethyl-n-propoxy group, 1,2-dimethyl-n-propoxy group, 2,2-dimethyl-n-propoxy group, 1-ethyl-n-propoxy group, n-hexyloxy group, 1-methyl-n-pentyloxy group, 2-methyl-n-pentyloxy group, 3-methyl-n-pentyloxy group, 4-methyl-n-pentyloxy group, 1,1-dimethyl-n-butoxy group, 1,2-dimethyl-n-butoxy group, 1,3-dimethyl-n-butoxy group, 2,2-dimethyl-n-butoxy group, 2,3-dimethyl-n-butoxy group, 3,3-dimethyl-n-butoxy group, 1-ethyl-n-butoxy group, 2-ethyl-n-butoxy group, 1,1,2-trimethyl-n-propoxy group, 1,2,2-trimethyl-n-propoxy group, 1-ethyl-1-methyl-n-propoxy group, and 1-ethyl-2-methyl-n-propoxy group.

Examples of the cyclic alkoxy group include cyclopropoxy group, cyclobutoxy group, 1-methyl-cyclopropoxy group, 2-methyl-cyclopropoxy group, cyclopentyloxy group, 1-methyl-cyclobutoxy group, 2-methyl-cyclobutoxy group, 3-methyl-cyclobutoxy group, 1,2-dimethyl-cyclopropoxy group, 2,3-dimethyl-cyclopropoxy group, 1-ethyl-cyclopropoxy group, 2-ethyl-cyclopropoxy group, cyclohexyloxy group, 1-methyl-cyclopentyloxy group, 2-methyl-cyclopentyloxy group, 3-methyl-cyclopentyloxy group, 1-ethyl-cyclobutoxy group, 2-ethyl-cyclobutoxy group, 3-ethyl-cyclobutoxy group, 1,2-dimethyl-cyclobutoxy group, 1,3-dimethyl-cyclobutoxy group, 2,2-dimethyl-cyclobutoxy group, 2,3-dimethyl-cyclobutoxy group, 2,4-dimethyl-cyclobutoxy group, 3,3-dimethyl-cyclobutoxy group, 1-n-propyl-cyclopropoxy group, 2-n-propyl-cyclopropoxy group, 1-i-propyl-cyclopropoxy group, 2-i-propyl-cyclopropoxy group, 1,2,2-trimethyl-cyclopropoxy group, 1,2,3-trimethyl-cyclopropoxy group, 2,2,3-trimethyl-cyclopropoxy group, 1-ethyl-2-methyl-cyclopropoxy group, 2-ethyl-1-methyl-cyclopropoxy group, 2-ethyl-2-methyl-cyclopropoxy group, and 2-ethyl-3-methyl-cyclopropoxy group.

Specific examples of the alkoxyalkyl group include, but are not limited to, lower (about 5 or less carbon atoms) alkyloxy lower (about 5 or less carbon atoms) alkyl groups, such as methoxymethyl group, ethoxymethyl group, 1-ethoxyethyl group, 2-ethoxyethyl group, and ethoxymethyl group.

The alkenyl group may be linear or branched, and the carbon atom number of the linear or branched alkenyl group is not particularly limited, but is preferably 40 or less, more preferably 30 or less, still more preferably 20 or less, and yet still more preferably 10 or less.

Specific examples of the alkenyl group include ethenyl group (vinyl group), 1-propenyl group, 2-propenyl group, 1-methyl-1-ethenyl group, 1-butenyl group, 2-butenyl group, 3-butenyl group, 2-methyl-1-propenyl group, 2-methyl-2-propenyl group, 1-ethylethenyl group, 1-methyl-1-propenyl group, 1-methyl-2-propenyl group, 1-pentenyl group, 2-pentenyl group, 3-pentenyl group, 4-pentenyl group, 1-n-propylethenyl group, 1-methyl-1-butenyl group, 1-methyl-2-butenyl group, 1-methyl-3-butenyl group, 2-ethyl-2-propenyl group, 2-methyl-1-butenyl group, 2-methyl-2-butenyl group, 2-methyl-3-butenyl group, 3-methyl-1-butenyl group, 3-methyl-2-butenyl group, 3-methyl-3-butenyl group, 1,1-dimethyl-2-propenyl group, 1-i-propylethenyl group, 1,2-dimethyl-1-propenyl group, 1,2-dimethyl-2-propenyl group, 1-hexenyl group, 2-hexenyl group, 3-hexenyl group, 4-hexenyl group, 5-hexenyl group, 1-methyl-1-pentenyl group, 1-methyl-2-pentenyl group, 1-methyl-3-pentenyl group, 1-methyl-4-pentenyl group, 1-n-butylethenyl group, 2-methyl-1-pentenyl group, 2-methyl-2-pentenyl group, 2-methyl-3 pentenyl group, 2-methyl-4-pentenyl group, 2-n-propyl-2-propenyl group, 3-methyl-1-pentenyl group, 3-methyl-2-pentenyl group, 3-methyl-3-pentenyl group, 3-methyl-4-pentenyl group, 3-ethyl-3-butenyl group, 4-methyl-1-pentenyl group, 4-methyl-2-pentenyl group, 4-methyl-3-pentenyl group, 4-methyl-4-pentenyl group, 1,1-dimethyl-2-butenyl group, 1,1-dimethyl-3-butenyl group, 1,2-dimethyl-1-butenyl group, 1,2-dimethyl-2-butenyl group, 1,2-dimethyl-3-butenyl group, 1-methyl-2-ethyl-2-propenyl group, 1-s-butylethenyl group, 1,3-dimethyl-1-butenyl group, 1,3-dimethyl-2-butenyl group, 1,3-dimethyl-3-butenyl group, 1-i-butylethenyl group, 2,2-dimethyl-3-butenyl group, 2,3-dimethyl-1-butenyl group, 2,3-dimethyl-2-butenyl group, 2,3-dimethyl-3-butenyl group, 2-i-propyl-2-propenyl group, 3,3-dimethyl-1-butenyl group, 1-ethyl-1-butenyl group, 1-ethyl-2-butenyl group, 1-ethyl-3-butenyl group, 1-n-propyl-1-propenyl group, 1-n-propyl-2-propenyl group, 2-ethyl-1-butenyl group, 2-ethyl-2-butenyl group, 2-ethyl-3-butenyl group, 1,1,2-trimethyl-2-propenyl group, 1-t-butylethenyl group, 1-methyl-1-ethyl-2-propenyl group, 1-ethyl-2-methyl-1-propenyl group, 1-ethyl-2-methyl-2-propenyl group, 1-i-propyl-1-propenyl group, and 1-i-propyl-2-propenyl group.

Examples of the substituent of the alkyl group, alkyl halide group, alkoxyalkyl group, and alkenyl group include an alkyl group, an alkyl halide group, an alkoxyalkyl group, an alkenyl group, and an alkoxy group. Specific examples of these groups and preferred carbon atom numbers thereof are the same as those described above or below.

When two or more substituents are present, the substituents may be bonded together to form a ring.

Examples of the organic group having an epoxy group include glycidoxymethyl group, glycidoxyethyl group, glycidoxypropyl group, glycidoxybutyl group, and epoxy cyclohexyl group.

Examples of the organic group having an acryloyl group include acryloyloxymethyl group, acryloyloxyethyl group, and acryloyloxypropyl group.

Examples of the organic group having a methacryloyl group include methacryloyloxymethyl group, methacryloyloxyethyl group, and methacryloyloxypropyl group.

Examples of the organic group having a mercapto group include mercaptoethyl group, mercaptobutyl group, mercaptohexyl group, and mercaptooctyl group.

Examples of the organic group having an amino group include, but are not limited to, amino group, aminomethyl group, aminoethyl group, dimethylaminoethyl group, and dimethylaminopropyl group. The organic group having an amino group will be described later in more detail.

Examples of the organic group having an alkoxy group include, but are not limited to, methoxymethyl group and methoxyethyl group. However, the organic group excludes a group wherein an alkoxy group is directly bonded to a silicon atom.

Examples of the organic group having a sulfonyl group include, but are not limited to, sulfonylalkyl group.

Examples of the organic group having a cyano group include cyanoethyl group, cyanopropyl group, and thiocyanate group.

The organic group having an amino group is, for example, an organic group having at least one of a primary amino group, a secondary amino group, or a tertiary amino group. A hydrolysis condensate in which a hydrolyzable silane having a tertiary amino group is hydrolyzed with a strong acid to form a counter cation having a tertiary ammonium group can be preferably used. The organic group may contain a heteroatom such as an oxygen atom or a sulfur atom, in addition to the nitrogen atom forming the amino group.

A preferable example of the organic group having an amino group is a group represented by the Following formula (A1).

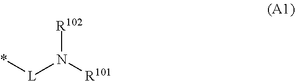

where in Formula (A1), R¹⁰¹ and R¹⁰² each independently represent a hydrogen atom or a hydrocarbon group, and L represents an independently and optionally substituted alkylene group, and an asterisk * represents a bonding hand.

Examples of the hydrocarbon group include, but are not limited to, alkyl group and alkenyl group. Specific examples of the alkyl group and the alkenyl group are the same as those described above regarding R².

The alkylene group may be linear or branched, and the carbon atom number of the linear or branched alkylene group is ordinarily 1 to 10, preferably 1 to 5. Examples of the linear or branched alkylene group include linear alkylene groups such as methylene group, ethylene group, trimethylene group, tetramethylene group, pentamethylene group, hexamethylene group, heptamethylene group, octamethylene group, nonamethylene group, and decamethylene group.

Examples of the organic group having an amino group include, but are not limited to, amino group, aminomethyl group, aminoethyl group, dimethylaminoethyl group, and dimethylaminopropyl group.

### <<X in Formula (A-1)>>

Examples of the alkoxy group in X include the alkoxy groups exemplified in the description of R².

Examples of the halogen atom in X include the halogen atoms exemplified in the description of R².

The aralkyloxy group is a monovalent group derived by removing a hydrogen atom from a hydroxy group of aralkyl alcohol, and specific examples of the aralkyl group in the aralkyloxy group are the same as those described above.

The carbon atom number of the aralkyloxy group is not particularly limited, but may be, for example, 40 or less, preferably 30 or less, and more preferably 20 or less.

Specific examples of the aralkyloxy group include, but are not limited to, phenylmethyloxy group (benzyloxy group), 2-phenylethyleneoxy group, 3-phenyl-n-propyloxy group, 4-phenyl-n-butyloxy group, 5-phenyl-n-pentyloxy group, 6-phenyl n-hexyloxy group, 7-phenyl-n-heptyloxy group, 8-phenyl-n-octyloxy group, 9-phenyl-n-nonyloxy group, and 10-phenyl-n-decyloxy group.

The acyloxy group is a monovalent group derived by removing a hydrogen atom from a carboxyl group (—COOH) of a carboxylic acid compound, and examples of the acyloxy group typically include, but are not limited to, alkylcarbonyloxy group, arylcarbonyloxy group, or aralkylcarbonyloxy group, derived by removing a hydrogen atom from a carboxyl group of an alkyl carboxylic acid, an aryl carboxylic acid, or an aralkyl carboxylic acid. Specific examples of the alkyl group, aryl group, and aralkyl group in the alkyl carboxylic acid, aryl carboxylic acid, and aralkyl carboxylic acid are the same as those described above.

Specific examples of the acyloxy group include acyloxy group having 2 to 20 carbon atoms, for example, methylcarbonyloxy group, ethylcarbonyloxy group, n-propylcarbonyloxy group, i-propylcarbonyloxy group, n-butylcarbonyloxy group, i-butylcarbonyloxy group, s-butylcarbonyloxy group, t-butylcarbonyloxy group, n-pentylcarbonyloxy group, 1-methyl-n-butylcarbonyloxy group, 2-methyl-n-butylcarbonyloxy group, 3-methyl-n-butylcarbonyloxy group, 1,1-dimethyl-n-propylcarbonyloxy group, 1,2-dimethyl-n-propylcarbonyloxy group, 2,2-dimethyl-n-propylcarbonyloxy group, 1-ethyl-n-propylcarbonyloxy group, n-hexylcarbonyloxy group, 1-methyl-n-pentylcarbonyloxy group, 2-methyl-n-pentylcarbonyloxy group, 3-methyl-n-pentylcarbonyloxy group, 4-methyl-n-pentylcarbonyloxy group, 1,1-dimethyl-n-butylcarbonyloxy group, 1,2-dimethyl-n-butylcarbonyloxy group, 1,3-dimethyl-n-butylcarbonyloxy group, 2,2-dimethyl-n-butylcarbonyloxy group, 2,3-dimethyl-n-butylcarbonyloxy group, 3,3-dimethyl-n-butylcarbonyloxy group, 1-ethyl-n-butylcarbonyloxy group, 2-ethyl-n-butylcarbonyloxy group, 1,1,2-trimethyl-n-propylcarbonyloxy group, 1,2,2-trimethyl-n-propylcarbonyloxy group, 1-ethyl-1-methyl-n-propylcarbonyloxy group, 1-ethyl-2-methyl-n-propylcarbonyloxy group, phenylcarbonyloxy group, and tosylcarbonyloxy group.

Specific examples of the hydrolyzable silane (A) represented by Formula (A-1) include the following compounds, but the hydrolyzable silane (A) represented by Formula (A-1) is not limited to these compounds.

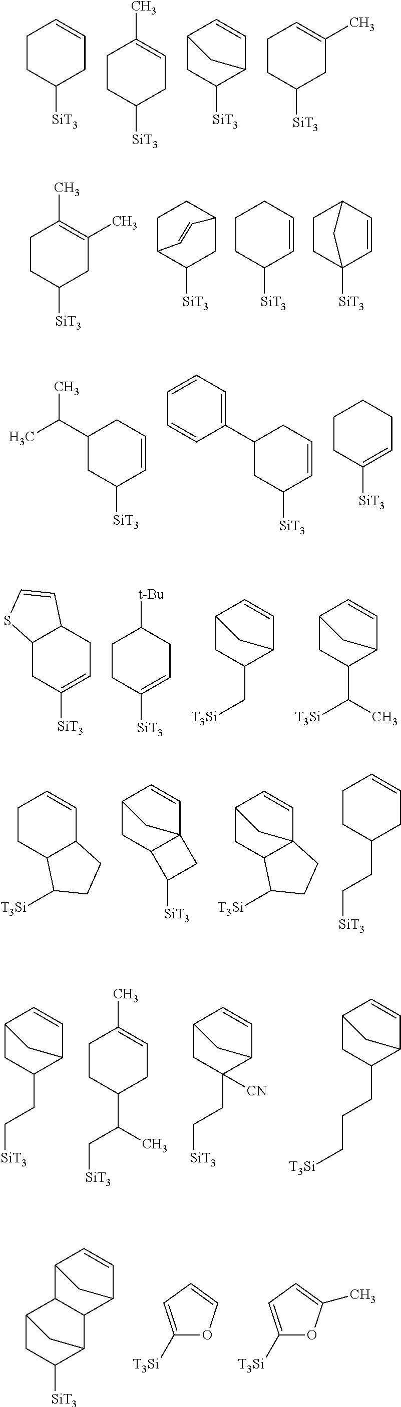

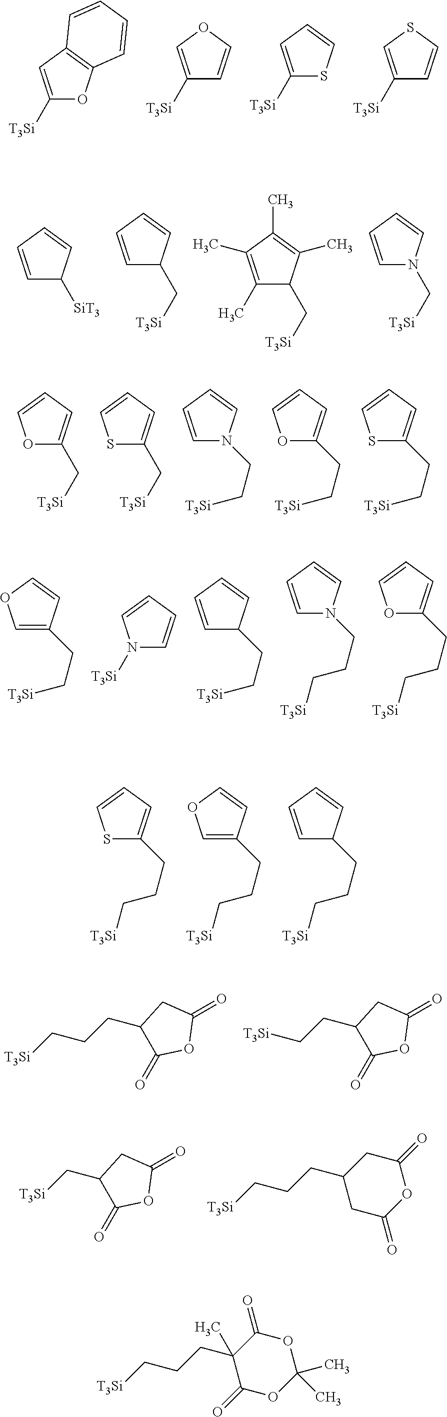

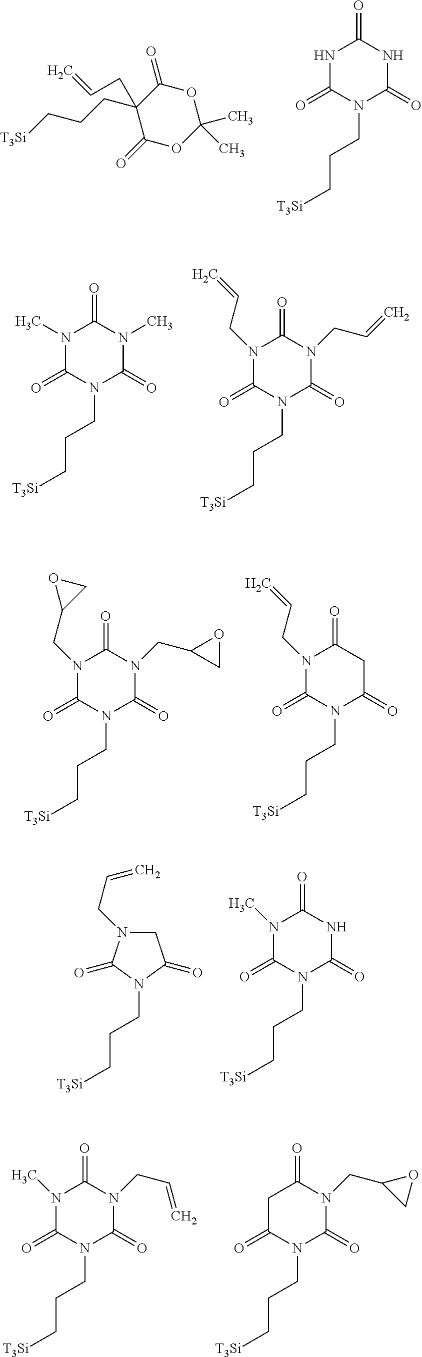

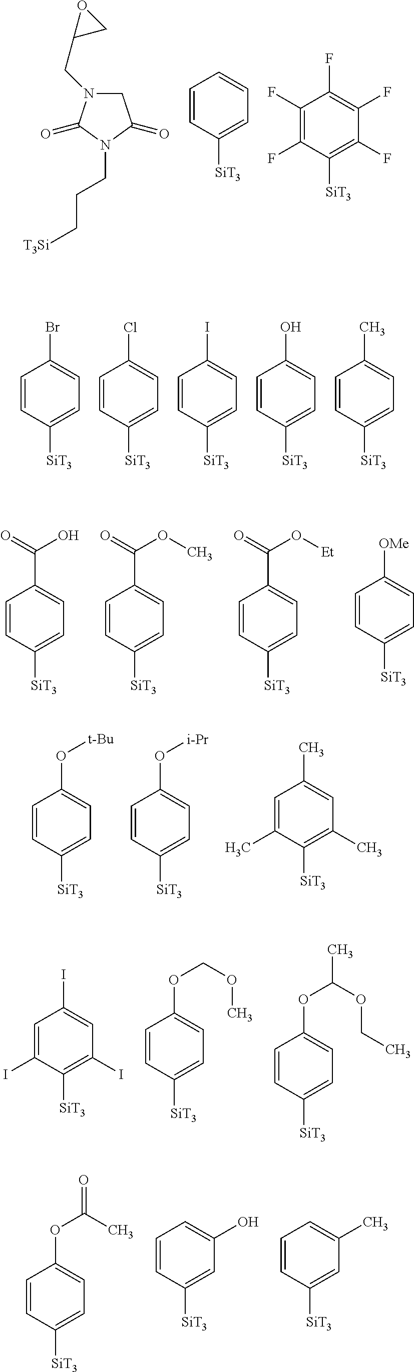

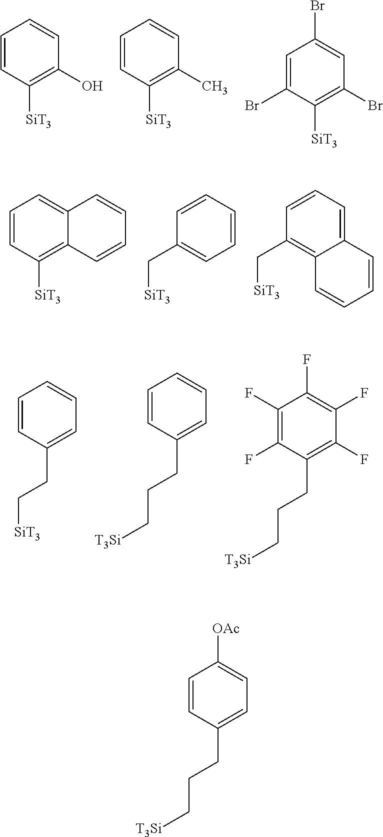

where T represents X in Formula (A-1), T represents, for example, a methoxy group or an ethoxy group, and Me represents a methyl group, Et represents an ethyl group, Pr represents a propyl group, Bu represents a butyl group, and Ac represents an acetyl group.

In the first embodiment, the amount of the hydrolyzable silane (A) in synthesizing the polysiloxane containing the structural unit derived from the hydrolyzable silane (A) represented by Formula (A-1) [A] is preferably 0.01 to 100 parts by mass, more preferably 0.05 to 50 parts by mass, still more preferably 0.1 to 30 parts by mass, and particularly preferably 1 to 20 parts by mass, relative to 100 parts by mass of the total amount of the hydrolyzable silane used for synthesizing the polysiloxane, from the viewpoint of more sufficiently achieving the effects of the present invention.

In the second embodiment, the content of the hydrolyzable silane (A) represented by Formula (A-1) as the component [B] in the silicon-containing resist underlayer film-forming composition is preferably 0.01 to 100 parts by mass, more preferably 0.05 to 50 parts by mass, still more preferably 0.1 to 30 parts by mass, and particularly preferably 1 to 20 parts by mass, relative to 100 parts by mass of polysiloxane [A′], from the viewpoint of more sufficiently achieving the effects of the present invention.

### <Component [A] and Component [A′]: Polysiloxane>

The polysiloxane as the component [A] is not particularly limited as long as it contains the structural unit derived from the hydrolyzable silane (A) represented by Formula (A-1) and is a polymer having a siloxane bond.

The polysiloxane as the component [A′] is not particularly limited as long as it is a polymer having a siloxane bond. The polysiloxane as the component [A′] may be the polysiloxane as the component [A].

The polysiloxane may be a modified polysiloxane in which some of silanol groups are modified, for example, a modified polysiloxane in which some of silanol groups are alcohol-modified or acetal-protected.

Further, the polysiloxane may be, as an example, a hydrolysis condensate of a hydrolyzable silane, or may be a modified product in which at least some of silanol groups of the hydrolysis condensate are alcohol-modified or acetal-protected (hereinafter, may be referred to as “modified product of hydrolysis condensate”). The hydrolyzable silane corresponding to the hydrolysis condensate may contain one or two or more hydrolyzable silanes.

Further, the polysiloxane as the component [A] or [A′] may have a structure having a cage-shaped, ladder-shaped, linear, or branched main chain. Furthermore, the polysiloxane as the component [A′] to be used may be a commercially available polysiloxane.

In the present invention, the “hydrolysis condensate”, i.e. product of hydrolysis condensation, of the hydrolyzable silane includes a polyorganosiloxane polymer which is a condensate prepared through complete condensation, and a polyorganosiloxane polymer which is a partial hydrolysis condensate prepared through incomplete condensation. Such a partial hydrolysis condensate is a polymer prepared through hydrolysis and condensation of a hydrolyzable silane compound, as in the case of a condensate prepared through complete condensation. However, the partial hydrolysis condensate contains remaining Si—OH groups, due to partial or incomplete hydrolysis and condensation of the silane compound. Further, the silicon-containing resist underlayer film-forming composition may contain an uncondensed hydrolysate (complete hydrolysate or partial hydrolysate) or a remaining monomer (hydrolyzable silane), in addition to the hydrolysis condensate.

In the present specification, the “hydrolyzable silane” may be simply referred to as “silane compound”.

The polysiloxane as the component [A] may be, for example, a hydrolysis condensate of a hydrolyzable silane containing the hydrolyzable silane (A) represented by Formula (A-1) or a modified product of the hydrolysis condensate.

The polysiloxane as the component [A] may be, for example, a hydrolysis condensate of a hydrolyzable silane containing the hydrolyzable silane (A) represented by Formula (A-1) and at least one hydrolyzable silane represented by the following Formula (1) or a modified product of the hydrolysis condensate.

The polysiloxane as the component [A′] may be, for example, a hydrolysis condensate of a hydrolyzable silane containing at least one hydrolyzable silane represented by the following Formula (1) or a modified product of the hydrolysis condensate.

<<Formula (1)>>

R¹ₐSi(R²)₄₋ₐ (1)

In Formula (1), R¹ is a group bonded to a silicon atom, and each independently represents an optionally substituted alkyl group, an optionally substituted alkyl halide, an optionally substituted alkoxyalkyl group, or an optionally substituted alkenyl group, or represents an organic group having an epoxy group, an organic group having an acryloyl group, an organic group having a methacryloyl group, an organic group having a mercapto group, an organic group having an amino group, an organic group having an alkoxy group, an organic group having a sulfonyl group, or an organic group having a cyano group, or a combination of two or more of the groups.

R² is a group or atom bonded to a silicon atom, and each independently represents an alkoxy group, an aralkyloxy group, an acyloxy group, or a halogen atom.
a represents an integer of 0 to 3.

Specific examples of the groups and atoms of R¹ in Formula (1) and preferred carbon atom numbers thereof are the same as the groups and atoms described above regarding R² in Formula (A-1).

Specific examples of the groups and atoms of R² in Formula (1) and preferred carbon atom numbers thereof are the same as the groups and atoms and the carbon atom numbers described above regarding X in Formula (A-1).

### <<<Specific Example of Hydrolyzable Silane Represented by Formula (1)>>>

Specific examples of the hydrolyzable silane represented by Formula (1) include, but are not limited to, tetramethoxysilane, tetrachlorosilane, tetraacetoxysilane, tetraethoxysilane, tetra-n-propoxysilane, tetra-i-propoxysilane, tetra-n-butoxysilane, methyltrimethoxysilane, methyltrichlorosilane, methyltriacetoxysilane, methyltriethoxysilane, methyltripropoxysilane, methyltributoxysilane, methyltriamyloxysilane, methyltriphenoxysilane, methyltribenzyloxysilane, methyltriphenethyloxysilane, glycidoxymethyltrimethoxysilane, glycidoxymethyltriethoxysilane, α-glycidoxyethyltrimethoxysilane, α-glycidoxyethyltriethoxysilane, β-glycidoxyethyltrimethoxysilane, β-glycidoxyethyltriethoxysilane, α-glycidoxypropyltrimethoxysilane, α-glycidoxypropyltriethoxysilane, β-glycidoxypropyltrimethoxysilane, β-glycidoxypropyltriethoxysilane, γ-glycidoxypropyltrimethoxysilane, γ-glycidoxypropyltriethoxysilane, γ-glycidoxypropyltripropoxysilane, γ-glycidoxypropyltributoxysilane, γ-glycidoxypropyltriphenoxysilane, α-glycidoxybutyltrimethoxysilane, α-glycidoxybutyltriethoxysilane, β-glycidoxybutyltriethoxysilane, γ-glycidoxybutyltrimethoxysilane, γ-glycidoxybutyltriethoxysilane, 5-glycidoxybutyltrimethoxysilane, 5-glycidoxybutyltriethoxysilane, (3,4-epoxycyclohexyl)methyltrimethoxysilane, (3,4-epoxycyclohexyl)methyltriethoxysilane, β-(3,4-epoxycyclohexyl)ethyltrimethoxysilane, β-(3,4-epoxycyclohexyl)ethyltriethoxysilane, β-(3,4-epoxycyclohexyl)ethyltripropoxysilane, β-(3,4-epoxycyclohexyl)ethyltributoxysilane, β-(3,4-epoxycyclohexyl)ethyltriphenoxysilane, γ-(3,4-epoxycyclohexyl)propyltrimethoxysilane, γ-(3,4-epoxycyclohexyl)propyltriethoxysilane, 5-(3,4-epoxycyclohexyl)butyltrimethoxysilane, 5-(3,4-epoxycyclohexyl)butyltriethoxysilane, glycidoxymethylmethyldimethoxysilane, glycidoxymethylmethyldiethoxysilane, α-glycidoxyethylmethyldimethoxysilane, α-glycidoxyethylmethyldiethoxysilane, β-glycidoxyethylmethyldimethoxysilane, β-glycidoxyethylethyldimethoxysilane, α-glycidoxypropylmethyldimethoxysilane, α-glycidoxypropylmethyldiethoxysilane, β-glycidoxypropylmethyldimethoxysilane, β-glycidoxypropylethyldimethoxysilane, γ-glycidoxypropylmethyldimethoxysilane, γ-glycidoxypropylmethyldiethoxysilane, γ-glycidoxypropylmethyldipropoxysilane, γ-glycidoxypropylmethyldibutoxysilane, γ-glycidoxypropylmethyldiphenoxysilane, γ-glycidoxypropylethyldimethoxysilane, γ-glycidoxypropylethyldiethoxysilane, γ-glycidoxypropylvinyldimethoxysilane, γ-glycidoxypropylvinyldiethoxysilane, ethyltrimethoxysilane, ethyltriethoxysilane, vinyltrimethoxysilane, vinyltriethoxysilane, vinyltrichlorosilane, vinyltriacetoxysilane, methylvinyldimethoxysilane, methylvinyldiethoxysilane, methylvinyldichlorosilane, methylvinyldiacetoxysilane, dimethylvinylmethoxysilane, dimethylvinylethoxysilane, dimethylvinylchlorosilane, dimethylvinylacetoxysilane, divinyldimethoxysilane, divinyldiethoxysilane, divinyldichlorosilane, divinyldiacetoxysilane, γ-glycidoxypropylvinyldimethoxysilane, γ-glycidoxypropylvinyldiethoxysilane, allyltrimethoxysilane, allyltriethoxysilane, allyltrichlorosilane, allyltriacetoxysilane, allylmethyldimethoxysilane, allylmethyldiethoxysilane, allylmethyldichlorosilane, allylmethyldiacetoxysilane, allyldimethylmethoxysilane, allyldimethylethoxysilane, allyldimethylchlorosilane, allyldimethylacetoxysilane, diallyldimethoxysilane, diallyldiethoxysilane, diallyldichlorosilane, diallyldiacetoxysilane, 3-allylaminopropyltrimethoxysilane, 3-allylaminopropyltriethoxysilane, p-styryltrimethoxysilane, phenyltrimethoxysilane, phenyltriethoxysilane, phenyltrichlorosilane, phenyltriacetoxysilane, phenylmethyldimethoxysilane, phenylmethyldiethoxysilane, phenylmethyldichlorosilane, phenylmethyldiacetoxysilane, phenyldimethylmethoxysilane, phenyldimethylethoxysilane, phenyldimethylchlorosilane, phenyldimethylacetoxysilane, diphenylmethylmethoxysilane, diphenylmethylethoxysilane, diphenylmethylchlorosilane, diphenylmethylacetoxysilane, diphenyldimethoxysilane, diphenyldiethoxysilane, diphenyldichlorosilane, diphenyldiacetoxysilane, triphenylmethoxysilane, triphenylethoxysilane, triphenylacetoxysilane, triphenylchlorosilane, 3-phenylaminopropyltrimethoxysilane, 3-phenylaminopropyltriethoxysilane, dimethoxymethyl-3-(3-phenoxypropylthiopropyl)silane, triethoxy((2-methoxy-4-(methoxymethyl)phenoxy)methyl)silane, benzyltrimethoxysilane, benzyltriethoxysilane, benzylmethyldimethoxysilane, benzylmethyldiethoxysilane, benzyldimethylmethoxysilane, benzyldimethylethoxysilane, benzyldimethylchlorosilane, phenethyltrimethoxysilane, phenethyltriethoxysilane, phenethyltrichlorosilane, phenethyltriacetoxysilane, phenethylmethyldimethoxysilane, phenethylmethyldiethoxysilane, phenethylmethyldichlorosilane, phenethylmethyldiacetoxysilane, methoxyphenyltrimethoxysilane, methoxyphenyltriethoxysilane, methoxyphenyltriacetoxysilane, methoxyphenyltrichlorosilane, methoxybenzyltrimethoxysilane, methoxybenzyltriethoxysilane, methoxybenzyltriacetoxysilane, methoxybenzyltrichlorosilane, methoxyphenethyltrimethoxysilane, methoxyphenethyltriethoxysilane, methoxyphenethyltriacetoxysilane, methoxyphenethyltrichlorosilane, ethoxyphenyltrimethoxysilane, ethoxyphenyltriethoxysilane, ethoxyphenyltriacetoxysilane, ethoxyphenyltrichlorosilane, ethoxybenzyltrimethoxysilane, ethoxybenzyltriethoxysilane, ethoxybenzyltriacetoxysilane, ethoxybenzyltrichlorosilane, i-propoxyphenyltrimethoxysilane, i-propoxyphenyltriethoxysilane, i-propoxyphenyltriacetoxysilane, i-propoxyphenyltrichlorosilane, i-propoxybenzyltrimethoxysilane, i-propoxybenzyltriethoxysilane, i-propoxybenzyltriacetoxysilane, i-propoxybenzyltrichlorosilane, t-butoxyphenyltrimethoxysilane, t-butoxyphenyltriethoxysilane, t-butoxyphenyltriacetoxysilane, t-butoxyphenyltrichlorosilane, t-butoxybenzyltrimethoxysilane, t-butoxybenzyltriethoxysilane, t-butoxybenzyltriacetoxysilane, t-butoxybenzyltrichlorosilane, methoxynaphthyltrimethoxysilane, methoxynaphthyltriethoxysilane, methoxynaphthyltriacetoxysilane, methoxynaphthyltrichlorosilane, ethoxynaphthyltrimethoxysilane, ethoxynaphthyltriethoxysilane, ethoxynaphthyltriacetoxysilane, ethoxynaphthyltrichlorosilane, γ-chloropropyltrimethoxysilane, γ-chloropropyltriethoxysilane, γ-chloropropyltriacetoxysilane, 3,3,3-trifluoropropyltrimethoxysilane, γ-methacryloxypropyltrimethoxysilane, γ-mercaptopropyltrimethoxysilane, γ-mercaptopropyltriethoxysilane, β-cyanoethyltriethoxysilane, thiocyanatepropyltriethoxysilane, chloromethyltrimethoxysilane, chloromethyltriethoxysilane, triethoxysilylpropyldiallylisocyanurate, bicyclo[2,2,1]heptenyltriethoxysilane, benzenesulfonylpropyltriethoxysilane, benzenesulfonamidepropyltriethoxysilane, dimethylaminopropyltrimethoxysilane, dimethyldimethoxysilane, phenylmethyldimethoxysilane, dimethyldiethoxysilane, phenylmethyldiethoxysilane, γ-chloropropylmethyldimethoxysilane, γ-chloropropylmethyldiethoxysilane, dimethyldiacetoxysilane, γ-methacryloxypropylmethyldimethoxysilane, γ-methacryloxypropylmethyldiethoxysilane, γ-mercaptopropylmethyldimethoxysilane, γ-mercaptomethyldiehoxysilane, methylvinyldimethoxysilane, methylvinyldiethoxysilane, and silanes of the following Formulae.

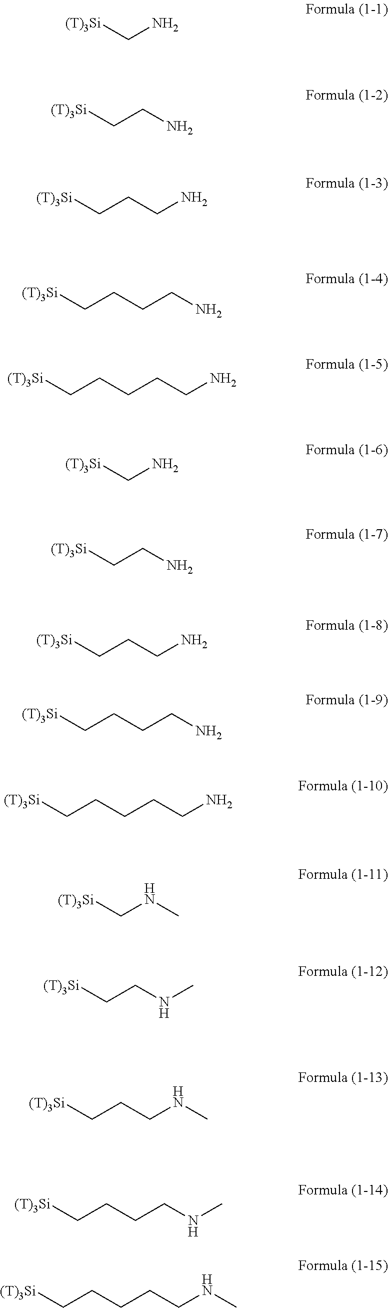

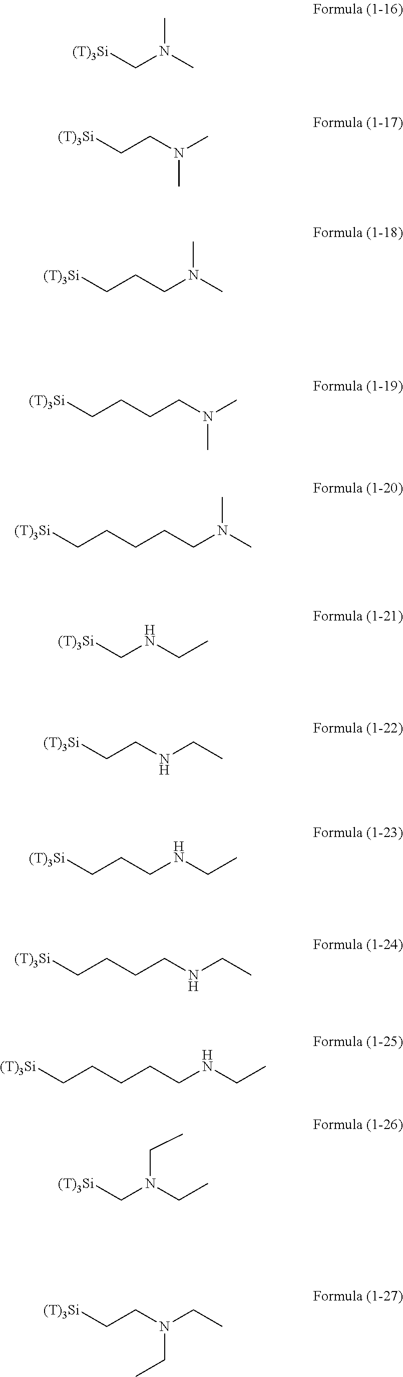

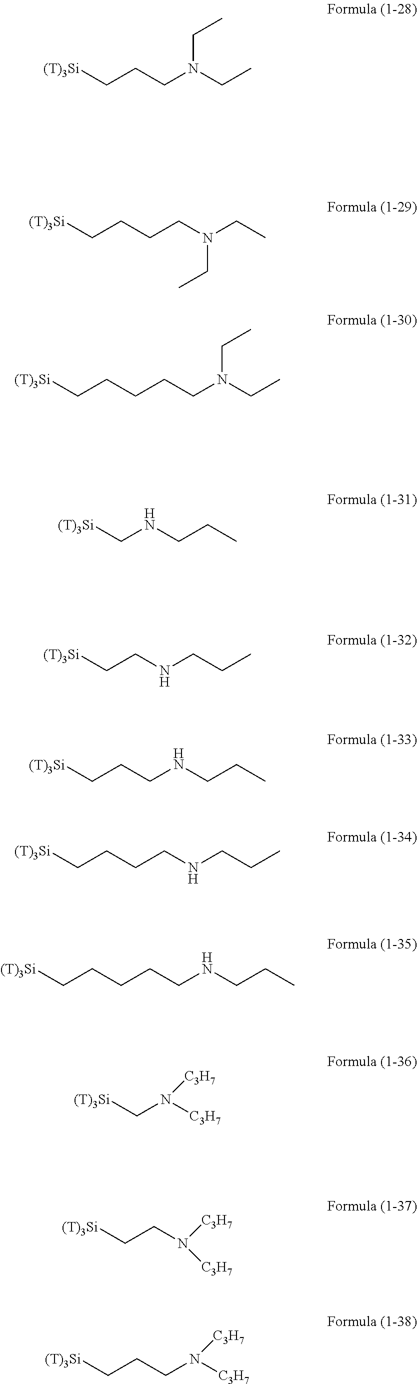

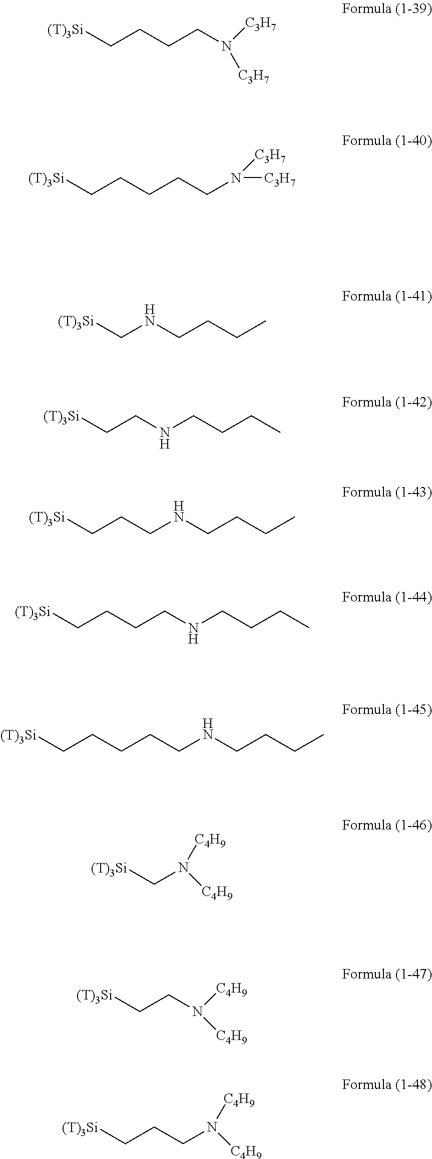

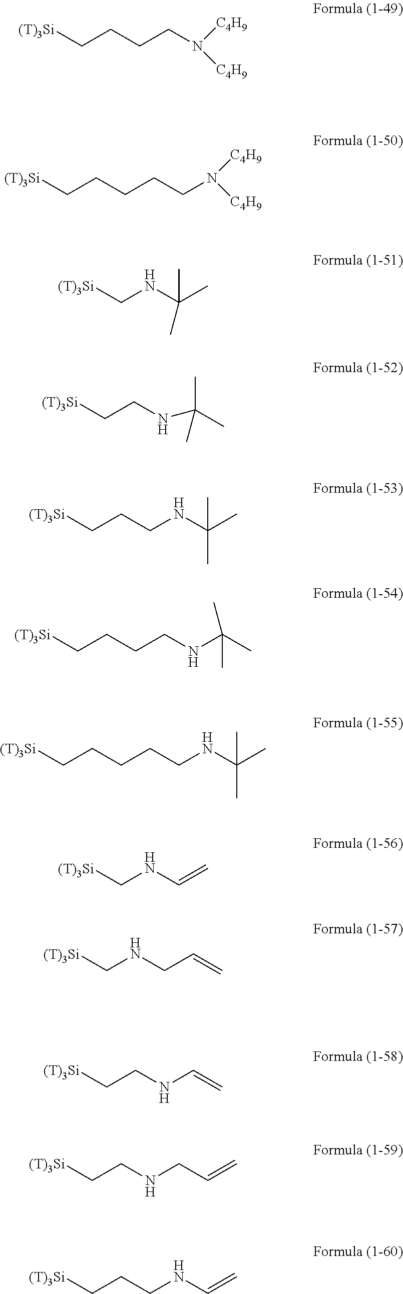

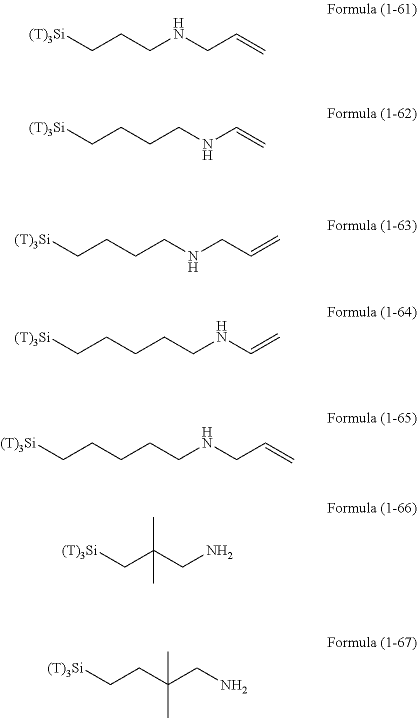

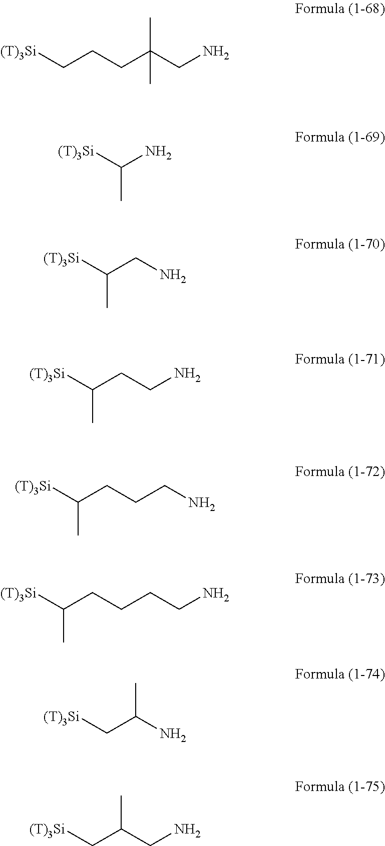

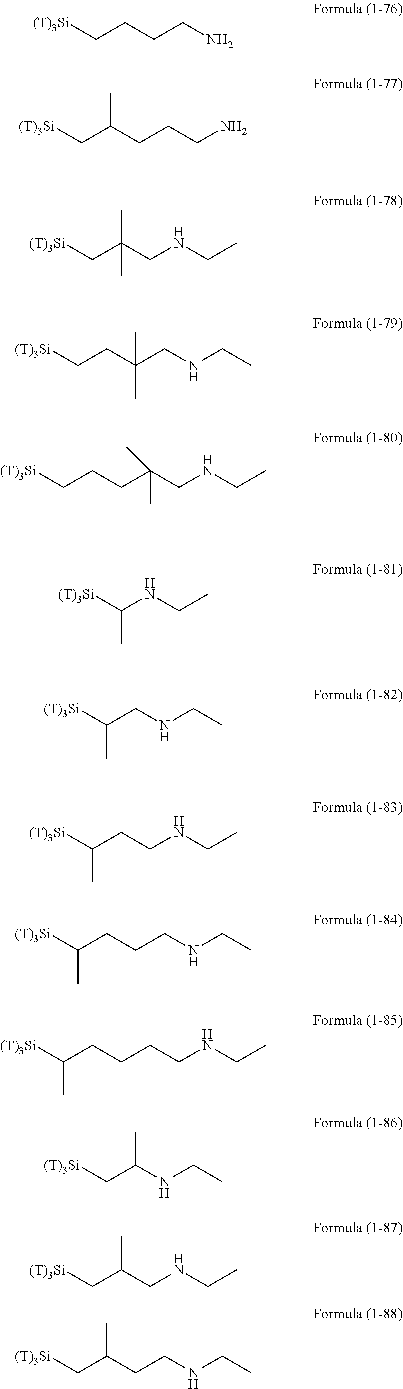

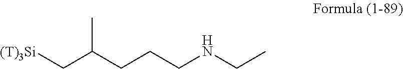

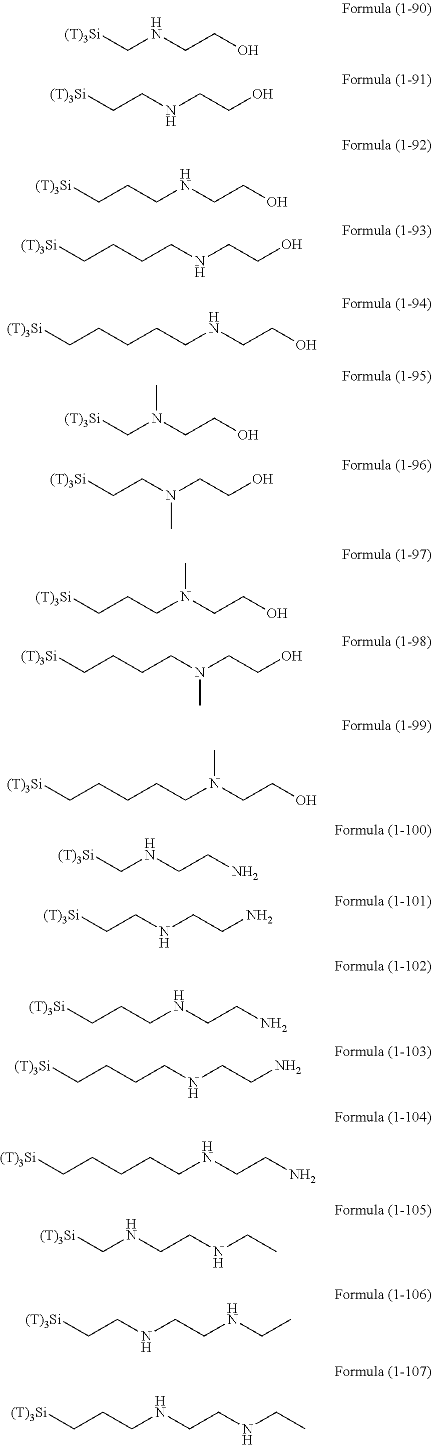

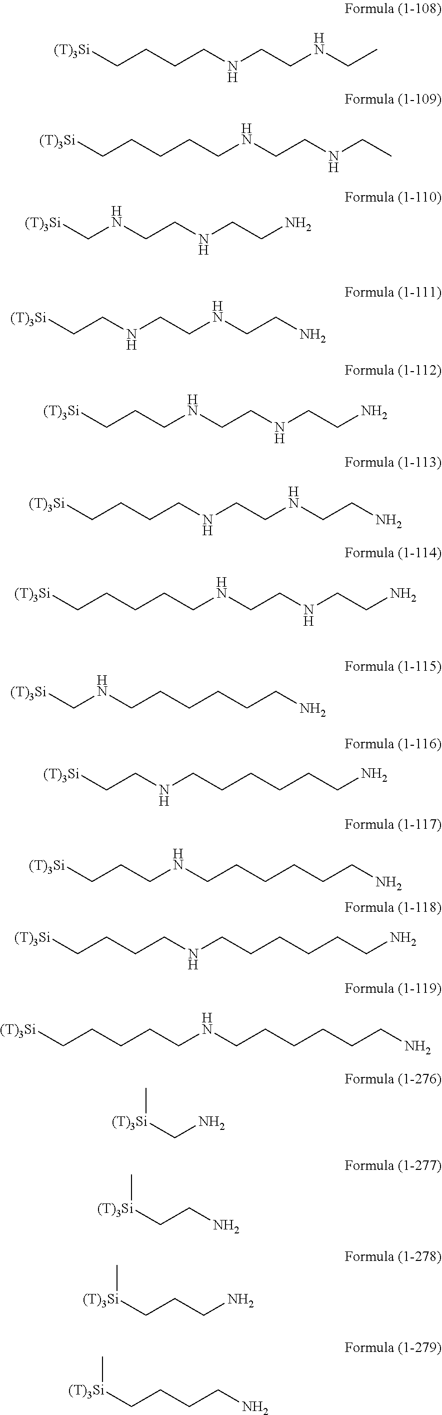

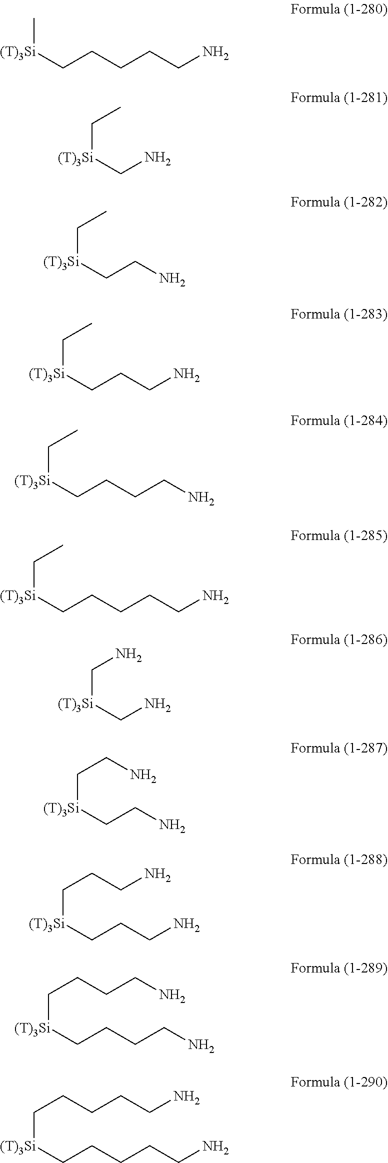

where Ts each independently represent an alkoxy group, an acyloxy group, or a halogen group, and represents preferably a methoxy group or an ethoxy group, for example.

The polysiloxane [A] may be, for example, a hydrolysis condensate of a hydrolyzable silane containing the hydrolyzable silane (A) represented by Formula (A-i) and a hydrolyzable silane represented by the following Formula (2) or a modified product of the hydrolysis condensate.

The polysiloxane [A] may be, for example, a hydrolysis condensate of a hydrolyzable silane containing the hydrolyzable silane (A) represented by Formula (A-1), a hydrolyzable silane represented by Formula (1), and a hydrolyzable silane represented by the following Formula (2), or a modified product of the hydrolysis condensate.

The polysiloxane [A′] may be, for example, a hydrolysis condensate of a hydrolyzable silane containing the hydrolyzable silane represented by the following Formula (2) together with the hydrolyzable silane represented by Formula (1) or in place of the hydrolyzable silane represented by Formula (1), or a modified product of the hydrolysis condensate.

<Formula (2)>

[symbol]

R³_{b}Si(R⁴)_{3-b} [symbol] ₂R⁵_{c} (2)

In Formula (2), R³ is a group bonded to a silicon atom, and each independently represents an optionally substituted alkyl group, an optionally substituted alkyl halide group, an optionally substituted alkoxyalkyl group, or an optionally substituted alkenyl group, or represents an organic group having an epoxy group, an organic group having an acryloyl group, an organic group having a methacryloyl group, an organic group having a mercapto group, an organic group having an amino group, an organic group having an alkoxy group, an organic group having a sulfonyl group, or an organic group having a cyano group, or a combination of two or more of the groups.

R⁴ is a group or atom bonded to a silicon atom, and each independently represents an alkoxy group, an aralkyloxy group, an acyloxy group, or a halogen atom.

R⁵ is a group bonded to a silicon atom, and each independently represents an alkylene group or an arylene group.

b represents 0 or 1, and c represents 0 or 1.

Specific examples of the groups and atoms of R³ and preferred carbon atom numbers thereof are the same as the groups and carbon atom numbers thereof described above regarding R² in Formula (A-1).

Specific examples of the groups and atoms of R⁴ and preferred carbon atom numbers thereof are the same as the groups and atoms and carbon atom numbers thereof described above regarding X in Formula (A-1).

Specific examples of the alkylene group in R⁵ include, but are not limited to, alkylene groups, for example, linear alkylene groups such as methylene group, ethylene group, trimethylene group, tetramethylene group, pentamethylene group, hexamethylene group, heptamethylene group, octamethylene group, nonamethylene group, decamethylene group; branched alkylene groups, such as 1-methyltrimethylene group, 2-methyltrimethylene group, 1,1-dimethylethylene group, 1-methyltetramethylene group, 2-methyltetramethylene group, 1,1-dimethyltrimethylene group, 1,2-dimethyltrimethylene group, 2,2-dimethyltrimethylene group, 1-ethyltrimethylene group; and alkanetriyl groups, such as methanetriyl group, ethane-1,1,2-triyl group, ethane-1,2,2-triyl group, ethane-2,2,2-triyl group, propane-1,1,1-triyl group; propane-1,1,2-triyl group, propane-1,2,3-triyl group, propane-1,2,2-triyl group, propane-1,1,3-triyl group, butane-1,1,1-triyl group, butane-1,1,2-triyl group, butane-1,1,3-triyl group, butane-1,2,3-triyl group, butane-1,2,4-triyl group, butane-1,2,2-triyl group, butane-2,2,3-triyl group, 2-methylpropane-1,1,1-triyl group, 2-methylpropane-1,1,2-triyl group, and 2-methylpropane-1,1,3-triyl group.

Specific examples of the arylene group in R⁵ include, but are not limited to, 1,2-phenylene group, 1,3-phenylene group, 1,4-phenylene group; groups derived from a condensed-ring aromatic hydrocarbon compound through removal of two hydrogen atoms on the aromatic ring, such as 1,5-naphthalenediyl group, 1,8-naphthalenediyl group, 2,6-naphthalenediyl group, 2,7-naphthalenediyl group, 1,2-anthracenediyl group, 1,3-anthracenediyl group, 1,4-anthracenediyl group, 1,5-anthracenediyl group, 1,6-anthracenediyl group, 1,7-anthracenediyl group, 1,8-anthracenediyl group, 2,3-anthracenediyl group, 2,6-anthracenediyl group, 2,7-anthracenediyl group, 2,9-anthracenediyl group, 2,10-anthracenediyl group, and 9,10-anthracenediyl group; and groups derived from a linked-ring aromatic hydrocarbon compound through removal of two hydrogen atoms on the aromatic ring, such as 4,4′-biphenyldiyl group and 4,4″-p-terphenyldiyl group.

b is preferably 0.

c is preferably 1.

Specific examples of the hydrolyzable silane represented by Formula (2) include, but are not limited to, methylenebistrimethoxysilane, methylenebistrichlorosilane, methylenebistriacetoxysilane, ethylenebistriethoxysilane, ethylenebistrichlorosilane, ethylenebistriacetoxysilane, propylenebistriethoxysilane, butylenebistrimethoxysilane, phenylenebistrimethoxysilane, phenylenebistriethoxysilane, phenylenebismethyldiethoxysilane, phenylenebismethyldimethoxysilane, naphthylenebistrimethoxysilane, bistrimethoxysilane, bistrimethoxydisilane, bistriethoxydisilane, bisethyldiethoxydisilane, and bismethyldimethoxydisilane.

The polysiloxane [A] may be, for example, a hydrolysis condensate of a hydrolyzable silane containing the hydrolyzable silane (A) represented by Formula (A-1), the hydrolyzable silane represented by Formula (1) and/or the hydrolyzable silane represented by Formula (2), and an additional hydrolyzable silane described below, or a modified product of the hydrolysis condensate.

The polysiloxane [A′] may be, for example, a hydrolysis condensate of a hydrolyzable silane containing the hydrolyzable silane represented by Formula (1) and/or the hydrolyzable silane represented by Formula (2), and an additional hydrolyzable silane described below, or a modified product of the hydrolysis condensate.

Examples of the additional hydrolyzable silane include, but are not limited to, silane compounds having an onium group in the molecule.

### <<Silane Compound Having Onium Group in Molecule (Hydrolyzable Organosilane)>>

A silane compound having an onium group in the molecule is expected to effectively and efficiently promote the crosslinking reaction of a hydrolyzable silane.

One preferred example of the silane compound having an onium group in the molecule is shown in the following Formula (3).

R¹¹_{f}R¹²_{g}Si(R¹³)_{4-(f+g)} (3)

R¹¹ is a group bonded to a silicon atom, and represents an onium group or an organic group having the onium group.
R¹² is a group bonded to a silicon atom, and each independently represents an optionally substituted alkyl group, an optionally substituted alkyl halide group, an optionally substituted alkoxyalkyl group or an optionally substituted alkenyl group, or represents an organic group having an epoxy group, an organic group having an acryloyl group, an organic group having a methacryloyl group, an organic group having a mercapto group, an organic group having an amino group, or an organic group having a cyano group, or a combination of two or more of the groups.
R¹³ is a group or atom bonded to a silicon atom, and each independently represents an alkoxy group, an aralkyloxy group, an acyloxy group, or a halogen atom.
f represents 1 or 2, g represents 0 or 1, and 1 f+g≤2 is satisfied.

Specific examples of the alkyl group, the alkyl halide group, the alkoxyalkyl group, the alkenyl group, and the organic group having an epoxy group, the organic group having an acryloyl group, the organic group having a methacryloyl group, the organic group having a mercapto group, the organic group having an amino group, the organic group having a cyano group, the alkoxy group, the aralkyloxy group, the acyloxy group, and the halogen atom, and specific examples of the substituents of the alkyl group, the alkyl halide group, the alkoxyalkyl group, and the alkenyl group, and preferred carbon atom numbers thereof are the same as those described above regarding R² in Formula (A-1)(for R¹²), and regarding X in Formula (A-1)(for R¹³).

More specifically, the onium group is, for example, a cyclic ammonium group or a chain ammonium group, and is preferably a tertiary ammonium group or a quaternary ammonium group.

That is, preferred specific examples of the onium group or the organic group having the onium group include a cyclic ammonium group, a chain ammonium group, or an organic group containing at least one of the cyclic ammonium group or the chain ammonium group. Preferred is a tertiary ammonium group or a quaternary ammonium group or an organic group containing at least one of the tertiary ammonium group or the quaternary ammonium group.

When the onium group is a cyclic ammonium group, a nitrogen atom forming the ammonium group also serves as an atom constituting the ring. In this case, the nitrogen atom forming the ring and the silicon atom are bonded directly or via a divalent linking group, or the carbon atom forming the ring and the silicon atom are bonded directly or via a divalent linking group.

In one preferred aspect, R¹¹, i.e. the group bonding to the silicon atom in Formula (3), may be a heteroaliphatic cyclic ammonium group represented by the following Formula (S2).

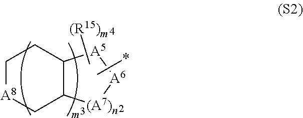

In Formula (S2), A⁵, A⁶, A⁷, and A⁸ each independently represent a group represented by any one of the following Formulae (J4) to (J6), and at least one of A⁵ to A⁸ represents a group represented by the following Formula (J5). Depending on to which atom of A⁵ to A⁸ a silicon atom in Formula (3) is bonded, it is determined whether a bond between any one of A⁵ to A⁸ and a ring-forming atom adjacent to the any one is a single bond or a double bond so that the ring to be formed exhibits non-aromaticity. An asterisk * represents a bonding hand.

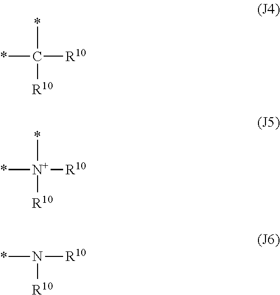

In Formulae (J4) to (J6), R¹⁰ each independently represents a single bond, a hydrogen atom, an alkyl group, or an alkyl halide group. Specific examples of the alkyl group, the alkyl halide group, and preferred carbon atom numbers thereof are the same as those described above. Each asterisk * represents a bonding hand.

In Formula (S2), R¹⁵ each independently represents an alkyl group, an alkyl halide group, or a hydroxy group. When two or more of R¹⁵s are present, the two R¹⁵s may be bonded together to form a ring, and the ring formed by the two R¹⁵s may have a crosslinked ring structure. In such a case, the cyclic ammonium group has an adamantane ring, a spiro ring, or the like.

Specific examples of the alkyl group, the alkyl halide group, and preferred carbon atom numbers thereof are the same as those described above.

In Formula (S2), n² is an integer of 1 to 8, m³ is 0 or 1, and m⁴ is 0 or a positive integer ranging from 1 to the possible maximum number being substituted on a monocyclic or polycyclic ring.

When m³ is 0, a (4+n²)-membered ring including A⁵ to A⁸ is formed. That is, when n² is 1, a 5-membered ring is formed; when n² is 2, a 6-membered ring is formed; when n² is 3, a 7-membered ring is formed; when n² is 4, an 8-membered ring is formed; when n² is 5, a 9-membered ring is formed; when n² is 6, a 10-membered ring is formed; when n² is 7, a 11-membered ring is formed; and when n² is 8, a 12-membered ring is formed.

When m³ is 1, a condensed ring is formed by condensation between a (4+n²)-membered ring including A⁵ to A⁷ and a 6-membered ring including A⁸.

Since each of A⁵ to A⁸ is any of the groups of Formulae (J4) to (J6), the ring-forming atom has or does not have a hydrogen atom. In each of A⁵ to A⁸, when the ring-forming atom has a hydrogen atom, the hydrogen atom may be substituted with R¹⁵. Alternatively, a ring-forming atom other than the ring-forming atom in each of A⁵ to A⁸ may be substituted with R¹.

Because of such circumstances, as described above, m⁴ is selected from 0 or an integer ranging from 1 to the possible maximum number being substituted on a monocyclic or polycyclic ring.

The bonding hand of the heteroaliphatic cyclic ammonium group represented by Formula (S2) is present on any carbon atom or nitrogen atom present in such a monocyclic ring or condensed ring, and is directly bonded to a silicon atom. Alternatively, the bonding hand is bonded to a linking group to form an organic group containing the cyclic ammonium group, and the organic group is bonded to a silicon atom.

Examples of the linking group include an alkylene group, and specific examples of the alkylene group and preferred carbon atom numbers thereof are the same as those described above.

Specific examples of the silane compound (hydrolyzable organosilane) represented by Formula (3) having the heteroaliphatic cyclic ammonium group represented by Formula (S2) include, but are not limited to, silanes represented by the following Formula.

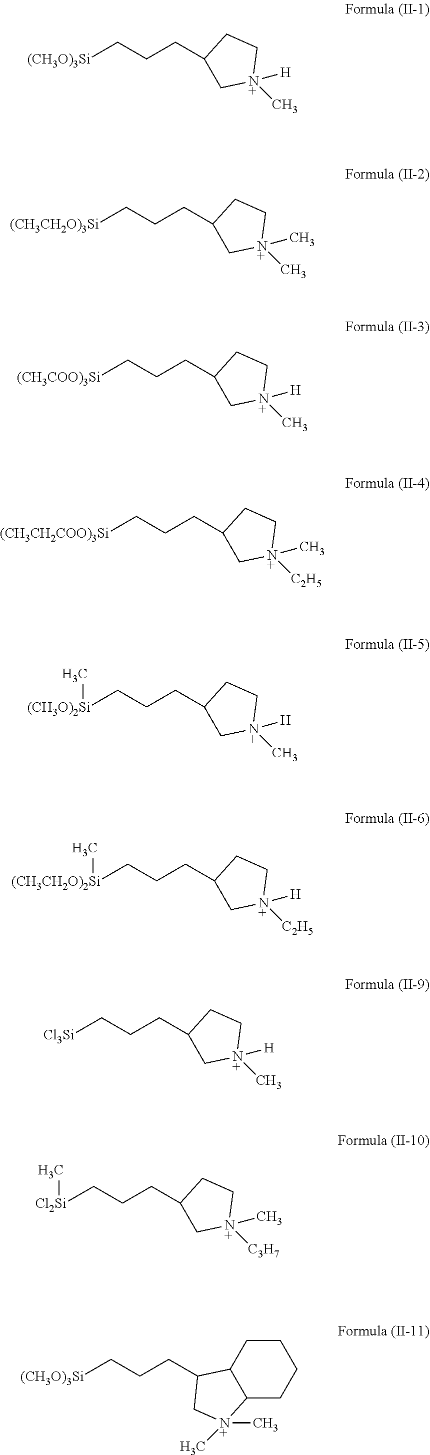

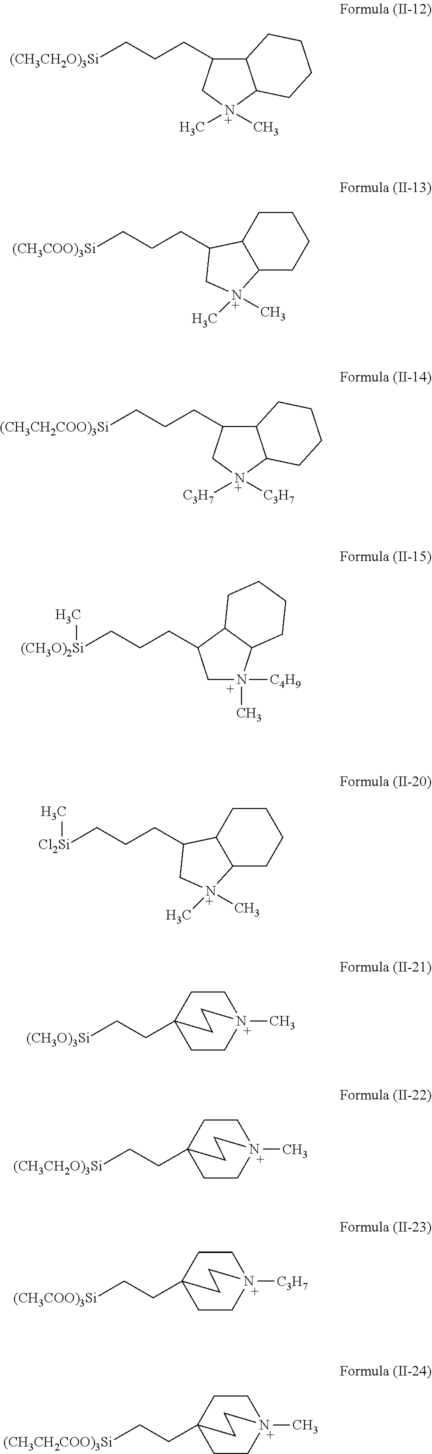

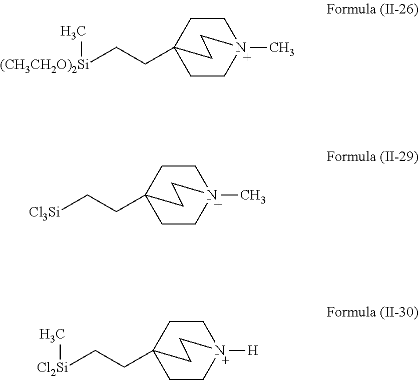

In another example, R¹¹, i.e. the group bonding to the silicon atom in Formula (3), may be a chain ammonium group represented by the following Formula (S3).

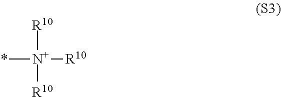

In Formula (S3), R¹⁰ each independently represents a hydrogen atom, an alkyl group, an alkyl halide group, or an alkenyl group. Specific examples of the alkyl group, the alkyl halide, the alkenyl group, and preferred carbon atom numbers thereof are the same as those described above. an asterisk * represents a bonding hand.

The chain ammonium group represented by Formula (S3) is directly bonded to a silicon atom. Alternatively, the chain ammonium group is bonded to a linking group to form an organic group containing the chain ammonium group, and the organic group is bonded to a silicon atom.

The linking group is, for example, an alkylene group or an alkenylene group. Specific examples of the alkylene group and the alkenylene group are the same as those as described above.

Specific examples of the silane compound (hydrolyzable organosilane) represented by Formula (3) having the chain ammonium group represented by Formula (S3) include, but are not limited to, silanes represented by the following Formula.

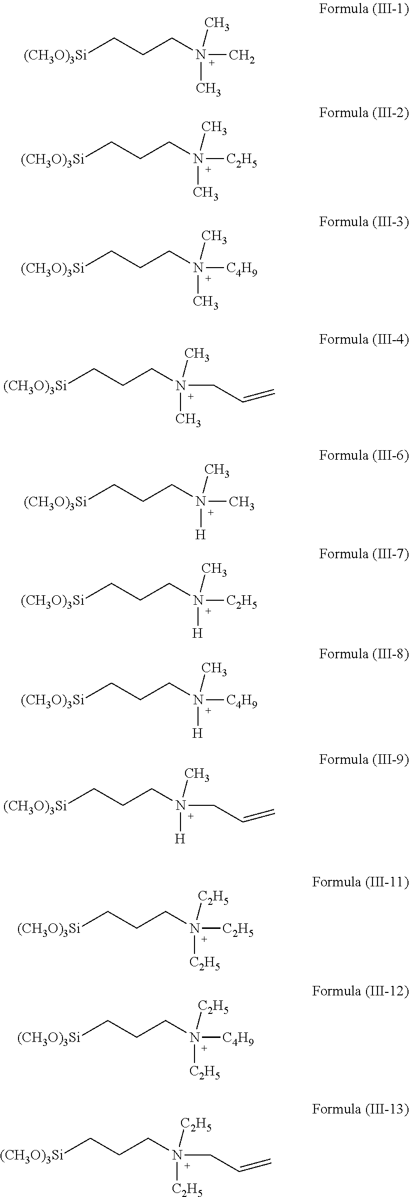

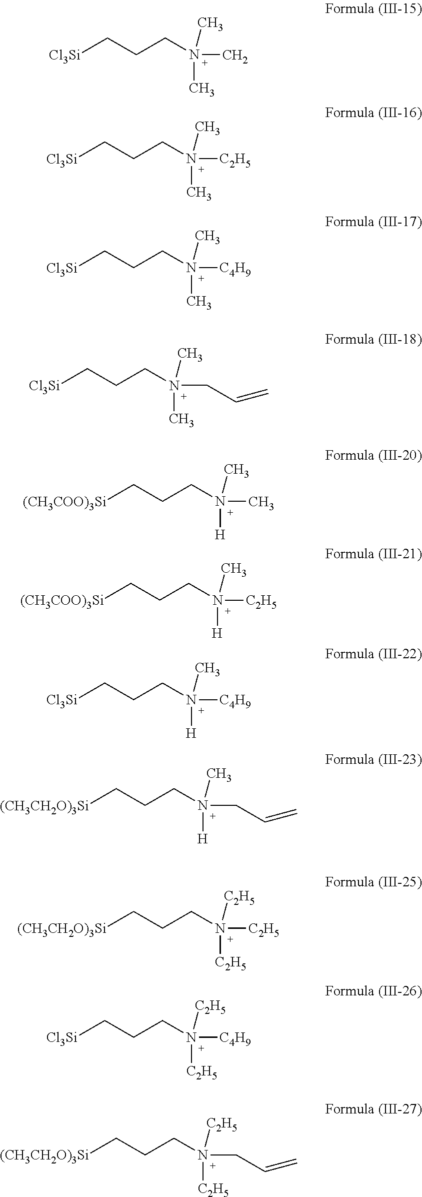

The polysiloxane [A] and the polysiloxane [A′] may be a hydrolysis condensate of a hydrolyzable silane containing a silane compound other than those exemplified above or a modified product of the hydrolysis condensate as long as the effects of the present invention are not impaired.

As described above, as the polysiloxane [A] and the polysiloxane [A′], a modified product in which at least some of silanol groups of the hydrolysis condensate are modified can be used. For example, a modified product in which at least some of silanol groups are alcohol-modified or acetal-protected can be used.

Examples of the polysiloxane as the modified product include a product prepared by a reaction between at least some of silanol groups of the above-described hydrolysis condensate of hydrolyzable silane and a hydroxy group of an alcohol, a product prepared by dehydration reaction between the condensate and an alcohol, and a modified product prepared by protection of at least some of silanol groups of the condensate with an acetal group.

As the alcohol, a monohydric alcohol can be used. Examples of the monohydric alcohol include methanol, ethanol, 2-propanol, 1-butanol, 2-butanol, isobutyl alcohol, tert-butyl alcohol, 1-pentanol, 2-pentanol, 3-pentanol, 1-heptanol, 2-heptanol, tert-amyl alcohol, neopentyl alcohol, 2-methyl-1-propanol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-diethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, and cyclohexanol.

For example, alkoxy group-containing alcohols such as 3-methoxybutanol, ethylene glycol monomethyl ether, ethylene glycol monoethyl ether, diethylene glycol monomethyl ether, diethylene glycol monoethyl ether, propylene glycol monomethyl ether (1-methoxy-2-propanol), propylene glycol monoethyl ether (1-ethoxy-2-propanol), and propylene glycol monobutyl ether (1-butoxy-2 propanol) can be used.

The reaction between silanol groups of the hydrolysis condensate and hydroxy groups of the alcohol is performed by bringing the hydrolysis condensate in to contact with the alcohol. A modified product containing capped silanol groups is prepared by performing the reaction at a temperature of 40 to 160° C. (e.g. 60° C.) for 0.1 to 48 hours (e.g. 24 hours). In this case, the alcohol serving as a capping agent may be used as a solvent in the composition containing the polysiloxane.

The product by dehydration reaction between the hydrolysis condensate of hydrolyzable silane and the alcohol can be produced by reacting the hydrolysis condensate with the alcohol in the presence of an acid as a catalyst, capping silanol groups with the alcohol, and removing water generated through the dehydration to the outside of the reaction system.

The acid may be an organic acid having an acid dissociation constant (pka) of −1 to 5, preferably 4 to 5. Examples of the acid include trifluoroacetic acid, maleic acid, benzoic acid, isobutyric acid, and acetic acid. In particular, benzoic acid, isobutyric acid, and acetic acid can be exemplified.

As the acid, an acid having a boiling point of 70 to 160° C. may be used. Examples of the acid include trifluoroacetic acid, isobutyric acid, acetic acid, and nitric acid.

Preferably, the acid described above has either an acid dissociation constant (pka) of 4 to 5 or a boiling point of 70 to 160° C. That is, the acid to be used may be an acid having a weak acidity, or an acid having a strong acidity and a low boiling point.

Either of these properties: acid dissociation constant and boiling point of the acid may be utilized.

The acetal protection of silanol groups of the hydrolysis condensate can be performed with a vinyl ether; for example, a vinyl ether represented by the following Formula (5). Such a reaction can be performed to introduce a partial structure represented by the following Formula (6) into the polysiloxane.

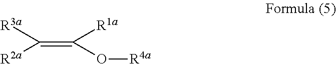

In Formula (5), R^{1a}, R^{2a}, and R^{3a} each represent a hydrogen atom or an alkyl group having 1 to 10 carbon atoms, R^{4a} represents an alkyl group having 1 to 10 carbon atoms, and R^{2a} and R^{4a} may be bonded together to form a ring. Examples of the alkyl group are the same as those described above.

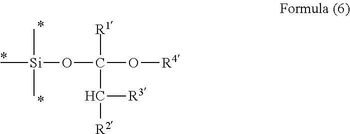

In Formula (6), R^{1′}, R^{2′}, and R^{3′} each represent a hydrogen atom or an alkyl group having 1 to 10 carbon atoms, R^{4′} represents an alkyl group having 1 to 10 carbon atoms, and R^{2′} and R^{4′} may be bonded together to form a ring. In Formula (6), * represents a bond to an adjacent atom. The adjacent atom is, for example, an oxygen atom of a siloxane bond, an oxygen atom of a silanol group, or a carbon atom derived from R¹ of Formula (1). Examples of the alkyl group are the same as those described above.

As the vinyl ether represented by Formula (5), for example, aliphatic vinyl ether compounds, such as methyl vinyl ether, ethyl vinyl ether, isopropyl vinyl ether, normal butyl vinyl ether, 2-ethylhexyl vinyl ether, tert-butyl vinyl ether, and cyclohexyl vinyl ether; and cyclic vinyl ether compounds, such as 2,3-dihydrofuran, 4-methyl-2,3-dihydrofuran, and 3,4-dihydro-2H-pyran, may be used. In particular, ethyl vinyl ether, propyl vinyl ether, butyl vinyl ether, ethylhexyl vinyl ether, cyclohexyl vinyl ether, 3,4-dihydro-2H-pyran, or 2,3-dihydrofuran may be preferably used.

The acetal protection of silanol groups can be performed using a hydrolysis condensate, a vinyl ether, and an aprotic solvent such as propylene glycol monomethyl ether acetate, ethyl acetate, dimethylformamide, tetrahydrofuran, or 1,4-dioxane as a solvent, and a catalyst such as pyridium p-toluenesulfonate, trifluoromethanesulfonic acid, p-toluenesulfonic acid, methanesulfonic acid, hydrochloric acid, or sulfuric acid.

The capping of silanol groups with an alcohol or the acetal protection of silanol groups may be performed simultaneously with the hydrolysis and condensation of the hydrolyzable silane described below.

The hydrolysis condensate of hydrolyzable silane or a modified product of the hydrolysis condensate may have a weight-average molecular weight of, for example, 500 to 1,000,000. From the viewpoint of preventing the precipitation of the hydrolysis condensate or a modified product of the hydrolysis condensate in the composition, the weight-average molecular weight is preferably 500,000 or less, more preferably 250,000 or less, and still more preferably 100,000 or less. From the viewpoint of the compatibility between storage stability and application property, the weight-average molecular weight may be preferably 700 or more, more preferably 1,000 or more. The weight-average molecular weight is determined by GPC analysis in terms of polystyrene. The GPC analysis can be performed under the following conditions: GPC apparatus (trade name: HLC-8220GPC, manufactured by Tosoh Corporation), GPC columns (trade name: Shodex (registered trademark) KF803L, KF802, and KF801, manufactured by Showa Denko K.K.), column temperature of 40° C., tetrahydrofuran as an eluent (elution solvent), flow amount (flow rate) of 1.0 mL/min, and polystyrene (Shodex (registered trademark) manufactured by Showa Denko K.K.) as a standard sample.

The hydrolysis condensate of hydrolyzable silane is prepared by hydrolysis and condensation of the above-described silane compound (hydrolyzable silane).

The above-described silane compound (hydrolyzable silane) contains an alkoxy group, aralkyloxy group, acyloxy group, or halogen atom directly bonded to a silicon atom; i.e. an alkoxysilyl group, an aralkyloxysilyl group, an acyloxysilyl group, or a halogenated silyl group (hereinafter, such a group is referred to as “hydrolyzable group”).

For the hydrolysis of the hydrolyzable group, ordinarily 0.1 to 100 mol, for example, 0.5 to 100 mol, preferably 1 to 10 mol, of water is used per mol of the hydrolyzable group.

During hydrolysis and condensation, a hydrolysis catalyst may be used for the purpose of promoting the reaction. Alternatively, the hydrolysis and condensation may be performed without use of a hydrolysis catalyst. When a hydrolysis catalyst is used, the amount of the hydrolysis catalyst is ordinarily 0.0001 to 10 mol, preferably 0.001 to 1 mol per mol of the hydrolyzable group.

The reaction temperature for the hydrolysis and condensation is ordinarily equal to or higher than room temperature, or equal to or lower than the reflux temperature at normal pressure of an organic solvent usable for hydrolysis. The reaction temperature may be, for example, 20 to 110° C., or, for example, 20 to 80° C.

The hydrolysis may be performed completely; i.e. all hydrolyzable groups may be converted into silanol groups, or may be performed partially; i.e. unreacted hydrolyzable groups may remain.

Examples of the hydrolysis catalyst usable for the hydrolysis and condensation include a metal chelate compound, an organic acid, an inorganic acid, an organic base, and an inorganic base.

Examples of the metal chelate compound as the hydrolysis catalyst include, but are not limited to, titanium chelate compounds such as triethoxy-mono(acetylacetonate)titanium, tri-n-propoxy-mono(acetylacetonate)titanium, tri-i-propoxy-mono(acetylacetonate)titanium, tri-n-butoxy-mono(acetylacetonate)titanium, tri-sec-butoxy-mono(acetylacetonate)titanium, tri-t-butoxy-mono(acetylacetonate)titanium, diethoxy-bis(acetylacetonate)titanium, di-n-propoxy-bis(acetylacetonate)titanium, di-i-propoxy-bis(acetylacetonate)titanium, di-n-butoxy-bis(acetylacetonate)titanium, di-sec-butoxy-bis(acetylacetonate)titanium, di-t-butoxy-bis(acetylacetonate)titanium, monoethoxy-tris(acetylacetonate)titanium, mono-n-propoxy-tris(acetylacetonate)titanium, mono-i-propoxy-tris(acetylacetonate)titanium, mono-n-butoxy-tris(acetylacetonate)titanium, mono-sec-butoxy-tris(acetylacetonate)titanium, mono-t-butoxy-tris(acetylacetonate)titanium, tetrakis(acetylacetonate)titanium, triethoxy-mono(ethyl acetoacetate)titanium, tri-n-propoxy-mono(ethyl acetoacetate)titanium, tri-i-propoxy-mono(ethyl acetoacetate)titanium, tri-n-butoxy-mono(ethyl acetoacetate)titanium, tri-sec-butoxy-mono(ethyl acetoacetate)titanium, tri-t-butoxy-mono(ethyl acetoacetate)titanium, diethoxy-bis(ethyl acetoacetate)titanium, di-n-propoxy-bis(ethyl acetoacetate)titanium, di-i-propoxy-bis(ethyl acetoacetate)titanium, di-n-butoxy-bis(ethyl acetoacetate)titanium, di-sec-butoxy-bis(ethyl acetoacetate)titanium, di-t-butoxy-bis(ethyl acetoacetate)titanium, monoethoxy-tris(ethyl acetoacetate)titanium, mono-n-propoxy-tris(ethyl acetoacetate)titanium, mono-i-propoxy-tris(ethyl acetoacetate)titanium, mono-n-butoxy-tris(ethyl acetoacetate)titanium, mono-sec-butoxy-tris(ethyl acetoacetate)titanium, mono-t-butoxy-tris(ethyl acetoacetate)titanium, tetrakis(ethyl acetoacetate)titanium, mono(acetylacetonate)tris(ethyl acetoacetate)titanium, bis(acetylacetonate)bis(ethyl acetoacetate)titanium, and tris(acetylacetonate)mono(ethyl acetoacetate)titanium; zirconium chelate compounds such as triethoxy-mono(acetylacetonate)zirconium, tri-n-propoxy-mono(acetylacetonate)zirconium, tri-i-propoxy-mono(acetylacetonate)zirconium, tri-n-butoxy-mono(acetylacetonate)zirconium, tri-sec-butoxy-mono(acetylacetonate)zirconium, tri-t-butoxy-mono(acetylacetonate)zirconium, diethoxy-bis(acetylacetonate)zirconium, di-n-propoxy-bis(acetylacetonate)zirconium, di-i-propoxy-bis(acetylacetonate)zirconium, di-n-butoxy-bis(acetylacetonate)zirconium, di-sec-butoxy-bis(acetylacetonate)zirconium, di-t-butoxy-bis(acetylacetonate)zirconium, monoethoxy-tris(acetylacetonate)zirconium, mono-n-propoxy-tris(acetylacetonato)zirconium, mono-i-propoxy-tris(acetylacetonate)zirconium, mono-n-butoxy-tris(acetylacetonate)zirconium, mono-sec-butoxy-tris (acetylacetonate)zirconium, mono-t-butoxy-tris(acetylacetonate)zirconium, tetrakis(acetylacetonate)zirconium, triethoxy-mono(ethyl acetoacetate)zirconium, tri-n-propoxy-mono(ethyl acetoacetate)zirconium, tri-i-propoxy-mono(ethyl acetoacetate)zirconium, tri-n-butoxy-mono(ethyl acetoacetate)zirconium, tri-sec-butoxy-mono(ethyl acetoacetate)zirconium, tri-t-butoxy-mono(ethyl acetoacetate)zirconium, diethoxy-bis(ethyl acetoacetate)zirconium, di-n-propoxy-bis(ethyl acetoacetate)zirconium, di-i-propoxy-bis(ethyl acetoacetate)zirconium, di-n-butoxy-bis(ethyl acetoacetate)zirconium, di-sec-butoxy-bis(ethyl acetoacetate)zirconium, di-i-butoxy-bis(ethyl acetoacetate)zirconium, monoethoxy-tris(ethyl acetoacetate)zirconium, mono-n-propoxy-tris(ethyl acetoacetate)zirconium, mono-i-propoxy-tris(ethyl acetoacetate)zirconium, mono-n-butoxy-tris(ethyl acetoacetate)zirconium, mono-sec-butoxy-tris(ethyl acetoacetate)zirconium, mono-t-butoxy-tris(ethyl acetoacetate)zirconium, tetrakis(ethyl acetoacetate)zirconium, mono(acetylacetonate)tris(ethyl acetoacetate)zirconium, bis(acetylacetonate)bis(ethyl acetoacetate)zirconium, and tris(acetylacetonate)mono(ethyl acetoacetate)zirconium; and aluminum chelate compounds such as tris(acetylacetonate)aluminum and tris(ethyl acetoacetate)aluminum.

Examples of the organic acid as the hydrolysis catalyst include, but are not limited to, acetic acid, propionic acid, butanoic acid, pentanoic acid, hexanoic acid, heptanoic acid, octanoic acid, nonanoic acid, decanoic acid, oxalic acid, maleic acid, methylmalonic acid, adipic acid, sebacic acid, gallic acid, butyric acid, mellitic acid, arachidonic acid, 2-ethylhexanoic acid, oleic acid, stearic acid, linoleic acid, linolenic acid, salicylic acid, benzoic acid, p-aminobenzoic acid, p-toluenesulfonic acid, benzenesulfonic acid, monochloroacetic acid, dichloroacetic acid, trichloroacetic acid, trifluoroacetic acid, formic acid, malonic acid, sulfonic acid, phthalic acid, fumaric acid, citric acid, and tartaric acid.

Examples of the inorganic acid as the hydrolysis catalyst include, but are not limited to, hydrochloric acid, nitric acid, sulfuric acid, hydrofluoric acid, and phosphoric acid.

Examples of the organic base as the hydrolysis catalyst include, but are not limited to, pyridine, pyrrole, piperazine, pyrrolidine, piperidine, picoline, trimethylamine, triethylamine, monoethanolamine, diethanolamine, dimethylmonoethanolamine, monomethyldiethanolamine, triethanolamine, diazabicyclooctane, diazabicyclononane, diazabicycloundecene, tetramethylammonium hydroxide, tetraethylammonium hydroxide, tetrapropylammonium hydroxide, tetrabutylammonium hydroxide, trimethylphenylammonium hydroxide, benzyltrimethylammonium hydroxide, and benzyltriethylammonium hydroxide.

Examples of the inorganic base as the hydrolysis catalyst include, but are not limited to, ammonia, sodium hydroxide, potassium hydroxide, barium hydroxide, and calcium hydroxide.

Among these catalysts, a metal chelate compound, an organic acid, and an inorganic acid is preferred. These catalysts may be used singly or in combination of two or more kinds thereof.

In particular, nitric acid can be suitably used as a hydrolysis catalyst in the present invention. The use of nitric acid enables an improvement in the storage stability of a reaction solution after the hydrolysis and condensation, and particularly enables suppression of a change in the molecular weight of a hydrolysis condensate or a modified product of the hydrolysis condensate. It is known that the stability of the hydrolysis condensate or a modified product of the hydrolysis condensate contained in the reaction solution depends on the pH of the solution. As a result of intensive studies, it has been found that the pH of the reaction solution falls in a stable range by use of an appropriate amount of nitric acid.

As described above, nitric acid can also be used for preparation of a modified product of the hydrolysis condensate; for example, for capping of silanol groups with an alcohol. Thus, nitric acid is preferred from the viewpoint that it can contribute to the reactions of hydrolysis and condensation of the hydrolyzable silane, as well as the reaction of capping of the hydrolysis condensate with an alcohol.

An organic solvent may be used for the hydrolysis and condensation. Specific examples of the organic solvent include, but are not limited to, aliphatic hydrocarbon solvents, such as n-pentane, i-pentane, n-hexane, i-hexane, n-heptane, i-heptane, 2,2,4-trimethylpentane, n-octane, i-octane, cyclohexane, and methylcyclohexane; aromatic hydrocarbon solvents, such as benzene, toluene, xylene, ethylbenzene, trimethylbenzene, methylethylbenzene, n-propylbenzene, i-propylbenzene, diethylbenzene, i-butylbenzene, triethylbenzene, di-i-propylbenzene, and n-amylnaphthalene; monohydric alcohol solvents, such as methanol, ethanol, n-propanol, i-propanol, n-butanol, i-butanol, sec-butanol, t-butanol, n-pentanol, i-pentanol, 2-methylbutanol, sec-pentanol, t-pentanol, 3-methoxybutanol, n-hexanol, 2-methylpentanol, sec-hexanol, 2-ethylbutanol, n-heptanol, sec-heptanol, 3-heptanol, n-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethylcarbinol, diacetone alcohol, and cresol; polyhydric alcohol solvents, such as ethylene glycol, propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, tripropylene glycol, and glycerin; ketone solvents, such as acetone, methyl ethyl ketone, methyl-n-propyl ketone, methyl-n-butyl ketone, diethyl ketone, methyl-1-butyl ketone, methyl-n-pentyl ketone, ethyl-n-butyl ketone, methyl-n-hexyl ketone, di-i-butyl ketone, trimethylnonanone, cyclohexanone, methylcyclohexanone, 2,4-pentanedione, acetonylacetone, diacetone alcohol, acetophenone, and fenchone; ether solvents, such as ethyl ether, i-propyl ether, n-butyl ether, n-hexyl ether, 2-ethylhexyl ether, ethylene oxide, 1,2-propylene oxide, dioxolane, 4-methyldioxolane, dioxane, dimethyldioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethylbutyl ether, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxytriglycol, tetraethylene glycol di-n-butyl ether, propylene glycol monomethyl ether (1-methoxy-2-propanol), propylene glycol monoethyl ether (1-ethoxy-2-propanol), propylene glycol monopropyl ether, propylene glycol monobutyl ether, propylene glycol monomethyl ether acetate (1-methoxy-2-propanol monoacetate), dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, and 2-methyltetrahydrofuran; ester solvents, such as diethyl carbonate, methyl acetate, ethyl acetate, γ-butyrolactone, γ-valerolactone, n-propyl acetate, i-propyl acetate, n-butyl acetate, i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxytriglycol acetate, ethylene glycol diacetate, triethylene glycol methyl ether acetate, ethyl propionate, n-butyl propionate, i-amyl propionate, diethyl oxalate, di-n-butyl oxalate, methyl lactate, ethyl lactate, n-butyl lactate, n-amyl lactate, diethyl malonate, dimethyl phthalate, and diethyl phthalate; nitrogen-containing solvents, such as N-methylformamide, N,N-dimethylformamide, N,N-diethylformamide, acetamide, N-methylacetamide, N,N-dimethylacetamide, N-methylpropionamide, and N-methyl-2-pyrrolidone; and sulfur-containing solvents, such as dimethyl sulfide, diethyl sulfide, thiophene, tetrahydrothiophene, dimethyl sulfoxide, sulfolane, and 1,3-propanesultone. These solvents can be used singly or in combination of two or more kinds thereof.

After completion of the hydrolysis and condensation reactions, the reaction solution is used as is, or diluted or concentrated. The resultant reaction solution can be neutralized or treated with an ion exchange resin, and thus the hydrolysis catalyst, e.g. an acid or a base, used for the hydrolysis and condensation can be removed. Before or after such a treatment, alcohols: by-products, water, the used hydrolysis catalyst, and the like can be removed from the reaction solution, for example, by distillation under reduced pressure.

The thus-prepared hydrolysis condensate or a modified product of the hydrolysis condensate (hereinafter, also referred to as “polysiloxane”) is in the form of a polysiloxane varnish dissolved in an organic solvent, which may be used as is for preparation of the silicon-containing resist underlayer film-forming composition. That is, the reaction solution may be used as is (or diluted) for preparation of the silicon-containing resist underlayer film-forming composition. In this case, the hydrolysis catalyst used for the hydrolysis and condensation, by-products, and the like may remain in the reaction solution, so long as the effects of the present invention is not impaired. For example, nitric acid used as a hydrolysis catalyst or used for capping of silanol groups with an alcohol may remain in the polymer varnish solution in an amount of about 100 ppm to 5,000 ppm.

The resultant polysiloxane varnish may be subjected to solvent replacement, or may be appropriately diluted with a solvent. In a case where the storage stability of the resultant polysiloxane varnish is not poor, the organic solvent may be distilled off to achieve a film-forming component concentration of 100%. The film-forming component refers to a component resulted from the removal of a solvent component from all the components of the composition.

The organic solvent used for solvent replacement, dilution, or the like of the polysiloxane varnish may be identical to or different from the organic solvent used for the hydrolysis and condensation reactions of the hydrolyzable silane. The solvent for dilution is not particularly limited, and one kind or two or more kinds of solvents may be arbitrarily selected and used.

### <Component [C]: Solvent>

In the first embodiment, the solvent as the component [C] can be used without particular limitation as long as it is a solvent capable of dissolving and mixing the component [A] and, if necessary, other components contained in the silicon-containing resist underlayer film-forming composition.

In the second embodiment, the solvent as the component [C] can be used without particular limitation as long as it is a solvent capable of dissolving and mixing the component [A′] and the component [B] and, if necessary, other components contained in the silicon-containing resist underlayer film-forming composition.

The solvent [C] is preferably an alcohol-based solvent, more preferably alkylene glycol monoalkyl ether: alcohol-based solvent, and still more preferably propylene glycol monoalkyl ether. Since these solvents are also capping agents for silanol groups of the hydrolysis condensate, the solvent replacement or the like is not required. The silicon-containing resist underlayer film-forming composition can be prepared from a solution obtained by preparation of the polysiloxane [A] or the polysiloxane [A′].

Examples of the alkylene glycol monoalkyl ether include ethylene glycol monomethyl ether, ethylene glycol monoethyl ether, ethylene glycol monopropyl ether, ethylene glycol monobutyl ether, propylene glycol monomethyl ether (1-methoxy-2-propanol), propylene glycol monoethyl ether (1-ethoxy-2-propanol), methyl isobutyl carbinol, and propylene glycol monobutyl ether.

Specific examples of other solvent [C] include methyl cellosolve acetate, ethyl cellosolve acetate, propylene glycol, propylene glycol monomethyl ether acetate (1-methoxy-2-propanol monoacetate), propylene glycol monoethyl ether acetate, propylene glycol monopropyl ether acetate, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethylene glycol monomethyl ether acetate, ethylene glycol monoethyl ether acetate, ethylene glycol monopropyl ether acetate, ethylene glycol monobutyl ether acetate, diethylene glycol dimethyl ether, diethylene glycol diethyl ether, diethylene glycol dipropyl ether, diethylene glycol dibutyl ether, propylene glycol monomethyl ether, propylene glycol dimethyl ether, propylene glycol diethyl ether, propylene glycol dipropyl ether, propylene glycol dibutyl ether, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propyl propionate, isopropyl propionate, butyl propionate, isobutyl propionate, methyl butyrate, ethyl butyrate, propyl butyrate, isopropyl butyrate, butyl butyrate, isobutyl butyrate, ethyl hydroxyacetate, ethyl 2-hydroxy-2-methylpropionate, methyl 3-methoxy-2-methylpropionate, methyl 2-hydroxy-3-methybutyrate, ethyl methoxyacetate, ethyl ethoxyacetate, methyl 3-methoxypropionate, ethyl 3-ethoxypropionate, ethyl 3-methoxypropionate, 3-methoxybutyl acetate, 3-methoxypropyl acetate, 3-methyl-3-methoxybutyl acetate, 3-methyl-3-methoxybutyl propionate, 3-methyl-3-methoxybutyl butyrate, methyl acetoacetate, toluene, xylene, methyl ethyl ketone, methyl propyl ketone, methyl butyl ketone, 2-heptanone, 3-heptanone, 4-heptanone, cyclohexanone, N,N-dimethylformamide, N-methylacetamide, N,N-dimethylacetamide, N-methyl-2-pyrrolidone, 4-methyl-2-pentanol, and γ-butyrolactone. These solvents can be used singly or in combination of two or more kinds thereof.

The silicon-containing resist underlayer film-forming composition of the present invention may contain water as a solvent. When water is contained as the solvent, the content thereof may be, for example, 30 mass % or less, preferably 20 mass % or less, and still more preferably 15 mass % or less relative to the total mass of the solvent contained in the composition.

### <Component [D]: Curing Catalyst>

The silicon-containing resist underlayer film-forming composition may contain no curing catalyst. Alternatively, the composition preferably contains a curing catalyst (component [D]).

The curing catalyst may be, for example, an ammonium salt, a phosphine compound, a phosphonium salt, or a sulfonium salt. The salt described below as an example of a curing catalyst may be added in the form of a salt, or may be a compound that forms a salt in the composition (i.e. a compound that forms a salt in the system, but is in a form different from the salt during addition).

Examples of the ammonium salt include: a quaternary ammonium salt having a structure represented by the following Formula (D-1):

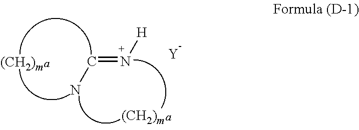

(where m^{a} represents an integer of 2 to 11, n^{a} represents an integer of 2 to 3, R²¹ represents an alkyl group, an aryl group, or an aralkyl group, and Y⁻ represents an anion);
a quaternary ammonium salt having a structure represented by the following Formula (D-2):

R²²R²³R²⁴R²⁵N⁺Y⁻ Formula (D-2)
(where R²², R²³, R²⁴, and R²⁵ each independently represent an alkyl group, an aryl group, or an aralkyl group, Y− represents an anion, and R²², R²³, R²⁴, and R²⁵ are each bonded to a nitrogen atom);
a quaternary ammonium salt having a structure represented by the following Formula (D-3):

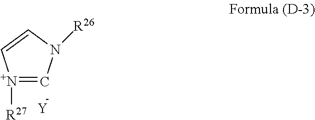

(where R²⁶ and R²⁷ each independently represent an alkyl group, an aryl group, or an aralkyl group, and Y⁻ represents an anion);
a quaternary ammonium salt having a structure represented by the following Formula (D-4):

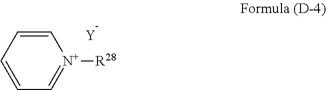

(where R²⁸ represents an alkyl group, an aryl group, or an aralkyl group, and Y⁻ represents an anion);
a quaternary ammonium salt having a structure represented by the following Formula (D-5):

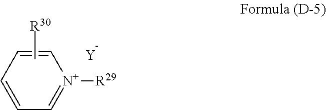

(where R²⁹ and R³⁰ each independently represent an alkyl group, an aryl group, or an aralkyl group, and Y⁻ represents an anion); and
a tertiary ammonium salt having a structure represented by the following Formula (D-6):

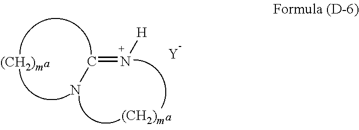

(where m^{a} represents an integer of 2 to 11, n^{a} represents an integer of 2 to 3, and Y⁻ represents an anion).

Examples of the phosphonium salt include a quaternary phosphonium salt represented by the following Formula (D-7):

R³¹R³²R³³R³⁴P⁺Y⁻ Formula (D-7)
(where R³¹, R³², R³³, and R³⁴ each independently represent an alkyl group, an aryl group, or an aralkyl group, Y⁻ represents an anion, and each of R³¹, R³², R³³, and R³⁴ is bonded to the phosphorus atom).

Examples of the sulfonium salt include a tertiary sulfonium salt represented by the following Formula (D-8):

R³⁵R³⁶R³⁷S⁺Y⁻ Formula(D-8)
(where R³⁵, R³⁶, and R³⁷ each independently represent an alkyl group, an aryl group, or an aralkyl group, Y⁻ represents an anion, and each of R³⁵, R³⁶, and R³⁷ is bonded to the sulfur atom).

The compound of Formula (D-1) is a quaternary ammonium salt derived from an amine, where m^{a} represents an integer of 2 to 11, and n^{a} represents an integer of 2 to 3. R²¹ of the quaternary ammonium salt represents, for example, an alkyl group having 1 to 18, preferably 2 to 10 carbon atoms, an aryl group having 6 to 18 carbon atoms, or an aralkyl group having 7 to 18 carbon atoms. Examples thereof include linear alkyl groups such as ethyl group, propyl group, and butyl group, benzyl group, cyclohexyl group, cyclohexylmethyl group, and dicyclopentadienyl group. Further, examples of the anion (Y⁻) include halide ions, such as chlorine ion (Cl⁻), bromine ion (Br⁻), and iodine ion (I⁻); and acid groups, such as carboxylate (—COO⁻), sulfonate (—SO₃⁻), and alcoholate (—O⁻).

The compound of Formula (D-2) is a quaternary ammonium salt represented by R²²R²³R²⁴R²⁵N⁺Y⁻. R²², R²³, R²⁴, and R²⁵ of the quaternary ammonium salt are each, for example, an alkyl group having 1 to 18 carbon atoms, such as ethyl group, propyl group, butyl group, cyclohexyl group, and cyclohexylmethyl group, an aryl group having 6 to 18 carbon atoms, such as phenyl group, or an aralkyl group having 7 to 18 carbon atoms, such as benzyl group. Examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O⁻). The quaternary ammonium salt is commercially available, and examples of the quaternary ammonium salt include tetramethylammonium acetate, tetrabutylammonium acetate, triethylbenzylammonium chloride, triethylbenzylammonium bromide, trioctylmethylammonium chloride, tributylbenzylammonium chloride, and trimethylbenzylammonium chloride.

The compound of Formula (D-3) is a quaternary ammonium salt derived from 1-substituted imidazole. The carbon atom number of each of R²⁶ and R²⁷ is, for example, 1 to 18, and the total number of carbon atoms of R²⁶ and R²⁷ is preferably 7 or more. Examples of R²⁶ include alkyl groups, such as methyl group, ethyl group, and propyl group, and aryl groups, such as phenyl group. Examples of R²⁷ include aralkyl groups, such as benzyl group, and alkyl groups, such as octyl group and octadecyl group. Examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O⁻). Although this compound is commercially available, the compound may be produced through, for example, reaction between an imidazole compound (e.g. 1-methylimidazole or 1-benzylimidazole) and an aralkyl halide, an alkyl halide, or an aryl halide, such as benzyl bromide, methyl bromide, or benzene bromide.

The compound of Formula (D-4) is a quaternary ammonium salt derived from pyridine. R²⁸ is, for example, an alkyl group having 1 to 18 carbon atoms, preferably 4 to 18 carbon atoms, an aryl group having 6 to 18 carbon atoms, or an aralkyl group having 7 to 18 carbon atoms. Examples thereof include butyl group, octyl group, benzyl group, and lauryl group. Examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O⁻). Although this compound is commercially available, the compound may be produced through, for example, reaction between pyridine and an alkyl halide or an aryl halide, such as lauryl chloride, benzyl chloride, benzyl bromide, methyl bromide, or octyl bromide. Examples of this compound include N-laurylpyridinium chloride and N-benzylpyridinium bromide.

The compound of Formula (D-5) is a quaternary ammonium salt derived from a substituted pyridine, such as picoline. R²⁹ is, for example, an alkyl group having 1 to 18 carbon atoms, preferably 4 to 18 carbon atoms, an aryl group having 6 to 18 carbon atoms, or an aralkyl group having 7 to 18 carbon atoms. Examples thereof include methyl group, octyl group, lauryl group, and benzyl group. R³⁰ is, for example, an alkyl group having 1 to 18 carbon atoms, an aryl group having 6 to 18 carbon atoms, or an aralkyl group having 7 to 18 carbon atoms. For example, R³⁰ is a methyl group when the compound represented by Formula (D-5) is a quaternary ammonium derived from picoline. Examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O⁻). Although this compound is commercially available, the compound may be produced through, for example, reaction between a substituted pyridine (e.g. picoline) and an alkyl halide or an aryl halide, such as methyl bromide, octyl bromide, lauryl chloride, benzyl chloride, or benzyl bromide. Examples of this compound include N-benzylpicolinium chloride, N-benzylpicolinium bromide, and N-laurylpicolinium chloride.

The compound of Formula (D-6) is a tertiary ammonium salt derived from an amine, where m^{a} represents an integer of 2 to 11, and n^{a} represents 2 or 3. Further, examples of the anion (Y⁻) include halide ions, such as chlorine ion (Cl⁻), bromine ion (Br⁻), and iodine ion (I⁻); and acid groups, such as carboxylate (—COO⁻), sulfonate (—SO₃⁻), and alcoholate (—O⁻). The compound may be produced through reaction between an amine and a weak acid, such as a carboxylic acid or phenol. Examples of the carboxylic acid include formic acid and acetic acid. When formic acid is used, the anion (Y⁻) is (HCOO⁻). When acetic acid is used, the anion (Y⁻) is (CH₃COO⁻). When phenol is used, the anion (Y⁻) is (C₆H₅O⁻).

The compound of Formula (D-7) is a quaternary phosphonium salt having a structure of R³¹R³²R³³R³⁴P⁺Y⁻. R³¹, R³², R³³, and R³⁴ are each, for example, an alkyl group having 1 to 18 carbon atoms, such as ethyl group, propyl group, butyl group, or cyclohexylmethyl, an aryl group having 6 to 18 carbon atoms, such as phenyl group, or an aralkyl group having 7 to 18 carbon atoms, such as benzyl group. Three of four substituents of R³¹ to R³⁴ are each preferably an unsubstituted phenyl group or a substituted phenyl group. Examples thereof include a phenyl group or a tolyl group. The remaining one substituent is an alkyl group having 1 to 18 carbon atoms, an aryl group having 6 to 18 carbon atoms, or an aralkyl group having 7 to 18 carbon atoms. Further, examples of the anion (Y⁻) include halide ions, such as chlorine ion (Cl⁻), bromine ion (Br⁻), and iodine ion (I⁻); and acid groups, such as carboxylate (—COO⁻), sulfonate (—SO₃⁻), and alcoholate (—O⁻). This compound is commercially available, and examples of the compound include tetraalkylphosphonium halides, such as tetra-n-butylphosphonium halide and tetra-n-propylphosphonium halide; trialkylbenzylphosphonium halides, such as triethylbenzylphosphonium halide; triphenylmonoalkylphosphonium halides, such as triphenylmethylphosphonium halide and triphenylethylphosphonium halide; triphenylbenzylphosphonium halide; tetraphenylphosphonium halide; tritolylmonoarylphosphonium halide; or tritolylmonoalkylphosphonium halide (where the halogen atom is a chlorine atom or a bromine atom). Particularly preferred are triphenylmonoalkylphosphonium halides, such as triphenylmethylphosphonium halide and triphenylethylphosphonium halide; triphenylmonoarylphosphonium halides, such as triphenylbenzylphosphonium halide; tritolylmonoarylphosphonium halides, such as tritolylmonophenylphosphonium halide; and tritolylmonoalkylphosphonium halides, such as tritolylmonomethylphosphonium halide (where the halogen atom is a chlorine atom or a bromine atom).

Examples of the phosphine compound include primary phosphines, such as methylphosphine, ethylphosphine, propylphosphine, isopropylphosphine, isobutylphosphine, and phenylphosphine; secondary phosphines, such as dimethylphosphine, diethylphosphine, diisopropylphosphine, diisoamylphosphine, and diphenylphosphine; and tertiary phosphines, such as trimethylphosphine, triethylphosphine, triphenylphosphine, methyldiphenylphosphine, and dimethylphenylphosphine.

The compound of Formula (D-8) is a tertiary sulfonium salt having a structure of R³⁵R³⁶R³⁷S⁺Y⁻. R³⁵, R³⁶, and R³⁷ are each, for example, an alkyl group having 1 to 18 carbon atoms, such as ethyl group, propyl group, butyl group, or cyclohexylmethyl, an aryl group having 6 to 18 carbon atoms, such as phenyl group, or an aralkyl group having 7 to 18 carbon atoms, such as benzyl group. Two of three substituents of R³⁵ to R³⁷ are each preferably an unsubstituted phenyl group or a substituted phenyl group. Examples thereof include a phenyl group or a tolyl group. The remaining one substituent is an alkyl group having 1 to 18 carbon atoms, an aryl group having 6 to 18 carbon atoms, or an aralkyl group having 7 to 18 carbon atoms. Examples of the anion (Y⁻) include halide ions, such as chlorine ion (Cl⁻), bromine ion (Br⁻), and iodine ion (I⁻); and acid groups, such as carboxylate (—COO⁻), sulfonate (—SO₃⁻), alcoholate (—O⁻), maleate anion, and nitrate anion. This compound is commercially available, and examples of the compound include trialkylsulfonium halides, such as tri-n-butylsulfonium halide and tri-n-propylsulfonium halide; dialkylbenzylsulfonium halides, such as diethylbenzylsulfonium halide; diphenylmonoalkylsulfonium halides, such as diphenylmethylsulfonium halide and diphenylethylsulfonium halide; triphenylsulfonium halides (where the halogen atom is a chlorine atom or a bromine atom); trialkylsulfonium carboxylates, such as tri-n-butylsulfonium carboxylate and tri-n-propylsulfonium carboxylate; dialkylbenzylsulfonium carboxylates, such as diethylbenzylsulfonium carboxylate; diphenylmonoalkylsulfonium carboxylates, such as diphenylmethylsulfonium carboxylate and diphenylethylsulfonium carboxylate; and triphenylsulfonium carboxylate. Triphenylsulfonium halide and triphenylsulfonium carboxylate are preferably used.

In addition, a nitrogen-containing silane compound may be added as a curing catalyst. Examples of the nitrogen-containing silane compound include silane compounds containing an imidazole ring, such as N-(3-triethoxysilylpropyl)-4,5-dihydroimidazole.

The content of the curing catalyst [D] in the silicon-containing resist underlayer film-forming composition according to the first embodiment is preferably 0.1 to 30 parts by mass, more preferably 0.5 to 25 parts by mass, and still more preferably 1 to 20 parts by mass relative to 100 parts by mass of the polysiloxane [A] from the viewpoint of more sufficiently achieving the effects of the present invention.

The content of the curing catalyst [D] in the silicon-containing resist underlayer film-forming composition according to the second embodiment is preferably 0.1 to 30 parts by mass, more preferably 0.5 to 25 parts by mass, and still more preferably 1 to 20 parts by mass relative to 100 parts by mass of the polysiloxane [A′] from the viewpoint of more sufficiently achieving the effects of the present invention.

### <Component [E]: Nitric Acid>

The silicon-containing resist underlayer film-forming composition preferably contains nitric acid [E].

Nitric acid [E] may be added during preparation of the silicon-containing resist underlayer film-forming composition. Alternatively, nitric acid may be used as a hydrolysis catalyst or used for capping of silanol groups with an alcohol in the production of the polysiloxane described above, and may remain in the resultant polysiloxane varnish.

The amount of the nitric acid [E](amount of residual nitric acid) added may be, for example, 0.0001 mass % to 1 mass %, 0.001 mass % to 0.1 mass %, or 0.005 mass % to 0.05 mass % relative to the total mass of the silicon-containing resist underlayer film-forming composition.

### <Additional Additives>

The silicon-containing resist underlayer film-forming composition may contain various additives depending on the intended use.

Examples of the additives include known additives incorporated in materials (compositions) for forming various films (e.g. resist underlayer film, anti-reflective coating, and pattern reversing film) that can be used in the production of a semiconductor element, such as a crosslinking agent, a crosslinking catalyst, a stabilizer (e.g. an organic acid, water, or an alcohol), an organic polymer, an acid generator, a surfactant (e.g. a nonionic surfactant, an anionic surfactant, a cationic surfactant, a silicon-based surfactant, a fluorine-based surfactant, or an UV-curable surfactant), a pH adjuster, a metal oxide, a rheology controlling agent, and an adhesion aid.

Hereinafter, various additives will be exemplified, but the additives are not limited thereto.

### <<Stabilizer>>

The stabilizer may be added for the purpose of stabilizing the hydrolysis condensate of the hydrolyzable silane, or the like. Specific example of the stabilizer that include an organic acid, water, alcohol, or a combination thereof.

Examples of the organic acid include oxalic acid, malonic acid, methylmalonic acid, succinic acid, maleic acid, malic acid, tartaric acid, phthalic acid, citric acid, glutaric acid, lactic acid, and salicylic acid. Among these organic acids, oxalic acid and maleic acid are preferred. When the organic acid is added, the amount of the organic acid added is 0.1 to 5.0 mass % relative to the hydrolysis condensate of the hydrolyzable silane. These organic acids may also serve as pH adjusters.

As the water, pure water, ultrapure water, ion exchanged water, or the like may be used. When pure water, ultrapure water, or ion exchanged water is used, the amount of the water added can be 1 to 20 parts by mass relative to 100 parts by mass of the silicon-containing resist underlayer film-forming composition.

The alcohol is preferably an alcohol that is easily scattered by heating after the application, and examples of the alcohol include methanol, ethanol, propanol, i-propanol, and butanol. When an alcohol is added, the amount of the alcohol added may be 1 to 20 parts by mass relative to 100 parts by mass of the silicon-containing resist underlayer film-forming composition.

### <<Organic Polymer>>

Addition of the organic polymer to the silicon-containing resist underlayer film-forming composition enables adjustment of the dry etching rate (the amount of reduction in film thickness per unit time), attenuation coefficient, refractive index, and the like of a film (resist underlayer film) formed from the composition. The organic polymer is not particularly limited, and is appropriately selected from various organic polymers (polycondensation polymer and addition polymerization polymer) depending on the purpose of addition thereof. Specific examples of the organic polymer include addition polymerization polymers and polycondensation polymers, such as polyester, polystyrene, polyimide, acrylic polymer, methacrylic polymer, polyvinyl ether, phenol novolac, naphthol novolac, polyether, polyamide, and polycarbonate.

In the present invention, an organic polymer having an aromatic or heteroaromatic ring that functions as a light-absorbing moiety (e.g. a benzene ring, a naphthalene ring, an anthracene ring, a triazine ring, a quinoline ring, or a quinoxaline ring) can also be suitably used in the case where such a function is required. Specific examples of such an organic polymer include, but are not limited to, addition polymerization polymers containing, as structural units, addition polymerizable monomers, such as benzyl acrylate, benzyl methacrylate, phenyl acrylate, naphthyl acrylate, anthryl methacrylate, anthryl methyl methacrylate, styrene, hydroxystyrene, benzyl vinyl ether, and N-phenylmaleimide, and condensation polycondensation polymers, such as phenol novolac and naphthol novolac.

When an addition polymerization polymer is used as an organic polymer, the polymer may be either a homopolymer or a copolymer.

An addition polymerizable monomer is used for the production of the addition polymerization polymer. Specific examples of the addition polymerizable monomer include, but are not limited to, acrylic acid, methacrylic acid, an acrylate ester compound, a methacrylate ester compound, an acrylamide compound, a methacrylamide compound, a vinyl compound, a styrene compound, a maleimide compound, maleic anhydride, and acrylonitrile.

Specific examples of the acrylate ester compound include, but are not limited to, methyl acrylate, ethyl acrylate, normal hexyl acrylate, i-propyl acrylate, cyclohexyl acrylate, benzyl acrylate, phenyl acrylate, anthrylmethyl acrylate, 2-hydroxyethyl acrylate, 3-chloro-2-hydroxypropyl acrylate, 2-hydroxypropyl acrylate, 2,2,2-trifluoroethyl acrylate, 2,2,2-trichloroethyl acrylate, 2-bromoethyl acrylate, 4-hydroxybutyl acrylate, 2-methoxyethyl acrylate, tetrahydrofurfuryl acrylate, 2-methyl-2-adamantyl acrylate, 5-acryloyloxy-6-hydroxynorbornene-2-carboxylic-6-lactone, 3-acryloxypropyltriethoxysilane, and glycidyl acrylate.

Specific examples of the methacrylate ester compound include, but are not limited to, methyl methacrylate, ethyl methacrylate, normal hexyl methacrylate, i-propyl methacrylate, cyclohexyl methacrylate, benzyl methacrylate, phenyl methacrylate, anthrylmethyl methacrylate, 2-hydroxyethyl methacrylate, 2-hydroxypropyl methacrylate, 2,2,2-trifluoroethyl methacrylate, 2,2,2-trichloroethyl methacrylate, 2-bromoethyl methacrylate, 4-hydroxybutyl methacrylate, 2-methoxyethyl methacrylate, tetrahydrofurfuryl methacrylate, 2-methyl-2-adamantyl methacrylate, 5-methacryloyloxy-6-hydroxynorbornene-2-carboxylic-6-lactone, 3-methacryloxypropyltriethoxysilane, glycidyl methacrylate, 2-phenylethyl methacrylate, hydroxyphenyl methacrylate, and bromophenyl methacrylate.

Specific examples of the acrylamide compound include, but are not limited to, acrylamide, N-methylacrylamide, N-ethylacrylamide, N-benzylacrylamide, N-phenylacrylamide, N,N-dimethylacrylamide, and N-anthrylacrylamide.

Specific examples of the methacrylamide compound include, but are not limited to, methacrylamide, N-methylmethacrylamide, N-ethylmethacrylamide, N-benzylmethacrylamide, N-phenylmethacrylamide, N,N-dimethylmethacrylamide, and N-anthrylmethacrylamide.

Specific examples of the vinyl compound include, but are not limited to, vinyl alcohol, 2-hydroxyethyl vinyl ether, methyl vinyl ether, ethyl vinyl ether, benzyl vinyl ether, vinyl acetic acid, vinyltrimethoxysilane, 2-chloroethyl vinyl ether, 2-methoxyethyl vinyl ether, vinylnaphthalene, and vinylanthracene.

Specific examples of the styrene compound include, but are not limited to, styrene, hydroxystyrene, chlorostyrene, bromostyrene, methoxystyrene, cyanostyrene, and acetylstyrene.

Specific examples of the maleimide compound include, but are not limited to, maleimide, N-methylmaleimide, N-phenylmaleimide, N-cyclohexylmaleimide, N-benzylmaleimide, and N-hydroxyethylmaleimide.

When a polycondensation polymer is used as the polymer, the polymer is, for example, a polycondensation polymer composed of a glycol compound and a dicarboxylic acid compound. Examples of the glycol compound include diethylene glycol, hexamethylene glycol, and butylene glycol. Examples of the dicarboxylic acid compound include succinic acid, adipic acid, terephthalic acid, and maleic anhydride. Further, examples of the polymer include, but are not limited to, polyesters, polyamides, and polyimides, such as polypyromellitimide, poly(p-phenyleneterephthalamide), polybutylene terephthalate, and polyethylene terephthalate.

When the organic polymer contains a hydroxy group, the hydroxy group may be crosslinked with a hydrolysis condensate, or the like.

The organic polymer may ordinarily have a weight-average molecular weight of 1,000 to 1,000,000. From the viewpoint of sufficiently achieving the effect of the polymer function and preventing the precipitation of the polymer in the composition, the weight-average molecular weight of the organic polymer to be added may be, for example, 3,000 to 300,000, 5,000 to 300,000, or 10,000 to 200,000.

The organic polymer may be used singly or in combination of two or more kinds thereof.

When the silicon-containing resist underlayer film-forming composition contains an organic polymer, the content of the organic polymer cannot be univocally determined, since the content should be appropriately determined in consideration of the function of the organic polymer or the like. Ordinarily, the content may be 1 to 200 mass % relative to the polysiloxane [A] or the polysiloxane [A′]. From the viewpoint of preventing the precipitation of the organic polymer in the composition and the like, the content may be, for example, 100 mass % or less, preferably 50 mass % or less, and more preferably 30 mass % or less. From the viewpoint of sufficiently achieving the effect of the polymer and the like, the content may be, for example, 5 mass % or more, preferably 10 mass % or more, more preferably 30 mass % or more.

### <<Acid Generator>>

Examples of the acid generator include a thermal acid generator and a photoacid generator, and a photoacid generator may be preferably used.

Examples of the photoacid generator include, but are not limited to, an onium salt compound, a sulfonimide compound, and a disulfonyldiazomethane compound. The photoacid generator may also function as a curing catalyst depending on the type thereof, for example, a nitrate salt, a carboxylate salt (e.g. maleate), or a hydrochloride salt of an onium salt compound described below.

Examples of the thermal acid generator include, but are not limited to, tetramethylammonium nitrate.

Specific examples of the onium salt compound include, but are not limited to, iodonium salt compounds, such as diphenyliodonium hexafluorophosphate, diphenyliodonium trifluoromethanesulfonate, diphenyliodonium nonafluoro normal butanesulfonate, diphenyliodonium perfluoro normal octanesulfonate, diphenyliodonium camphorsulfonate, bis(4-t-butylphenyl)iodonium camphorsulfonate, and bis(4-t-butylphenyl)iodonium trifluoromethanesulfonate; and sulfonium salt compounds, such as triphenylsulfonium hexafluoroantimonate, triphenylsulfonium nonafluoro normal butanesulfonate, triphenylsulfonium camphorsulfonate, triphenylsulfonium trifluoromethanesulfonate, triphenylsulfonium nitrate, triphenylsulfonium trifluoroacetate, triphenylsulfonium maleate, and triphenylsulfonium chloride.

Specific examples of the sulfonimide compound include, but are not limited to, N-(trifluoromethanesulfonyloxy)succinimide, N-(nonafluoro normal butane sulfonyloxy)succinimide, N-(camphorsulfonyloxy)succinimide, and N-(trifluoromethanesulfonyloxy)naphthalimide.

Specific examples of the disulfonyldiazomethane compound include, but are not limited to, bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

When the silicon-containing resist underlayer film-forming composition contains an acid generator, the content of the acid generator cannot be univocally determined, since the amount should be appropriately determined in consideration of the type of the acid generator and the like. Ordinarily, the content of the acid generator is 0.01 to 5 mass % relative to the polysiloxane [A] or the polysiloxane [A′]. From the viewpoint of preventing the precipitation of the acid generator in the composition and the like, the content is preferably 3 mass % or less, more preferably 1 mass % or less. From the viewpoint of sufficiently achieving the effect of the acid generator and the like, the content is preferably 0.1 mass % or more, more preferably 0.5 mass % or more.

The acid generators may be used singly or in combination of two or more kinds thereof. A photoacid generator and a thermal acid generator may be used in combination.

### <<Surfactant>>

When the silicon-containing resist underlayer film-forming composition is applied to a substrate or an organic underlayer film, a surfactant is effective in prevention of formation of pinholes, striations, and the like. Examples of the surfactant include a nonionic surfactant, an anionic surfactant, a cationic surfactant, a silicon-based surfactant, a fluorine-based surfactant, and a UV-curable surfactant. Specific examples of the surfactant include, but are not limited to, nonionic surfactants, for example, polyoxyethylene alkyl ethers, such as polyoxyethylene lauryl ether, polyoxyethylene stearyl ether, polyoxyethylene cetyl ether, and polyoxyethylene oleyl ether, polyoxyethylene alkylaryl ethers, such as polyoxyethylene octylphenol ether and polyoxyethylene nonylphenol ether, polyoxyethylene-polyoxypropylene block copolymers, sorbitan fatty acid esters, such as sorbitan monolaurate, sorbitan monopalmitate, sorbitan monostearate, sorbitan monooleate, sorbitan trioleate, and sorbitan tristearate, polyoxyethylene sorbitan fatty acid esters, such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine-based surfactants, such as trade names EFTOP (registered trademark) EF301, EF303, and EF352 (manufactured by Mitsubishi Materials Electronic Chemicals Co., Ltd. (former Tohkem Products Corporation)), trade names MEGAFACE (registered trademark) F171, F173, R-08, R-30, R-30N, and R-40LM (manufactured by DIC Corporation), Fluorad FC430 and FC431 (manufactured by 3M Japan Limited), trade name Asahi Guard (registered trademark) AG710 (manufactured by AGC Inc.), and trade names SURFLON (registered trademark) S-382, SC101, SC102, SC103, SC104, SC105, and SC106 (manufactured by AGC Seimi Chemical Co., Ltd.); and Organosiloxane Polymer KP341 (manufactured by Shin-Etsu Chemical Co., Ltd.).

The surfactants may be used singly or in combination of two or more kinds thereof.

When the silicon-containing resist underlayer film-forming composition contains a surfactant, the content of the surfactant is ordinarily 0.0001 to 5 mass %, preferably 0.001 to 4 mass %, and more preferably 0.01 to 3 mass % relative to the polysiloxane [A] or the polysiloxane [A′].

### <<Rheology Controlling Agent>>

The rheology controlling agent is added mainly for the purpose of improving the fluidity of the silicon-containing resist underlayer film-forming composition, particularly in a baking process, improving the uniformity of the thickness of a film to be formed, or improving the fillability of the composition into holes. Specific examples of the rheology controlling agent include phthalic acid derivatives, such as dimethyl phthalate, diethyl phthalate, di-i-butyl phthalate, dihexyl phthalate, and butyl i-decyl phthalate; adipic acid derivatives, such as di-normal butyl adipate, di-i-butyl adipate, di-i-octyl adipate, and octyl decyl adipate; maleic acid derivatives, such as di-normal butyl maleate, diethyl maleate, and dinonyl maleate; oleic acid derivatives, such as methyl oleate, butyl oleate, and tetrahydrofurfuryl oleate; and stearic acid derivatives, such as normal butyl stearate and glyceryl stearate.

When such a rheology controlling agent is used, the amount of the rheology controlling agent added is ordinarily less than 30 mass % relative to all film-forming components of the silicon-containing resist underlayer film-forming composition.

### <<Adhesion Aid>>

The adhesion aid is added for the purpose of mainly improving the adhesion between a substrate, an organic underlayer film or a resist and a film (resist underlayer film) formed from the silicon-containing resist underlayer film-forming composition, in particular, suppressing or preventing the peeling of the resist during development. Specific examples of the adhesion aid include chlorosilanes, such as trimethylchlorosilane, dimethylvinylchlorosilane, methyldiphenylchlorosilane, and chloromethyldimethylchlorosilane; alkoxysilanes, such as trimethylmethoxysilane, dimethyldiethoxysilane, methyldimethoxysilane, and dimethylvinylethoxysilane; silazanes, such as hexamethyldisilazane, N,N′-bis(trimethylsilyl)urea, dimethyltrimethylsilylamine, and trimethylsilyl imidazole; other silanes, such as γ-chloropropyltrimethoxysilane, γ-aminopropyltriethoxysilane, and γ-glycidoxypropyltrimethoxysilane; heterocyclic compounds, such as benzotriazole, benzimidazole, indazole, imidazole, 2-mercaptobenzimidazole, 2-mercaptobenzothiazole, 2-mercaptobenzoxazole, urazole, thiouracil, mercaptoimidazole, mercaptopyrimidine; and urea or thiourea compounds, such as 1,1-dimethylurea and 1,3-dimethylurea.

When such an adhesion aid is used, the amount of the adhesion aid added is ordinarily less than 5 mass %, preferably less than 2 mass %, relative to the film-forming components of the silicon-containing resist underlayer film-forming composition.

### <<pH Adjuster>>

In addition, the pH adjuster may be an acid having one or two or more carboxylic acid groups, for example, an organic acid described above in <<Stabilizer>>. When a pH adjuster is used, the amount of the pH adjuster added may be 0.01 to 20 parts by mass, 0.01 to 10 parts by mass, or 0.01 to 5 parts by mass relative to 100 parts by mass of the polysiloxane [A] or the polysiloxane [A′].

### <<Metal Oxide>>

Examples of the metal oxide that may be added to the silicon-containing resist underlayer film-forming composition include, but are not limited to, oxides of a combination of one or more selected from among metals, such as tin (Sn), titanium (Ti), aluminum (Al), zirconium (Zr), zinc (Zn), niobium (Nb), tantalum (Ta), and W (tungsten), and semimetals, such as boron (B), silicon (Si), germanium (Ge), arsenic (As), antimony (Sb), and tellurium (Te).

The concentration of the film-forming component in the silicon-containing resist underlayer film-forming composition may be, for example, 0.1 to 50 mass %, 0.1 to 30 mass %, 0.1 to 25 mass %, or 0.5 to 20.0 mass % relative to the total amount of the composition.

The content of the polysiloxane [A] or the polysiloxane [A′] in the film-forming component is ordinarily 20 mass % to 100 mass %. From the viewpoint of achieving the effects of the present invention at high reproducibility or the like, the lower limit of the content of the polysiloxane [A] or the polysiloxane [A′] is preferably 50 mass %, more preferably 60 mass %, still more preferably 70 mass %, and yet still more preferably 80 mass %. The upper limit of the content is preferably 99 mass %. The balance may be an additive described below.

Further, the silicon-containing resist underlayer film-forming composition preferably has a pH of 2 to 5, more preferably a pH of 3 to 4.

The silicon-containing resist underlayer film-forming composition according to the first embodiment can be produced by mixing the polysiloxane [A], the solvent [C], and, if desired, an additional component. In this case, a solution containing the polysiloxane [A] may be prepared in advance, and this solution may be mixed with the solvent [C] and an additional component.

The order of mixing these components is not particularly limited. For example, the solvent [C] may be added to and mixed with a solution containing the polysiloxane [A], and an additional component may be added to the resultant mixture. Alternatively, a solution containing the polysiloxane [A], the solvent [C], and an additional component may be mixed simultaneously.

If necessary, the solvent [C] may be finally added, or some components that can be relatively easily dissolved in the solvent [C] may be finally added without being incorporated into the mixture. However, from the viewpoint of preventing aggregation or separation of the components to prepare a highly homogeneous composition with high reproducibility, the composition is preferably produced from a previously prepared solution containing the well-dissolved polysiloxane [A]. It should be noted that the polysiloxane [A] may be aggregated or precipitated when mixed with the solvent [C], or an additional component, depending on, for example, the type or amount of the solvent [C], or the amount or nature of the additional component. Further, it should be noted that when a composition is prepared from a solution containing the polysiloxane [A], the concentration of the solution of the polysiloxane [A] or the amount of the solution used must be determined to achieve a desired amount of the polysiloxane [A] contained in the finally produced composition.

During preparation of the composition, the composition may be appropriately heated so long as the components are not decomposed or denatured.

The silicon-containing resist underlayer film-forming composition according to the second embodiment can be produced by mixing the polysiloxane [A′], the hydrolyzable silane (A) represented by Formula (A-1) [B], the solvent [C], and, if desired, an additional component. In this case, a solution containing the polysiloxane [A′] may be prepared in advance, and this solution may be mixed with the hydrolyzable silane (A) represented by Formula (A-1) [B], the solvent [C], and an additional component.

The order of mixing these components is not particularly limited. For example, the hydrolyzable silane (A) represented by Formula (A-1) [B] and the solvent [C] may be added to and mixed with a solution containing the polysiloxane [A′], and an additional component may be added to the resultant mixture. Alternatively, a solution containing the polysiloxane [A′], the hydrolyzable silane (A) represented by Formula (A-1) [B], the solvent [C], and an additional component may be mixed simultaneously.

If necessary, the solvent [C] may be finally added, or some components that can be relatively easily dissolved in the solvent [C] may be finally added without being incorporated into the mixture. However, from the viewpoint of preventing aggregation or separation of the components to prepare a highly homogeneous composition with high reproducibility, the composition is preferably produced from a previously prepared solution containing the well-dissolved polysiloxane [A′]. It should be noted that the polysiloxane [A′] may be aggregated or precipitated when mixed with the hydrolyzable silane (A) represented by Formula (A-1) [B] and the solvent [C], or an additional component, depending on, for example, the type or amount of the solvent [C], or the amount or nature of the additional component. Further, it should be noted that when a composition is prepared from a solution containing the polysiloxane [A′], the concentration of the solution of the polysiloxane [A′] or the amount of the solution used must be determined to achieve a desired amount of the polysiloxane [A′] contained in the finally produced composition.

During preparation of the composition, the composition may be appropriately heated so long as the components are not decomposed or denatured.

In the present invention, the silicon-containing resist underlayer film-forming composition may be filtered with a submicrometer-order filter or the like during production of the composition or after mixing of all the components. The type of the material of the filter used is not limited. For example, a nylon-made filter or a fluororesin-made filter may be used.

The silicon-containing resist underlayer film-forming composition of the present invention may be suitably used as a composition for forming a resist underlayer film used in a lithography process.

### (Resist Underlayer Film, Semiconductor Processing Substrate, and Method for Forming Pattern, and Method for Producing Semiconductor Element)

The resist underlayer film of the present invention is a cured product of the silicon-containing resist underlayer film-forming composition of the present invention.

The semiconductor processing substrate of the present invention includes, for example, the silicon-containing resist underlayer film of the present invention.

The method for producing a semiconductor element of the present invention includes, for example,
the steps of: forming an organic underlayer film on a substrate;
forming a resist underlayer film on the organic underlayer film using the silicon-containing resist underlayer film-forming composition of the present invention; and
forming a metal-containing resist film on the resist underlayer film.

The method for forming a pattern of the present invention includes, for example, the steps of:
forming an organic underlayer film on a semiconductor substrate;
applying the silicon-containing resist underlayer film-forming composition of the present invention on the organic underlayer film and baking to form a resist underlayer film;
forming a metal-containing resist film on the resist underlayer film;
exposing and developing the metal-containing resist film to obtain a resist pattern;
etching the resist underlayer film using the resist pattern as a mask; and
etching the organic underlayer film using the patterned resist underlayer film as a mask.

Hereinafter, as one aspect of the present invention, a semiconductor processing substrate, a method for forming a pattern, and a method for producing a semiconductor element using the silicon-containing resist underlayer film of the present invention or the silicon-containing resist underlayer film-forming composition of the present invention will be described.

First, the silicon-containing resist underlayer film-forming composition of the present invention is applied onto a substrate used for the production of a precise integrated circuit element [e.g. a semiconductor substrate such as a silicon wafer coated with a silicon oxide film, a silicon nitride film, or a silicon oxynitride film, a silicon nitride substrate, a quartz substrate, a glass substrate (including alkali-free glass, low alkali glass, or crystallized glass), a glass substrate coated with an ITO (indium tin oxide) film or an IZO (indium zinc oxide) film, a plastic (e.g. polyimide or PET) substrate, a substrate coated with a low dielectric constant material (low-k material), or a flexible substrate] by an appropriate application method with, for example, a spinner or a coater. Thereafter, the composition is cured through baking by heating means (e.g. a hot plate) to form a resist underlayer film. Hereinafter, the term “resist underlayer film” used herein refers to the silicon-containing resist underlayer film of the present invention, or a film formed from the silicon-containing resist underlayer film-forming composition of the present invention.

The baking conditions are appropriately selected from a baking temperature of 40° C. to 400° C., or 80° C. to 250° C., and a baking time of 0.3 minutes to 60 minutes. Preferably, the baking temperature is 150° C. to 250° C., and the baking time is 0.5 minutes to 2 minutes.

The resist underlayer film formed here has a thickness of, for example, 10 nm to 1,000 nm, or 20 nm to 500 nm, or 50 nm to 300 nm, or 100 nm to 200 nm, or 10 to 150 nm.

As the silicon-containing resist underlayer film-forming composition used for formation of the resist underlayer film, the silicon-containing resist underlayer film-forming composition filtered through a nylon filter may be used. Here, the term “silicon-containing resist underlayer film-forming composition filtered through a nylon filter” refers to a composition that has been subjected to filtration with a nylon filter during production of the silicon-containing resist underlayer film-forming composition or after mixing all the components.

In one aspect of the present invention, the resist underlayer film is formed on the substrate, and then the resist underlayer film is formed on the organic underlayer film. In some cases, an aspect may be employed in which the organic underlayer film is not provided.

The organic underlayer film used here is not particularly limited, and may be arbitrarily selected from organic underlayer films commonly used in the lithography process.

In one aspect, the organic underlayer film is formed on the substrate, and the resist underlayer film is formed on the organic underlayer film, followed by formation of a metal-containing resist film as described below on the resist underlayer film. This can narrow the pattern width of a metal-containing resist film. Thus, even when the metal-containing resist film is formed thinly for preventing pattern collapse, the substrate can be processed through selection of an appropriate etching gas described below. For example, the resist underlayer film can be processed by using, as an etching gas, a fluorine-containing gas that achieves a sufficiently high etching rate for the metal-containing resist film. Further, the organic underlayer film can be processed by using, as an etching gas, an oxygen-containing gas that achieves a sufficiently high etching rate for the resist underlayer film. Further, the substrate can be processed by using, as an etching gas, a fluorine-containing gas that achieves a sufficiently high etching rate for the organic underlayer film.

The substrate and application method usable in this process are the same as those described above.

Subsequently, for example, a layer of a metal-containing resist material (metal-containing resist film) is formed on the resist underlayer film. The metal-containing resist film can be formed by a well-known method. Specifically, the metal-containing resist film can be formed by applying a coating-type resist material (e.g. a composition for forming a metal-containing resist film) onto the resist underlayer film, and baking the resist material.

The metal-containing resist film has a thickness of, for example, 5 nm to 10,000 nm, or 5 nm to 1,000 nm, or 5 nm to 40 nm.

The metal-containing resist film is not particularly limited, and preferably has at least one element of Si, Ge, Sn, Ti, Zr, Hf, Al, and Co.

The metal-containing resist is also called a metal oxide resist (metal oxide resist (MOR)), and typical examples thereof include a tin oxide-based resist.

The material of the metal oxide resist is, for example, a coating composition containing a metal oxo-hydroxo network having an organic ligand through a metal carbon bond and/or a metal carboxylate bond described in JP 2019-113855 A.

In an example of the metal-containing resist, a peroxo ligand is used as a radiation-sensitive stabilizing ligand. For example, details of the peroxo based metal oxo-hydroxo compounds are described in Patent Literature in paragraph [0011] of JP 2019-532489 A. Examples of the Patent Literature include U.S. Pat. No. 9,176,377 B2, US 2013/0224652 A1, U.S. Pat. No. 9,310,684 B2, US 2016/0116839 A1, and U.S. Ser. No. 15/291,738 A. Other examples of the metal-containing resist include compositions described in JP 2011-253185 A, WO2015/026482 A, WO2016/065120 A, WO2017/066319 A, WO2017/156388 A, WO2018/031896 A, JP 2020-122959 A, JP 2020-122960 A, WO2019/099981 A, WO2019/199467 A, WO2019/195522 A, WO2019/195522 A, WO2020/210660 A, WO2021/011367 A, and WO2021/016229 A.

These contents are incorporated herein to the same extent as all the contents are specified.

The metal-containing resist film may be formed by vapor deposition. The method for forming the metal-containing resist film by vapor deposition is, for example, a method described in JP 2017-116923 A. The contents of JP 2017-116923 A are incorporated herein to the same extent as all the contents are specified. In JP 2017-116923 A, the metal-containing resist film in the present invention is referred to as a metal oxide-containing film.

Subsequently, light exposure is performed on the metal-containing resist film formed above the resist underlayer film through a predetermined mask (reticle). The light exposure may be performed using a KrF excimer laser (wavelength: 248 nm), an ArF excimer laser (wavelength: 193 nm), an F₂ excimer laser (wavelength: 157 nm), EUV (wavelength: 13.5 nm), electron beams, or the like.

After the light exposure, post exposure bake may be performed as necessary. The post exposure bake is performed under appropriately selected conditions: a heating temperature of 70° C. to 250° C. and a heating time of 0.3 minutes to 10 minutes.

In the present invention, an organic solvent can be used as a developer. Development is performed with a developer (solvent) after light exposure. When, for example, a negative metal-containing resist film is used, an unexposed portion of the metal-containing resist film is removed, and thus a pattern of the metal-containing resist film is formed.

Examples of the developer (organic solvent) include methyl acetate, butyl acetate, ethyl acetate, isopropyl acetate, amyl acetate, isoamyl acetate, ethyl methoxyacetate, ethyl ethoxyacetate, propylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3 methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3 ethoxypropionate, and propyl-3-methoxypropionate. Furthermore, a surfactant or the like may be added to these developers. Development conditions are appropriately selected from a temperature of 5° C. to 50° C., and a time of 10 seconds to 600 seconds.

The resultant patterned metal-containing resist film (upper layer) is used as a protective film to remove the resist underlayer film (intermediate layer). Then, a film including the patterned metal-containing resist film and the patterned resist underlayer film (intermediate layer) is used as a protective film to remove the organic underlayer film (lower layer). Finally, the substrate is processed using the patterned resist underlayer film (intermediate layer) and the patterned organic underlayer film (lower layer) as protective films.

The resist underlayer film (intermediate layer) is removed (patterned) through dry etching by using the patterned metal-containing resist film (upper layer) as a protective film. The dry etching can be performed using any of gases, such as tetrafluoromethane (CF₄), perfluorocyclobutane (C₄F₈), perfluoropropane (C₃F₈), trifluoromethane, carbon monoxide, argon, oxygen, nitrogen, sulfur hexafluoride, difluoromethane, nitrogen trifluoride, chlorine trifluoride, chlorine, trichloroborane, and dichloroborane.

The dry etching of the resist underlayer film is preferably performed using a halogen-containing gas. The metal-containing resist film is basically less likely to be removed by dry etching with a halogen-containing gas. In contrast, the resist underlayer film containing numerous silicon atoms is quickly removed by a halogen-containing gas. Accordingly, a reduction in the thickness of the metal-containing resist film in associated with the dry etching of the resist underlayer film can be suppressed. As a result, the metal-containing resist film can be used in the form of thin film. Thus, the dry etching of the resist underlayer film is preferably performed using a fluorine-containing gas. Examples of the fluorine-containing gas include, but are not limited to, tetrafluoromethane (CF₄), perfluorocyclobutane (C₄F₈), perfluoropropane (C₃F₈), trifluoromethane, and difluoromethane (CH₂F2), thereto.

When the organic underlayer film is present between the substrate and the resist underlayer film, a film including the patterned metal-containing resist film (upper layer) (if remains) and the patterned resist underlayer film (intermediate layer) is used as a protective film to remove (pattern) the organic underlayer film (lower layer). The organic underlayer film (lower layer) is preferably removed (patterned) by dry etching with an oxygen-containing gas (e.g. oxygen gas or oxygen/carbonyl sulfide (COS) mixed gas). This is because the resist underlayer film of the present invention, which contains numerous silicon atoms, is less likely to be removed by dry etching with an oxygen-containing gas.

Thereafter, the patterned resist underlayer film (intermediate layer) and, if desired, the patterned organic underlayer film (lower layer) are used as protective films to process (pattern) the (semiconductor) substrate. The (semiconductor) substrate is preferably processed (patterned) by dry etching with a fluorine-containing gas. Examples of the fluorine-containing gas include tetrafluoromethane (CF₄), perfluorocyclobutane (C₄F₈), perfluoropropane (C₃F₈), trifluoromethane, and difluoromethane (CH₂F₂).

After the removal (patterning) of the organic underlayer film or after the processing (patterning) of the substrate, the resist underlayer film may be removed. The resist underlayer film may be removed by dry etching or wet etching (wet method).

The dry etching of the resist underlayer film is preferably performed with a fluorine-containing gas as described in the patterning. Examples of the fluorine-containing gas include, but are not limited to, tetrafluoromethane (CF₄), perfluorocyclobutane (C₄F₈), perfluoropropane (C₃F₈), trifluoromethane, and difluoromethane (CH₂F₂) Examples of the chemical liquid used for wet etching of the resist underlayer film include alkaline solutions, such as dilute hydrofluoric acid (hydrofluoric acid), buffered hydrofluoric acid (mixed solution of HF and NH₄F), an aqueous solution containing hydrochloric acid and hydrogen peroxide (SC-2 chemical liquid), an aqueous solution containing sulfuric acid and hydrogen peroxide (SPM chemical liquid), an aqueous solution containing hydrofluoric acid and hydrogen peroxide (FPM chemical liquid), and an aqueous solution containing ammonia and hydrogen peroxide (SC-1 chemical liquid). Further, examples of the alkaline solution include an aqueous solution containing 1 to 99 mass % of ammonia, tetramethylammonium hydroxide (TMAH), tetraethylammonium hydroxide, tetrapropylammonium hydroxide, tetrabutylammonium hydroxide, choline hydroxide, benzyltrimethylammonium hydroxide, benzyltriethylammonium hydroxide, DBU (diazabicycloundecene), DBN (diazabicyclononene), hydroxylamine, 1-butyl-1-methylpyrrolidinium hydroxide, 1-propyl-1-methylpyrrolidinium hydroxide, 1-butyl-1-methylpiperidinium hydroxide, 1-propyl-1-methylpiperidinium hydroxide, mepiquat hydroxide, trimethylsulfonium hydroxide, a hydrazine compound, an ethylenediamine compound, or guanidine, in addition to the ammonia-hydrogen peroxide mixture prepared by mixing ammonia, hydrogen peroxide water, and water described above (SC-1 chemical liquid). These chemical liquids may be used in the form of mixture.

An organic anti-reflective coating may be formed on the resist underlayer film before formation of the metal-containing resist film. The composition used for formation of the anti-reflective coating is not particularly limited, and for example, the composition may be appropriately selected from anti-reflective coating compositions commonly used in a lithography process. The anti-reflective coating can be formed by a commonly used method, for example, application of the composition with a spinner or a coater, and baking of the composition.

In addition, the substrate to which the silicon-containing resist underlayer film-forming composition is applied may have an organic or inorganic anti-reflective coating formed thereon by, for example, a CVD process. The resist underlayer film may be formed on the anti-reflective coating. Even in a case where the resist underlayer film of the present invention is formed on the organic underlayer film formed on the substrate, the substrate used may have an organic or inorganic anti-reflective coating formed thereon by, for example, a CVD process.

The resist underlayer film formed from the silicon-containing resist underlayer film-forming composition may absorb light used in a lithography process depending on the wavelength of the light. In such a case, the resist underlayer film can function as an anti-reflective coating having the effect of preventing reflection of light from the substrate.

Furthermore, the resist underlayer film can be used as, for example, a layer for preventing the interaction between the substrate and the metal-containing resist film; a layer having the function of preventing the adverse effect, on the substrate, of a material used for the metal-containing resist film or a substance generated during the exposure of the metal-containing resist film to light; a layer having the function of preventing diffusion of a substance generated from the substrate during heating and baking to the metal-containing resist film; and a barrier layer for reducing a poisoning effect of a dielectric layer of the semiconductor substrate on the metal-containing resist film.

The resist underlayer film can be applied to a substrate having via holes for use in a dual damascene process, and can be used as a hole filling material (embedding material) to fill up the holes. The resist underlayer film can also be used as a planarization material for planarizing the surface of a semiconductor substrate having irregularities.

The resist underlayer film of the present invention functions as an underlayer film of EUV metal-containing resist film or a hard mask. In addition, the resist underlayer film is capable of, without intermixing with the EUV metal-containing resist film, preventing the reflection, from a substrate or an interface, of exposure light undesirable for EUV exposure (wavelength: 13.5 nm), such as UV (ultraviolet) light or DUV (deep ultraviolet) light (ArF light, KrF light). Therefore, the silicon-containing resist underlayer film-forming composition of the present invention can be suitably used to form an anti-reflective underlayer coating of EUV metal-containing resist film. Thus, the resist underlayer film can efficiently prevent the light reflection as the underlayer film of the EUV metal-containing resist film. When the resist underlayer film is used as an EUV resist underlayer film, the film can be processed in a similar manner to the photoresist underlayer film.

A semiconductor substrate can be suitably processed by using a semiconductor processing substrate including the above-described resist underlayer film of the present invention and a semiconductor substrate.

In addition, a semiconductor substrate can be precisely processed at high reproducibility by the above-described semiconductor element production method including the steps of: forming an organic underlayer film; forming a resist underlayer film on the organic underlayer film using the silicon-containing resist underlayer film-forming composition of the present invention; and forming a metal-containing resist film on the resist underlayer film. Thus, it is expected that the method can stably produce a semiconductor element.

### EXAMPLES

Hereinafter, the present invention will be described more specifically with reference to Synthesis Examples and Examples, but the present invention is not limited to only the following Examples.

In the Examples, apparatuses and conditions used for analysis of the physical properties of samples are as follows.

### (1) Measurement of Molecular Weight

The molecular weight of the polysiloxane used in the present invention is determined by GPC analysis in terms of polystyrene.

The GPC analysis was performed under the following conditions: GPC apparatus (trade name: HLC-8220GPC, manufactured by Tosoh Corporation), GPC columns (trade name: Shodex (registered trademark) KF803L, KF802, and KF801, manufactured by Showa Denko K.K.), column temperature of 40° C., tetrahydrofuran as an eluent (elution solvent), flow amount (flow rate) of 1.0 mL/min, and polystyrene (manufactured by Showa Denko K.K.) as a standard sample.

### (2) ¹H-NMR

The evaluation was performed using a nuclear magnetic resonance apparatus ¹H-NMR (400 MHz), manufactured by JEOL Ltd., and d6-Acetone as a solvent.

### [1] Synthesis of Polymer (Hydrolysis Condensate)

### Synthesis Example 1

A 300 ml flask was charged with 11.1 g of tetraethoxysilane, 2.7 g of methyltriethoxysilane, 1.8 g of 4-cyclohexenylethyltrimethoxysilane, and 62.5 g of propylene glycol monoethyl ether. While the resultant mixed solution was stirred with a magnetic stirrer, 8.4 g of 0.2 M aqueous nitric acid solution was added dropwise to the mixed solution.

After the dropwise addition, the flask was transferred to an oil bath set at 60° C. and the mixed solution was refluxed for 20 hours. Thereafter, ethanol, methanol, and water, i.e. reaction by-products, were distilled off under reduced pressure for concentration to obtain a hydrolysis condensate (polymer) solution.

Further, propylene glycol monoethyl ether was added to the solution to achieve a solvent proportion of propylene glycol monoethyl ether of 100% and a concentration of 20 mass % in terms of solid residue at 150° C. The resultant solution was subjected to filtration with a nylon-made filter (pore size: 0.1 μm). The resultant polymer was found to contain a structure represented by the following Formula (E1), and to have a weight-average molecular weight Mw of 1,500 as determined by GPC in terms of polystyrene.

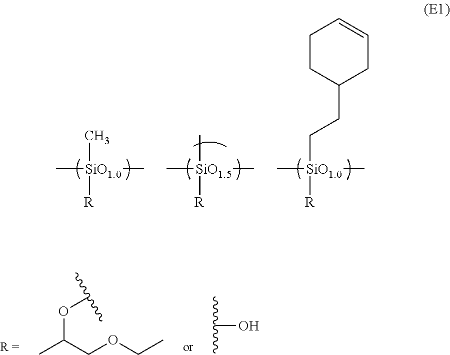

### Synthesis Example 2

A 300 ml flask was charged with 11.1 g of tetraethoxysilane, 2.7 g of methyltriethoxysilane, 2.1 g of 1,4-pentadienyl-3-propyltriethoxysilane, and 63.7 g of propylene glycol monoethyl ether. While the resultant mixed solution was stirred with a magnetic stirrer, 8.4 g of 0.2 M aqueous nitric acid solution was added dropwise to the mixed solution.

After the dropwise addition, the flask was transferred to an oil bath set at 60° C. and the mixed solution was refluxed for 20 hours. Thereafter, ethanol, and water, i.e. reaction by-products, were distilled off under reduced pressure for concentration to obtain a hydrolysis condensate (polymer) solution.

Further, propylene glycol monoethyl ether was added to the solution to achieve a solvent proportion of propylene glycol monoethyl ether of 100% and a concentration of 20 mass % in terms of solid residue at 150° C. The resultant solution was subjected to filtration with a nylon-made filter (pore size: 0.1 μm). The resultant polymer was found to contain a structure represented by the following Formula (E2), and to have a weight-average molecular weight Mw of 1,900 as determined by GPC in terms of polystyrene.

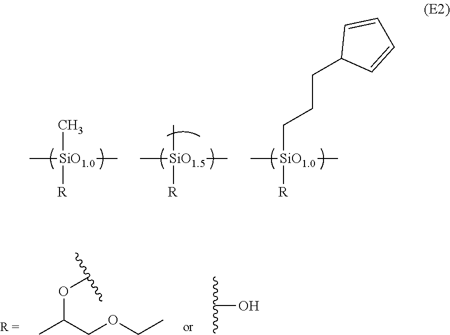

### Synthesis Example 3

A 300 ml flask was charged with 11.1 g of tetraethoxysilane, 2.7 g of methyltriethoxysilane, 2.0 g of norbornene triethoxysilane, and 39.0 g of propylene glycol monoethyl ether. While the resultant mixed solution was stirred with a magnetic stirrer, 8.4 g of 0.2M aqueous nitric acid solution was added dropwise to the mixed solution.

After the dropwise addition, the flask was transferred to an oil bath set at 60° C. and the mixed solution was refluxed for 20 hours. Thereafter, ethanol, and water, i.e. reaction by-products, were distilled off under reduced pressure for concentration to obtain a hydrolysis condensate (polymer) solution.

Further, propylene glycol monoethyl ether was added to the solution to achieve a solvent proportion of propylene glycol monoethyl ether of 100% and a concentration of 20 mass % in terms of solid residue at 150° C. The resultant solution was subjected to filtration with a nylon-made filter (pore size: 0.1 μm). The resultant polymer was found to contain a structure represented by the following Formula (E3), and to have a weight-average molecular weight Mw of 1,500 as determined by GPC in terms of polystyrene.

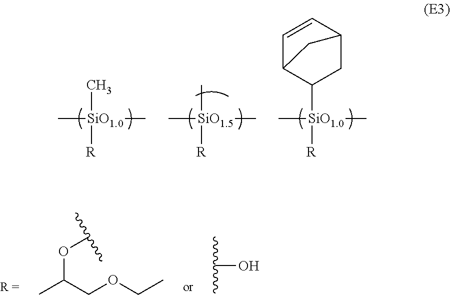

### Synthesis Example 4

A 300 ml flask was charged with 11.1 g of tetraethoxysilane, 2.7 g of methyltriethoxysilane, 1.5 g of phenyltrimethoxysilane, and 61.5 g of propylene glycol monoethyl ether. While the resultant mixed solution was stirred with a magnetic stirrer, 8.4 g of 0.2M aqueous nitric acid solution was added dropwise to the mixed solution.

After the dropwise addition, the flask was transferred to an oil bath set at 60° C. and the mixed solution was refluxed for 20 hours. Thereafter, ethanol, methanol, and water, i.e. reaction by-products, were distilled off under reduced pressure for concentration to obtain a hydrolysis condensate (polymer) solution.

Further, propylene glycol monoethyl ether was added to the solution to achieve a solvent proportion of propylene glycol monoethyl ether of 100% and a concentration of 20 mass % in terms of solid residue at 150° C. The resultant solution was subjected to filtration with a nylon-made filter (pore size: 0.1 μm). The resultant polymer was found to contain a structure represented by the following Formula (E4), and to have a weight-average molecular weight Mw of 2,700 as determined by GPC in terms of polystyrene.

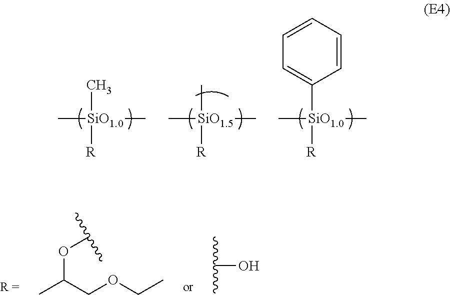

### Synthesis Example 5

A 300 ml flask was charged with 11.1 g of tetraethoxysilane, 2.7 g of methyltriethoxysilane, 2.5 g of pentafluorophenyltrimethoxysilane, and 42.5 g of propylene glycol monoethyl ether. While the resultant mixed solution was stirred with a magnetic stirrer, 8.4 g of 0.2M aqueous nitric acid solution was added dropwise to the mixed solution.

After the dropwise addition, the flask was transferred to an oil bath set at 60° C. and the mixed solution was refluxed for 20 hours. Thereafter, ethanol, methanol, and water, i.e. reaction by-products, were distilled off under reduced pressure for concentration to obtain a hydrolysis condensate (polymer) solution.

Further, propylene glycol monoethyl ether was added to the solution to achieve a solvent proportion of propylene glycol monoethyl ether of 100% and a concentration of 20 mass % in terms of solid residue at 150° C. The resultant solution was subjected to filtration with a nylon-made filter (pore size: 0.1 μm). The resultant polymer was found to contain a structure represented by the following Formula (E5), and to have a weight-average molecular weight Mw of 1,600 as determined by GPC in terms of polystyrene.

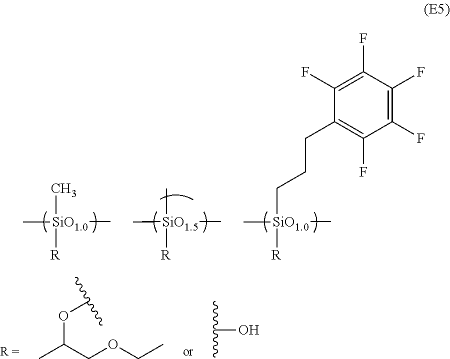

### Synthesis Example 6

A 300 ml flask was charged with 11.1 g of tetraethoxysilane, 2.7 g of methyltriethoxysilane, 1.8 g of N-propyl tri methoxy silyl pyrrole, and 36.4 g of propylene glycol monoethyl ether. While the resultant mixed solution was stirred with a magnetic stirrer, 8.4 g of 0.2M aqueous nitric acid solution was added dropwise to the mixed solution.

After the dropwise addition, the flask was transferred to an oil bath set at 60° C. and the mixed solution was refluxed for 20 hours. Thereafter, ethanol, methanol, and water, i.e. reaction by-products, were distilled off under reduced pressure for concentration to obtain a hydrolysis condensate (polymer) solution.

Further, propylene glycol monoethyl ether was added to the solution to achieve a solvent proportion of propylene glycol monoethyl ether of 100% and a concentration of 20 mass % in terms of solid residue at 150° C. The resultant solution was subjected to filtration with a nylon-made filter (pore size: 0.1 μm). The resultant polymer was found to contain a structure represented by the following Formula (E6), and to have a weight-average molecular weight Mw of 5,300 as determined by GPC in terms of polystyrene.

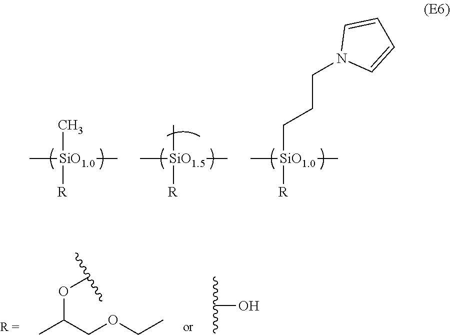

### Synthesis Example 7

A 300 ml flask was charged with 11.1 g of tetraethoxysilane, 2.7 g of methyltriethoxysilane, 1.8 g of furyl propyltriethoxysilane, and 36.5 g of propylene glycol monoethyl ether. While the resultant mixed solution was stirred with a magnetic stirrer, 8.4 g of 0.2M aqueous nitric acid solution was added dropwise to the mixed solution.

After the dropwise addition, the flask was transferred to an oil bath set at 60° C. and the mixed solution was refluxed for 20 hours. Thereafter, ethanol, and water, i.e. reaction by-products, were distilled off under reduced pressure for concentration to obtain a hydrolysis condensate (polymer) solution.

Further, propylene glycol monoethyl ether was added to the solution to achieve a solvent proportion of propylene glycol monoethyl ether of 100% and a concentration of 20 mass % in terms of solid residue at 150° C. The resultant solution was subjected to filtration with a nylon-made filter (pore size: 0.1 μm). The resultant polymer was found to contain a structure represented by the following Formula (E7), and to have a weight-average molecular weight Mw of 4,800 as determined by GPC in terms of polystyrene.

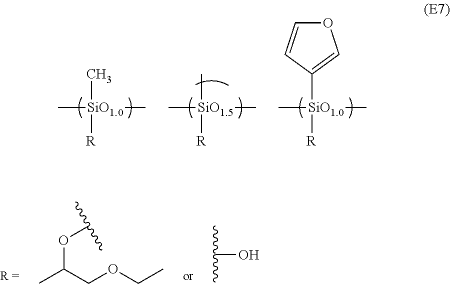

### Synthesis Example 8

A 300 ml flask was charged with 11.1 g of tetraethoxysilane, 2.7 g of methyltriethoxysilane, 1.8 g of Meldrum's acid allyl propyltriethoxysilane, and 36.5 g of propylene glycol monoethyl ether. While the resultant mixed solution was stirred with a magnetic stirrer, 8.4 g of 0.2M aqueous nitric acid solution was added dropwise to the mixed solution.

After the dropwise addition, the flask was transferred to an oil bath set at 60° C. and the mixed solution was refluxed for 20 hours. Thereafter, ethanol, and water, i.e. reaction by-products, were distilled off under reduced pressure for concentration to obtain a hydrolysis condensate (polymer) solution.

Further, propylene glycol monoethyl ether was added to the solution to achieve a solvent proportion of propylene glycol monoethyl ether of 100% and a concentration of 20 mass % in terms of solid residue at 150° C. The resultant solution was subjected to filtration with a nylon-made filter (pore size: 0.1 μm). The resultant polymer was found to contain a structure represented by the following Formula (E8), and to have a weight-average molecular weight Mw of 3,000 as determined by GPC in terms of polystyrene.

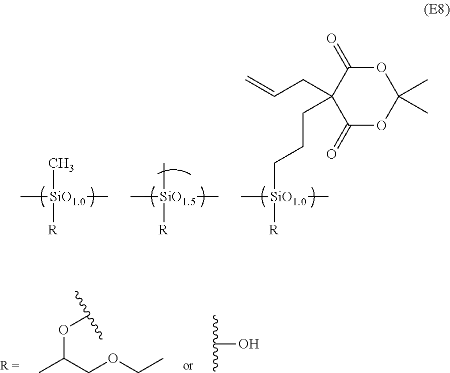

### Synthesis Example 9

A 300 ml flask was charged with 11.1 g of tetraethoxysilane, 2.7 g of methyltriethoxysilane, 3.2 g of N,N-diallyl isocyanurate propyltriethoxysilane, and 68.1 g of propylene glycol monoethyl ether. While the resultant mixed solution was stirred with a magnetic stirrer, 8.4 g of 0.2M aqueous nitric acid solution was added dropwise to the mixed solution.

After the dropwise addition, the flask was transferred to an oil bath set at 60° C. and the mixed solution was refluxed for 20 hours. Thereafter, ethanol, and water, i.e. reaction by-products, were distilled off under reduced pressure for concentration to obtain a hydrolysis condensate (polymer) solution.

Further, propylene glycol monoethyl ether was added to the solution to achieve a solvent proportion of propylene glycol monoethyl ether of 100% and a concentration of 20 mass % in terms of solid residue at 150° C. The resultant solution was subjected to filtration with a nylon-made filter (pore size: 0.1 μm). The resultant polymer was found to contain a structure represented by the following Formula (E9), and to have a weight-average molecular weight Mw of 1,640 as determined by GPC in terms of polystyrene.

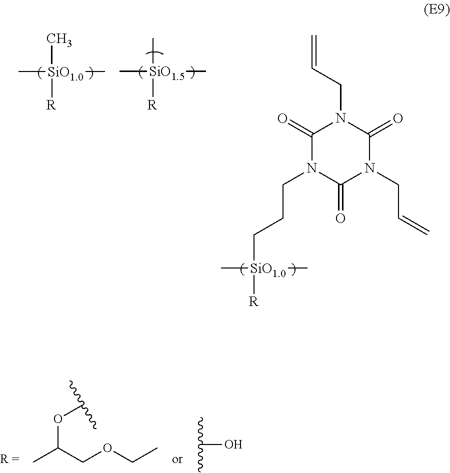

### Synthesis Example 10

A 300 ml flask was charged with 11.1 g of tetraethoxysilane, 2.7 g of methyltriethoxysilane, 3.1 g of N,N-dimethyl isocyanurate propyltrimethoxysilane, and 68.1 g of propylene glycol monoethyl ether. While the resultant mixed solution was stirred with a magnetic stirrer, 8.4 g of 0.2M aqueous nitric acid solution was added dropwise to the mixed solution.

After the dropwise addition, the flask was transferred to an oil bath set at 60° C. and the mixed solution was refluxed for 20 hours. Thereafter, ethanol, methanol, and water, i.e. reaction by-products, were distilled off under reduced pressure for concentration to obtain a hydrolysis condensate (polymer) solution.

Further, propylene glycol monoethyl ether was added to the solution to achieve a solvent proportion of propylene glycol monoethyl ether of 100% and a concentration of 20 mass % in terms of solid residue at 150° C. The resultant solution was subjected to filtration with a nylon-made filter (pore size: 0.1 μm). The resultant polymer was found to contain a structure represented by the following Formula (E10), and to have a weight-average molecular weight Mw of 1,600 as determined by GPC in terms of polystyrene.

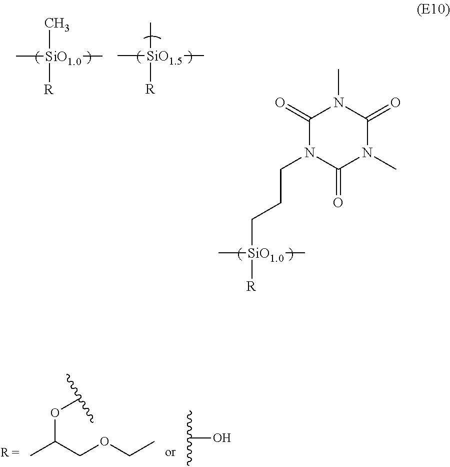

### Synthesis Example 11

A 300 ml flask was charged with 11.1 g of tetraethoxysilane, 2.7 g of methyltriethoxysilane, 2.3 g of propyltriethoxysilyl succinic anhydride and 24.3 g of propylene glycol monoethyl ether. While the resultant mixed solution was stirred with a magnetic stirrer, 8.4 g of 0.2M aqueous nitric acid solution was added dropwise to the mixed solution.

After the dropwise addition, the flask was transferred to an oil bath set at 60° C. and the mixed solution was refluxed for 20 hours. Thereafter, ethanol, and water, i.e. reaction by-products, were distilled off under reduced pressure for concentration to obtain a hydrolysis condensate (polymer) solution.

Further, propylene glycol monoethyl ether was added to the solution to achieve a solvent proportion of propylene glycol monoethyl ether of 100% and a concentration of 20 mass % in terms of solid residue at 150° C. The resultant solution was subjected to filtration with a nylon-made filter (pore size: 0.1 μm). The resultant polymer was found to contain a structure represented by the following Formula (E11), and to have a weight-average molecular weight Mw of 5,060 as determined by GPC in terms of polystyrene.

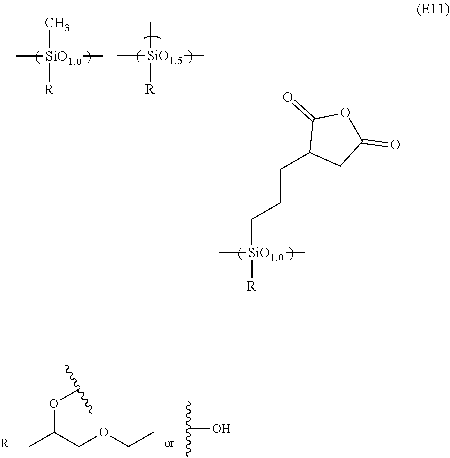

### Comparative Synthesis Example 1

A 300 ml flask was charged with 11.1 g of tetraethoxysilane, 4.1 g of methyltriethoxysilane, and 22.7 g of propylene glycol monoethyl ether. While the resultant mixed solution was stirred with a magnetic stirrer, 8.4 g of 0.2M aqueous nitric acid solution was added dropwise to the mixed solution.

After the dropwise addition, the flask was transferred to an oil bath set at 60° C. and the mixed solution was refluxed for 20 hours. Thereafter, ethanol, and water, i.e. reaction by-products, were distilled off under reduced pressure for concentration to obtain a hydrolysis condensate (polymer) solution.

Further, propylene glycol monoethyl ether was added to the solution to achieve a solvent proportion of propylene glycol monoethyl ether of 100% and a concentration of 20 mass % in terms of solid residue at 150° C. The resultant solution was subjected to filtration with a nylon-made filter (pore size: 0.1 μm). The resultant polymer was found to contain a structure represented by the following Formula (E12), and to have a weight-average molecular weight Mw of 5,500 as determined by GPC in terms of polystyrene.

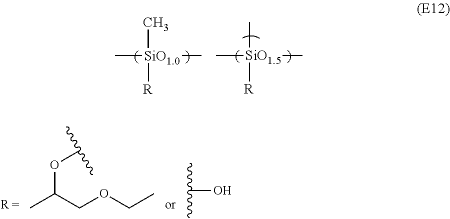

### Comparative Synthesis Example 2

A 300 ml flask was charged with 11.1 g of tetraethoxysilane, 2.7 g of methyltriethoxysilane, 1.5 g of cyclohexyltriethoxysilane, and 61.5 g of propylene glycol monoethyl ether. While the resultant mixed solution was stirred with a magnetic stirrer, 8.4 g of 0.2M aqueous nitric acid solution was added dropwise to the mixed solution.

After the dropwise addition, the flask was transferred to an oil bath set at 60° C. and the mixed solution was refluxed for 20 hours. Thereafter, ethanol, and water, i.e. reaction by-products, were distilled off under reduced pressure for concentration to obtain a hydrolysis condensate (polymer) solution.

Further, propylene glycol monoethyl ether was added to the solution to achieve a solvent proportion of propylene glycol monoethyl ether of 100% and a concentration of 20 mass % in terms of solid residue at 150° C. The resultant solution was subjected to filtration with a nylon-made filter (pore size: 0.1 μm). The resultant polymer was found to contain a structure represented by the following Formula (E13), and to have a weight-average molecular weight Mw of 2,400 as determined by GPC in terms of polystyrene.

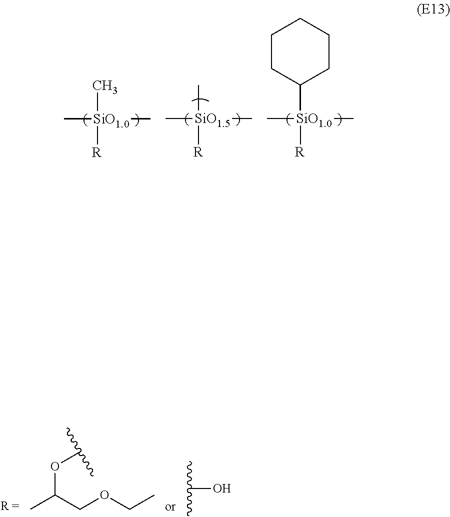

### Comparative Synthesis Example 3

A 300 ml flask was charged with 11.1 g of tetraethoxysilane, 1.4 g of methyltriethoxysilane, 2.3 g of vinyltrimethoxysilane, and 34.5 g of propylene glycol monoethyl ether. While the resultant mixed solution was stirred with a magnetic stirrer, 8.4 g of 0.2M aqueous nitric acid solution was added dropwise to the mixed solution.

After the dropwise addition, the flask was transferred to an oil bath set at 60° C. and the mixed solution was refluxed for 20 hours. Thereafter, ethanol, methanol, and water, i.e. reaction by-products, were distilled off under reduced pressure for concentration to obtain a hydrolysis condensate (polymer) solution.

Further, propylene glycol monoethyl ether was added to the solution to achieve a solvent proportion of propylene glycol monoethyl ether of 100% and a concentration of 20 mass % in terms of solid residue at 150° C. The resultant solution was subjected to filtration with a nylon-made filter (pore size: 0.1 μm). The resultant polymer was found to contain a structure represented by the following Formula (E14), and to have a weight-average molecular weight Mw of 2,151 as determined by GPC in terms of polystyrene.

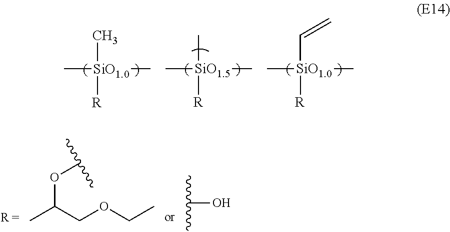

### [2] Preparation of Composition Applied to Resist Pattern

The polysiloxane (polymer) produced in each of the Synthesis Examples describe above, a stabilizer (additive 1), a curing catalyst (additive 2), a high-boiling-point glycol compound (additive 3), and a solvent were mixed in proportions shown in Table 1. The resultant mixture was filtered through a 0.1 μm fluororesin-made filter, and thus each composition to be applied to resist pattern is prepared. In Table 1, the amount of each component added is shown by part(s) by mass.

Although the composition was prepared from the solution containing the hydrolysis condensate (polymer) produced in each Synthesis Example, the amount of each polymer shown in Table 1 corresponds not to the amount of the polymer solution, but to the amount of the polymer itself.

Abbreviations in Table 1 are as follows.

### <Solvent>

DIW: ultrapure water
PGEE: propylene glycol monoethyl ether
PGME: propylene glycol monomethyl ether

### <Additive 1>

MA: maleic acid

### <Additive 2>

TPSNO3: triphenylsulfonium nitrate

### <Additive 3>

Farnesol: (isomer mixture, chain unsaturated alcohol)

TABLE 1

| | Polymer | Additive 1 | Additive 2 | Additive 3 | Solvent | | |
|---|---|---|---|---|---|---|---|
| Example 1 | Synthesis | MA | TPSNO3 | | PGEE | PGME | DIW |
| | Example 1 | | | | | | |
| (part(s) by | 0.5 | 0.005 | 0.005 | | 80 | 8 | 12 |
| mass) | | | | | | | |
| Example 2 | Synthesis | MA | TPSNO3 | | PGEE | PGME | DIW |
| | Example 2 | | | | | | |
| (part(s) by | 0.5 | 0.005 | 0.005 | | 80 | 8 | 12 |
| mass) | | | | | | | |
| Example 3 | Synthesis | MA | TPSNO3 | | PGEE | PGME | DIW |
| | Example 3 | | | | | | |
| (part(s) by | 0.5 | 0.005 | 0.005 | | 80 | 8 | 12 |
| mass) | | | | | | | |
| Example 4 | Synthesis | MA | TPSNO3 | | PGEE | PGME | DIW |
| | Example 4 | | | | | | |
| (part(s) by | 0.5 | 0.005 | 0.005 | | 80 | 8 | 12 |
| mass) | | | | | | | |
| Example 5 | Synthesis | MA | TPSNO3 | | PGEE | PGME | DIW |
| | Example 5 | | | | | | |
| (part(s) by | 0.5 | 0.005 | 0.005 | | 80 | 8 | 12 |
| mass) | | | | | | | |
| Example 6 | Synthesis | MA | TPSNO3 | | PGEE | PGME | DIW |
| | Example 6 | | | | | | |
| (part(s) by | 0.5 | 0.005 | 0.005 | | 80 | 8 | 12 |
| mass) | | | | | | | |
| Example 7 | Synthesis | MA | TPSNO3 | | PGEE | PGME | DIW |
| | Example 7 | | | | | | |
| (part(s) by | 0.5 | 0.005 | 0.005 | | 80 | 8 | 12 |
| mass) | | | | | | | |
| Example 8 | Synthesis | MA | TPSNO3 | | PGEE | PGME | DIW |
| | Example 8 | | | | | | |
| (part(s) by | 0.5 | 0.005 | 0.005 | | 80 | 8 | 12 |
| mass) | | | | | | | |
| Example 9 | Synthesis | MA | TPSNO3 | | PGEE | PGME | DIW |
| | Example 9 | | | | | | |
| (part(s) by | 0.5 | 0.005 | 0.005 | | 80 | 8 | 12 |
| mass) | | | | | | | |
| Example 10 | Synthesis | MA | TPSNO3 | | PGEE | PGME | DIW |
| | Example 10 | | | | | | |
| (part(s) by | 0.5 | 0.005 | 0.005 | | 80 | 8 | 12 |
| mass) | | | | | | | |
| Example 11 | Synthesis | MA | TPSNO3 | | PGEE | PGME | DIW |
| | Example 11 | | | | | | |
| (part(s) by | 0.5 | 0.005 | 0.005 | | 80 | 8 | 12 |
| mass) | | | | | | | |
| Comparative | Comparative | MA | TPSNO3 | | PGEE | PGME | DIW |
| Example 1 | Synthesis | | | | | | |
| | Example 1 | | | | | | |
| (part(s) by | 0.5 | 0.005 | 0.005 | | 80 | 8 | 12 |
| mass) | | | | | | | |
| Comparative | Comparative | MA | TPSNO3 | | PGEE | PGME | DIW |
| Example 2 | Synthesis | | | | | | |
| | Example 2 | | | | | | |
| (part(s) by | 0.5 | 0.005 | 0.005 | | 80 | 8 | 12 |
| mass) | | | | | | | |
| Comparative | Comparative | MA | TPSNO3 | | PGEE | PGME | DIW |
| Example 3 | Synthesis | | | | | | |
| | Example 3 | | | | | | |
| (part(s) by | 0.5 | 0.005 | 0.005 | | 80 | 8 | 12 |
| mass) | | | | | | | |
| Comparative | Comparative | MA | TPSNO3 | Farnesol | PGEE | PGME | DIW |
| Example 4 | Synthesis | | | | | | |
| | Example 1 | | | | | | |
| (part(s) by | 0.5 | 0.005 | 0.005 | 0.025 | 80 | 8 | 12 |
| mass) | | | | | | | |

*Examples 1 to 11 and Comparative Examples 1 to 4 further contain nitric acid contained in the polymer solution prepared in each Synthesis Example.

### [3] Preparation of Organic Resist Underlayer Film-Forming Composition

In a nitrogen atmosphere, a 100-mL four-necked flask was charged with 6.69 g (0.040 mol) of carbazole (manufactured by Tokyo Chemical Industry Co., Ltd.), 7.28 g (0.040 mol) of 9-fluorenone (manufactured by Tokyo Chemical Industry Co., Ltd.), and 0.76 g (0.0040 mol) of p-toluenesulfonic acid monohydrate (manufactured by Tokyo Chemical Industry Co., Ltd.), and then 6.69 g of 1,4-dioxane (manufactured by Kanto Chemical Co., Inc.) was added to the flask. The resultant mixture was stirred and then heated to 100° C. for dissolution, and thus polymerization was initiated. After 24 hours, the mixture was allowed to cool to 60° C.

The cooled reaction mixture was diluted with 34 g of chloroform (manufactured by Kanto Chemical Co., Inc.), and the diluted mixture was added to 168 g of methanol (manufactured by Kanto Chemical Co., Inc.) for precipitation.

The resultant precipitate was subjected to filtration and recovery, and the recovered solid was dried with a reduced-pressure dryer at 80° C. for 24 hours to obtain 9.37 g of a desired polymer represented by Formula (X) (hereinafter, abbreviated as PCzFL).

The results of ¹H-NMR measurement of PCzFL were as follows.

¹H-NMR (400 MHz, DMSO-d6): δ7.03-7.55 (br, 12H), δ7.61-8.10 (br, 4H), δ11.18 (br, 1H)

Further, PCzFL was found to have a weight-average molecular weight (Mw) of 2,800 as determined by GPC in terms of polystyrene and a polydispersity Mw/Mn of 1.77.

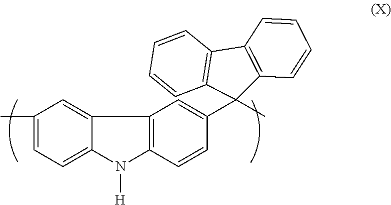

20 g of PCzFL was mixed with 3.0 g of tetramethoxymethyl glycoluril (trade name: Powderlink 1174, manufactured by Cytec Industries Japan LLC. (former Mitsui Cytec Ltd.)) as a crosslinking agent, 0.30 g of pyridinium p-toluenesulfonate as a catalyst, and 0.06 g of MEGAFACE R-30 (trade name, manufactured by DIC Corporation) as a surfactant, and the mixture was dissolved in 88 g of propylene glycol monomethyl ether acetate to prepare a solution. Thereafter, the solution was filtered with a polyethylene-made microfilter (pore size: 0.10 μm), and then the resultant solution was filtered with a polyethylene-made microfilter (pore size: 0.05 μm) to prepare an organic resist underlayer film-forming composition used for a lithography process using a multilayer film.

### [4] Test for Solvent Resistance

Each of the compositions prepared in Examples 1 to 11 and Comparative Examples 1 to 4 was applied onto a silicon wafer with a spinner. Then, the resultant wafer was heated on a hot plate at 215° C. for one minute to form an Si-containing resist underlayer film. The thickness of the resultant underlayer film was measured. The thickness was approximately 10 nm.

Thereafter, a mixed solvent of propylene glycol monomethyl ether/propylene glycol monomethyl ether acetate (7/3 (V/V)) was applied onto the Si-containing resist underlayer film, and then spin-dried. The thickness of the underlayer film was measured after application of the solvent, thereby evaluating the change (%) in film thickness between before application of the mixed solvent as a reference (100%) and after application of the mixed solvent. Solvent resistance was evaluated as “Good” when a film had a film thickness change of 1% or less before and after application of the mixed solvent, whereas solvent resistance was evaluated as “Not cured” when a film had a film thickness change of more than 1%.

TABLE 2

| | Solvent resistance |
|---|---|
| Example 1 | Good |
| Example 2 | Good |
| Example 3 | Good |
| Example 4 | Good |
| Example 5 | Good |
| Example 6 | Good |
| Example 7 | Good |
| Example 8 | Good |
| Example 9 | Good |
| Example 10 | Good |
| Example 11 | Good |
| Comparative Example 1 | Good |
| Comparative Example 2 | Good |
| Comparative Example 3 | Good |
| Comparative Example 4 | Good |

### [5] Formation of Resist Pattern by EUV Exposure: Negative Organic Solvent Development

The organic resist underlayer film-forming composition was applied onto a silicon wafer using a spinner, and baked on a hot plate at 215° C. for 60 seconds to form an organic underlayer film (A layer) having a thickness of 60 nm. The composition prepared in Example 1 was applied onto the organic underlayer film by spin coating, and then heated at 215° C. for 1 minute to form a resist underlayer film (B) layer (thickness: 10 nm).

Further, an EUV resist solution (tin oxide-based resist) was applied onto the resist underlayer film by spin coating, and heated at 130° C. for 1 minute to form an EUV resist layer (C). Thereafter, the EUV resist layer (C) was exposed to light by using an EUV exposure apparatus (NXE3400B), manufactured by ASML, under the following conditions: NA=0.33, σ=0.878/0.353 (outer/inner), and Dipole. During exposure, the resist layer was exposed to light through a mask designed to achieve a line width of 16 nm and an interline width of 16 nm (i.e. a 16-nm line-and-space (L/S)=1/1 dense line) in the EUV resist after development as described below.

After the light exposure, post exposure bake (PEB, at 170° C., for one minute) was performed, and then the resist layer was cooled on a cooling plate to room temperature, followed by development with an organic solvent (propylene glycol monomethyl ether acetate) for 60 seconds and rinsing treatment to form a resist pattern.

Each of the compositions prepared in Examples 2 to 11 and Comparative Examples 1 to 4 was used, and a resist pattern was formed through a similar procedure as described above.

A length measuring SEM (CG4100), manufactured by Hitachi High-Technologies Corporation, was used to measure the amount of light exposure formed with a line dimension of 16 nm. The measured amount of light exposure was used as sensitivity. Further, the line width of 120 lines in this case was measured to determine line width roughness (LWR). The results are shown in Table 3.

TABLE 3

| | Sensitivity (mJ/cm²) | LWR (nm) |
|---|---|---|
| Example 1 | 63.4 | 3.86 |
| Example 2 | 62.2 | 3.97 |
| Example 3 | 62.2 | 3.97 |
| Example 4 | 62.2 | 3.97 |
| Example 5 | 62.2 | 3.97 |
| Example 6 | 62.2 | 3.97 |
| Example 7 | 62.2 | 3.97 |
| Example 8 | 63.5 | 3.92 |
| Example 9 | 62.0 | 3.85 |
| Example 10 | 62.1 | 3.90 |
| Example 11 | 62.6 | 3.87 |
| Comparative Example 1 | 62.5 | 4.11 |
| Comparative Example 2 | 65.1 | 4.00 |
| Comparative Example 3 | 61.1 | 4.06 |
| Comparative Example 4 | 62.3 | 4.06 |

As shown in Table 3, it can be seen that when a film formed using the silicon-containing resist underlayer film-forming composition of the present invention is used as a resist underlayer film, a large decrease in sensitivity is not caused even in fine patterning, and the pattern width roughness (LWR) can be improved. Meanwhile, in Comparative Example 1 using a hydrolyzable silane not having an unsaturated bond and an alicyclic structure, Comparative Example 2 using a hydrolyzable silane having a cyclic structure but not having an unsaturated bond, Comparative Example 3 using a hydrolyzable silane containing, as a group bonding to Si, a (chain-structured) group having an unsaturated bond but not having a cyclic structure, and Comparative Example 4 further containing a chain unsaturated alcohol as an additive, the pattern width roughness (LWR) was inferior to that in the Examples.

The reason why the silicon-containing resist underlayer film-forming composition using a hydrolyzable silane containing, as a group bonding to Si, an organic group having an unsaturated bond and a ring structure is effective in improving the roughness in the fine patterning of the metal oxide resist is not strictly known. As one of hypotheses, it is considered that the unsaturated bond or conjugated system affected by distortion of the ring structure quenches a part of the chemical species or secondary electrons that promote the resist curing occurred in an exposed portion in the metal oxide resist, thereby suppressing diffusion of chemical species or secondary electrons to an unexposed portion of the resist, and as a result, the roughness is improved. The mechanism is still under investigation.

1. A silicon-containing resist underlayer film-forming composition for forming a silicon-containing resist underlayer film between a metal-containing resist film and a substrate, the silicon-containing resist underlayer film-forming composition comprising:
a component [A]: a polysiloxane; and
a component [C]: a solvent,
wherein the polysiloxane contains a structural unit derived from a hydrolyzable silane (A) represented by the following Formula (A-1): 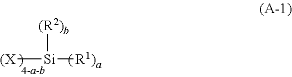
where in Formula (A-1), a represents an integer of 1 to 3,
b represents an integer of 0 to 2,
a+b represents an integer of 1 to 3,
R¹ represents an organic group having an unsaturated bond and a ring structure,
R² represents an optionally substituted alkyl group, an optionally substituted alkyl halide group, an optionally substituted alkoxyalkyl group, or an optionally substituted alkenyl group, or represents an organic group having an epoxy group, an organic group having an acryloyl group, an organic group having a methacryloyl group, an organic group having a mercapto group, an organic group having an amino group, an organic group having an alkoxy group, an organic group having a sulfonyl group or an organic group having a cyano group, or a combination of two or more of the groups,
X represents an alkoxy group, an aralkyloxy group, an acyloxy group, or a halogen atom, and
when a plurality of R¹s, R²s, or Xs is present, the plurality of R¹s, R²s, or Xs may be identical to or different from each other or one another.

2. A silicon-containing resist underlayer film-forming composition for forming a silicon-containing resist underlayer film between a metal-containing resist film and a substrate, the silicon-containing resist underlayer film-forming composition comprising:
a component [A′]: a polysiloxane;
a component [B]: a hydrolyzable silane (A) represented by the following Formula (A-1); and
a component [C]: a solvent, 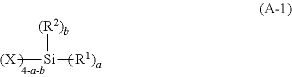
where in Formula (A-1), a represents an integer of 1 to 3,
b represents an integer of 0 to 2,
a+b represents an integer of 1 to 3,
R¹ represents an organic group having an unsaturated bond and a ring structure,
R² represents an optionally substituted alkyl group, an optionally substituted alkyl halide group, an optionally substituted alkoxyalkyl group, or an optionally substituted alkenyl group, or represents an organic group having an epoxy group, an organic group having an acryloyl group, an organic group having a methacryloyl group, an organic group having a mercapto group, an organic group having an amino group, an organic group having an alkoxy group, an organic group having a sulfonyl group or an organic group having a cyano group, or a combination of two or more of the groups,
X represents an alkoxy group, an aralkyloxy group, an acyloxy group, or a halogen atom, and
when a plurality of R¹s, R²s, or Xs is present, the plurality of R¹s, R²s, or Xs may be identical to or different from each other or one another.

3. The silicon-containing resist underlayer film-forming composition according to claim 1, wherein R¹ in Formula (A-1) is represented by the following Formula (A-2a): 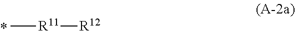
where in Formula (A-2a), R¹¹ represents a single bond or a divalent organic group which may have an ionic bond,
R¹² represents a group having an unsaturated bond and a ring structure, and
an asterisk * represents a bonding hand.

4. The silicon-containing resist underlayer film-forming composition according to claim 3, wherein R¹² in Formula (A-2a) is represented by the following Formula (A-2b): 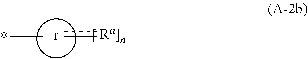
where in Formula (A-2b), r represents a ring structure, [symbol]
represents a single bond or a double bond, provided that, when [symbol]
represents a single bond, R^{a} represents a halogen atom or a monovalent group, and when [symbol]
represents a double bond, R^{a} represents an oxygen atom,
n is 0 or more and represents a value less than or equal to a number n of substituents that the ring structure r may have,
when n is 2 or more, [symbol]
and R^{a} may be identical or different,
when the ring structure r has a double bond in a bond forming the ring, n may be 0,
when the ring structure r has only a single bond as the bond forming the ring, n is 1 or more, and at least one of [symbol]
is a double bond or at least one R^{a} has an unsaturated bond, and
an asterisk * represents a bonding hand.

5. The silicon-containing resist underlayer film-forming composition according to claim 4, wherein the ring structure r is a monocyclic 5-membered ring structure, a monocyclic 6-membered ring structure, a bicyclic structure, or a tricyclic structure.

6. The silicon-containing resist underlayer film-forming composition according to claim 4, wherein Formula (A-2b) is any one of the following Formulae (A-2c-1) to (A-2c-6): 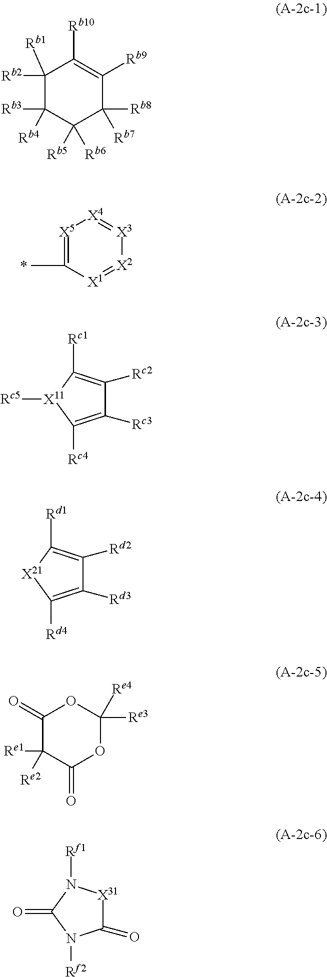
where in Formula (A-2c-1), R^{1b} to R^{b10} each independently represent a hydrogen atom, a halogen atom, or a monovalent group, R^{b1} and R^{b8} may be combined to form a methylene group or a 1,2-ethylene group, provided that one of R^{1b} to R^{b10} represents a bonding hand bonded to R¹¹ in Formula (A-2a),
in Formula (A-2c-2), X¹ to X⁵ each represent N or CR (provided that Rs each independently represent a hydrogen atom, a halogen atom, or a monovalent group), an asterisk * represents a bonding hand,
in Formula (A-2c-3), X¹¹ represents N or CR (provided that R represents a hydrogen atom, a halogen atom, or a monovalent group), R^{c1} to R^{c5} each independently represent a hydrogen atom, a halogen atom, or a monovalent group, provided that one of R^{c1} to R^{c5} represents a bonding hand bonded to R¹¹ in Formula (A-2a),
in Formula (A-2c-4), X²¹ represents O or S, R^{d1} to R^{d4} each independently represent a hydrogen atom, a halogen atom, or a monovalent group, provided that one of R^{d1} to R^{d4} represents a bonding hand bonded to R¹¹ in Formula (A-2a),
in Formula (A-2c-5), R^{e1} to R^{e4} each independently represent a hydrogen atom, a halogen atom, or a monovalent group, provided that one of R^{e1} to R^{e4} represents a bonding hand bonded to R¹¹ in Formula (A-2a),
in Formula (A-2c-6), X³¹ represents —C(═O)—N(R^{f3})-, —C(═O)—C(R^{f4})(R^{f5})—, or —C(R^{f6})(R^{f7})—, R^{f1} to R^{f7} each independently represent a hydrogen atom, a halogen atom, or a monovalent group, provided that one of R^{f1} and R^{f7} represents a bonding hand bonded to R¹¹ in Formula (A-2a).

7. The silicon-containing resist underlayer film-forming composition according to claim 1, wherein the polysiloxane as the component [A] is a modified polysiloxane in which some of silanol groups are alcohol-modified or acetal-protected.

8. The silicon-containing resist underlayer film-forming composition according to claim 2, wherein the polysiloxane as the component [A′] is a modified polysiloxane in which some of silanol groups are alcohol-modified or acetal-protected.

9. The silicon-containing resist underlayer film-forming composition according to claim 1, wherein the component [C] contains an alcohol-based solvent.

10. The silicon-containing resist underlayer film-forming composition according to claim 9, wherein the component [C] contains propylene glycol monoalkyl ether.

11. The silicon-containing resist underlayer film-forming composition according to claim 1, further comprising a component [D]: a curing catalyst.

12. The silicon-containing resist underlayer film-forming composition according to claim 1, further comprising a component [E]: nitric acid.

13. The silicon-containing resist underlayer film-forming composition according to claim 1, wherein the component [C] contains water.

14. The silicon-containing resist underlayer film-forming composition according to claim 1, which is for forming a resist underlayer film for EUV lithography.

15. A silicon-containing resist underlayer film which is a cured product of the silicon-containing resist underlayer film-forming composition according to claim 1.

16. A semiconductor processing substrate comprising:
a semiconductor substrate; and
the silicon-containing resist underlayer film according to claim 15.

17. A method for producing a semiconductor element, the method comprising:
forming an organic underlayer film on a substrate;
forming a resist underlayer film on the organic underlayer film using the silicon-containing resist underlayer film-forming composition according to claim 1; and
forming a metal-containing resist film on the resist underlayer film.

18. The method for producing a semiconductor element according to claim 17, wherein the metal-containing resist film is formed of a metal-containing resist for EUV lithography.

19. The method for producing a semiconductor element according to claim 17,
wherein in the forming the resist underlayer film, the silicon-containing resist underlayer film-forming composition to be used is filtered through a nylon filter.

20. A method for forming a pattern, the method comprising
forming an organic underlayer film on a semiconductor substrate;
applying the silicon-containing resist underlayer film-forming composition according to claim 1 on the organic underlayer film and baking to form a resist underlayer film;
forming a metal-containing resist film on the resist underlayer film;
exposing and developing the metal-containing resist film to form a resist pattern;
etching the resist underlayer film using the resist pattern as a mask; and
etching the organic underlayer film using the patterned resist underlayer film as a mask.

21. The method for forming a pattern according to claim 20, further comprising removing the resist underlayer film by a wet method using a chemical liquid, after the etching the organic underlayer film.

22. The method for forming a pattern according to claim 20, wherein the metal-containing resist film is formed of a metal-containing resist for EUV lithography.

23. The silicon-containing resist underlayer film-forming composition according to claim 2, wherein R¹ in Formula (A-1) is represented by the following Formula (A-2a): 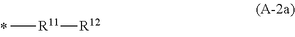
where in Formula (A-2a), R¹¹ represents a single bond or a divalent organic group which may have an ionic bond,
R¹² represents a group having an unsaturated bond and a ring structure, and an asterisk * represents a bonding hand.

24. The silicon-containing resist underlayer film-forming composition according to claim 23, wherein R¹² in Formula (A-2a) is represented by the following Formula (A-2b): 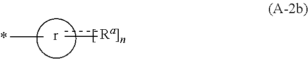
where in Formula (A-2b), r represents a ring structure, [symbol]
represents a single bond or a double bond, provided that, when [symbol]
represents a single bond, R^{a} represents a halogen atom or a monovalent group, and when [symbol]
represents a double bond, R^{a} represents an oxygen atom,
n is 0 or more and represents a value less than or equal to a number n of substituents that the ring structure r may have,
when n is 2 or more, [symbol]
and R^{a} may be identical or different,
when the ring structure r has a double bond in a bond forming the ring, n may be 0,
when the ring structure r has only a single bond as the bond forming the ring, n is 1 or more, and at least one of [symbol]
is a double bond or at least one R^{a} has an unsaturated bond, and
an asterisk * represents a bonding hand.

25. The silicon-containing resist underlayer film-forming composition according to claim 24, wherein the ring structure r is a monocyclic 5-membered ring structure, a monocyclic 6-membered ring structure, a bicyclic structure, or a tricyclic structure.

26. The silicon-containing resist underlayer film-forming composition according to claim 24, wherein Formula (A-2b) is any one of the following Formulae (A-2c-1) to (A-2c-6): 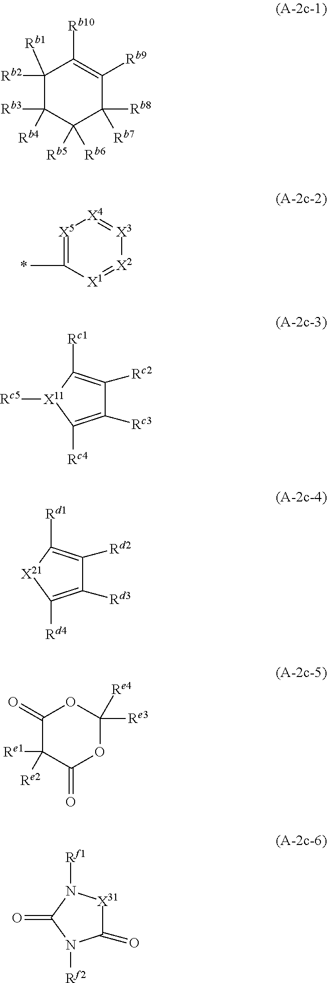
where in Formula (A-2c-1), R^{1b} to R^{b10} each independently represent a hydrogen atom, a halogen atom, or a monovalent group, R^{b1} and R^{b8} may be combined to form a methylene group or a 1,2-ethylene group, provided that one of R^{1b} to R^{b10} represents a bonding hand bonded to R¹¹ in Formula (A-2a),
in Formula (A-2c-2), X¹ to X⁵ each represent N or CR (provided that Rs each independently represent a hydrogen atom, a halogen atom, or a monovalent group), an asterisk * represents a bonding hand,
in Formula (A-2c-3), X¹¹ represents N or CR (provided that R represents a hydrogen atom, a halogen atom, or a monovalent group), R^{c1} to R^{c5} each independently represent a hydrogen atom, a halogen atom, or a monovalent group, provided that one of R^{c1} to R^{c5} represents a bonding hand bonded to R¹¹ in Formula (A-2a),
in Formula (A-2c-4), X²¹ represents O or S, R^{d1} to R^{d4} each independently represent a hydrogen atom, a halogen atom, or a monovalent group, provided that one of R^{d1} to R^{d4} represents a bonding hand bonded to R¹¹ in Formula (A-2a),
in Formula (A-2c-5), R^{e1} to R^{e4} each independently represent a hydrogen atom, a halogen atom, or a monovalent group, provided that one of R^{e1} to R^{e4} represents a bonding hand bonded to R¹¹ in Formula (A-2a),
in Formula (A-2c-6), X³¹ represents —C(═O)—N(R³)—, —C(═O)—C(R^{f4})(R^{f5})—, or —C(R^{f6})(R^{f7})—, R^{f1} to R^{f7} each independently represent a hydrogen atom, a halogen atom, or a monovalent group, provided that one of R^{f1} and R^{f2} represents a bonding hand bonded to R¹¹ in Formula (A-2a).

27. A silicon-containing resist underlayer film which is a cured product of the silicon-containing resist underlayer film-forming composition according to claim 2.

28. A semiconductor processing substrate comprising:
a semiconductor substrate; and
the silicon-containing resist underlayer film according to claim 27.

29. A method for producing a semiconductor element, the method comprising:
forming an organic underlayer film on a substrate;
forming a resist underlayer film on the organic underlayer film using the silicon-containing resist underlayer film-forming composition according to claim 2; and
forming a metal-containing resist film on the resist underlayer film.

30. A method for forming a pattern, the method comprising:
forming an organic underlayer film on a semiconductor substrate;
applying the silicon-containing resist underlayer film-forming composition according to claim 2 on the organic underlayer film and baking to form a resist underlayer film;
forming a metal-containing resist film on the resist underlayer film;
exposing and developing the metal-containing resist film to form a resist pattern;
etching the resist underlayer film using the resist pattern as a mask; and
etching the organic underlayer film using the patterned resist underlayer film as a mask.
